(19) United States
(12) Patent Application Publication
(10) Pub. No.: US 2011/0156182 A1
(43) Pub. Date: Jun. 30, 2011

(54) SEMICONDUCTOR DEVICE

(75) Inventors: Yosuke TAKEUCHI, Kanagawa (JP); Masamichi Matsuoka, Kanagawa (JP); Ryoji Matsuda, Kanagawa (JP)

(73) Assignee: RENESAS ELECTRONICS CORPORATION

(21) Appl. No.: 12/971,988

(22) Filed: Dec. 17, 2010

(30) Foreign Application Priority Data
Dec. 25, 2009 (JP) 2009-294895

(51) Int. Cl. H01L 29/82

(52) U.S. Cl. 257/421; 257/E29.323

(57) ABSTRACT

To provide a semiconductor device capable of further suppressing the leakage of magnetic field in a magnetoresistive element and capable of further improving performance.

There is provided a semiconductor device comprising a semiconductor substrate, a magnetoresistive element, a wire, barrier layers, and cladding layers. The semiconductor substrate has a main surface. The magnetoresistive element is located over the main surface of the semiconductor substrate. The wire is located over the magnetoresistive element. The barrier layers are arranged so as to continuously cover the side surface and the top surface of the wire. The cladding layers are arranged so as to continuously cover the surfaces of the barrier layers facing the wire and the surfaces on the opposite side. A plurality of memory units including the magnetoresistive element, the wire, the barrier layers, and the cladding layers is formed. The memory units are arranged in parallel in the direction intersecting with the direction in which the wire extends, and the cladding layers are separated between the memory units.

### CROSS-REFERENCE TO RELATED APPLICATION

The disclosure of Japanese Patent Application No. 2009-294895 filed on Dec. 25, 2009 including the specification, drawings and abstract is incorporated herein by reference in its entirety.

### BACKGROUND OF THE INVENTION

The present invention relates to a semiconductor device and particularly, to a semiconductor device comprising a magnetoresistive element.

As a semiconductor device, such as a semiconductor integrated circuit for storage, conventionally, a DRAM (Dynamic Random Access Memory) or SRAM (Static Random Access Memory) is used widely. On the other hand, an MRAM (Magnetic Random Access Memory) is a device that stores information by magnetism and has characteristics, such as high-speed operation, rewrite durability, and non-volatility, more excellent compared to other memory technologies.

The MRAM comprises a magnetoresistive element, referred to as an MTJ (Magnetic Tunnel Junction) element, which utilizes the tunneling magnetoresistive (TMR) effect and stores information by the magnetized state of the magnetoresistive element. The magnetoresistive elements are arranged at portions where, for example, a digit line extending in one direction and a bit line extending in one direction which is substantially perpendicular to the one direction intersect with each other, and are formed into the shape of an array. In each magnetoresistive element, two magnetic layers are laminated with a tunnel insulating film being interposed in between. The magnetoresistive element includes a layer whose direction of magnetization changes depending on the magnetic field produced by electric currents that flow through the digit line and the bit line. The magnetoresistive element stores the direction of magnetization as information. Then, according to the direction of magnetization of the layer, the electrical resistance of the magnetoresistive element changes. By the change in the electrical resistance, the detection of the change in the electric current that flows through the magnetoresistive element allows the detection of information stored in the magnetoresistive element.

In order to intensively supply magnetic fields produced by electric currents to the magnetoresistive element, a cladding layer having a high magnetic permeability is arranged on the side surface or top surface of a wire. Various kinds of MRAM have been proposed hitherto in which such a cladding layer is employed.

For example, in the MRAM device described in Japanese Patent Laid-Open No. 2000-353791 (Patent Document 1) and Japanese Patent Laid-Open No. 2003-249630 (Patent Document 2), a thin film layer having a high magnetic permeability is arranged so as to cover the side surface or top surface of the bit line, which is a wire used to supply magnetic fields produced by electric currents.

However, if a layer having a high magnetic permeability is arranged directly on the side surface and top surface of the bit line as in the MRAM device in Japanese Patent Laid-Open No. 2000-353791 and the semiconductor storage device in Japanese Patent Laid-Open No. 2003-249630, there is a possibility that the atoms in the bit line and the atoms in the cladding layer cause mutual diffusion. If such diffusion occurs, there may be a case where the resistance of the wire (bit line) rises or the efficiency in concentrating magnetic fields produced by electric currents into the magnetoresistive element decreases.

On the other hand, in the semiconductor device described in Japanese Patent Laid-Open No. 2009-38221 (Patent Document 3), an insulating film is sandwiched between a bit line of a magnetic memory element and a high magnetic permeability film thereabove and a barrier metal layer is sandwiched between the bit line and the high magnetic permeability film on the lateral side thereof. In the magnetic storage device described in Japanese Patent Laid-Open No. 2006-32762 (Patent Document 4), a barrier metal film and an interlayer insulating film are arranged between the lateral side of a wire (copper film) and a high magnetic permeability film. Further, an insulating film is arranged between the upper side of the wire and the high magnetic permeability film. Furthermore, in the magnetic-electronic device described in Japanese Unexamined Publication Patent Application Publication (Translation of PCT Application) No. 2006-511956 (Patent Document 5), an etching stop layer is sandwiched between a bit line and a cladding layer thereabove.

### SUMMARY OF THE INVENTION

In the semiconductor device in Japanese Patent Laid-Open No. 2009-38221, the high magnetic permeability film above the bit line and the high magnetic permeability film on the lateral side of the bit line are separated by the presence of the insulating film sandwiched between the high magnetic permeability film above the bit line and the bit line. That is, the high magnetic permeability film above the bit line and the high magnetic permeability film on the lateral side of the bit line are discontinuous. Because of this, there is a possibility that the magnetic lines of force that run along the high magnetic permeability film leak in the direction away from the bit line in the region where the high magnetic permeability films are discontinuous. If this occurs, the magnetic lines of force leak to, for example, the neighboring magnetoresistive element, and therefore, there is a possibility that information is erroneously written to the neighboring magnetoresistive element. This also applies to the magnetic-electronic device in Japanese Unexamined Publication Patent Application Publication (Translation of PCT Application) No. 2006-511956.

In the magnetic storage device in Japanese Patent Laid-Open No. 2006-32762, the high magnetic permeability films arranged above and on the lateral side of the respective two wires in parallel are common. That is, the high magnetic permeability films are continuous between the two wires in parallel. In this case, the magnetic lines of force produced by one of the wires run along the high magnetic permeability film that acts as an intermediate bridge between the two wires, and therefore, there is a possibility that the magnetic lines of force leak to the other wire. If this occurs, the magnetic lines of force leak to, for example, the neighboring magnetoresistive element, and therefore, there is a possibility that information is erroneously written to the neighboring magnetoresistive element. That is, it is preferable that the magnetic lines of force produced by the electric current that flows through a certain wire be supplied intensively to the magnetoresistive element present immediately under the wire and that the magnetoresistive element operate properly.

The present invention has been made in view of the above circumstances. An object of the present invention is to provide a semiconductor device including a memory unit of an MRAM capable of suppressing mutual diffusion between a wire and a high magnetic permeability film and at the same time, capable of intensively supplying magnetic fields produced by electric currents that flow through the wire to a desired magnetoresistive element.

According to an embodiment of the present invention, there is provided a semiconductor device comprising a semiconductor substrate, a magnetoresistive element, a wire, a barrier layer, and a cladding layer. The semiconductor substrate has a main surface. The magnetoresistive element is located over the main surface of the semiconductor substrate. The wire is located over the magnetoresistive element. The barrier layer is arranged so as to continuously cover the side surface and the top surface of the wire. The cladding layer is arranged so as to continuously cover the surface of the barrier layer facing the wire and the surface on the opposite side. A plurality of memory units including the magnetoresistive element, the wire, the barrier layer, and the cladding layer is formed. The memory units are arranged in parallel in the direction intersecting with the direction in which the wire extends and cladding layer is separated between the memory units.

According to the embodiment, the barrier layer suppresses mutual diffusion between the wire and the high magnetic permeability film. The magnetoresistive elements are provided, which are arranged so that the cladding layer arranged on the lateral side of the wire and the cladding layer arranged on the top of the wire are continuous with each other. Because of this, the magnetic lines of force that pass through the inside of the cladding layer are prevented from leaking to the outside of the cladding layer, particularly, to the neighboring magnetoresistive element. Consequently, there is an effect of suppressing an erroneous operation of a semiconductor device including the magnetoresistive element.

### BRIEF DESCRIPTION OF THE DRAWINGS

FIG. 1 is a plan view schematically showing a semiconductor device according to an embodiment;

FIG. 2 is a plan view showing a magnetoresistive element in FIG. 1 and its periphery;

FIG. 3 is a section view of the semiconductor device according to the present embodiment;

FIG. 4 is an enlarged section view of the side upper than a digit line of the semiconductor device in FIG. 3 according to a first embodiment;

FIG. 5 is a section view showing an aspect of a circuit on the periphery of a region in which a plurality of memory units is formed of the semiconductor device in FIG. 3 according to the present first embodiment;

FIG. 6 is a section view showing an example of a laminated structure configuring a magnetization fixed layer;

FIG. 7 is an enlarged view of a bit line in FIG. 4 and its nearby region, also a section view showing an aspect of a bit line according to the present first embodiment;

FIG. 8 is an enlarged view of a cladding layer end part in FIG. 7 and its nearby region;

FIG. 9 is a first modified example showing an aspect of the cladding layer end part shown in FIG. 8 and its nearby region;

FIG. 10 is an enlarged section view showing an aspect of magnetic lines of force formed when an electric current is caused to flow through the bit line in FIG. 4;

FIG. 11 is a section view showing a first process of a manufacturing process of the semiconductor device according to the present embodiment;

FIG. 12 is a section view showing a manufacturing process after the manufacturing process shown in FIG. 11;

FIG. 13 is a section view showing a manufacturing process after the manufacturing process shown in FIG. 12;

FIG. 14 is a section view showing a manufacturing process after the manufacturing process shown in FIG. 13;

FIG. 15 is a section view showing a manufacturing process after the manufacturing process shown in FIG. 14;

FIG. 16 is a section view showing a manufacturing process after the manufacturing process shown in FIG. 15;

FIG. 17 is a section view showing a manufacturing process after the manufacturing process shown in FIG. 16;

FIG. 18 is a section view showing a manufacturing process after the manufacturing process shown in FIG. 17;

FIG. 19 is a schematic diagram of a sputtering device;

FIG. 20 is a section view showing a manufacturing process after the manufacturing process shown in FIG. 18;

FIG. 21 is a section view showing a manufacturing process after the manufacturing process shown in FIG. 20;

FIG. 22 is a section view showing a manufacturing process after the manufacturing process shown in FIG. 21;

FIG. 23 is a section view showing a manufacturing process after the manufacturing process shown in FIG. 22;

FIG. 24 is a section view showing a manufacturing process after the manufacturing process shown in FIG. 23;

FIG. 25 is a section view showing a manufacturing process after the manufacturing process shown in FIG. 24;

FIG. 26 is a section view showing a manufacturing process after the manufacturing process shown in FIG. 25;

FIG. 27 is a section view showing a manufacturing process after the manufacturing process shown in FIG. 26;

FIG. 28(A) is a section view showing a manufacturing process after the manufacturing process shown in FIG. 27;

FIG. 28(B) is a section view showing an aspect when viewed in the direction intersecting with FIG. 28(A);

FIG. 28(C) is a section view showing an aspect of a peripheral circuit part in FIGS. 28(A) (B);

FIG. 29(A) is a section view showing a manufacturing process after the manufacturing process shown in FIG. 28 in the first embodiment;

FIG. 29(B) is a section view showing an aspect when viewed in the direction intersecting with FIG. 29(A);

FIG. 29(C) is a section view showing an aspect of a peripheral circuit part in FIGS. 29(A) (B);

FIG. 30(A) is a section view showing a manufacturing process after the manufacturing process shown in FIG. 29;

FIG. 30(B) is a section view showing an aspect when viewed in the direction intersecting with FIG. 30(A);

FIG. 30(C) is a section view showing an aspect of a peripheral circuit part in FIGS. 30(A) (B);

FIG. 31(A) is a section view showing a manufacturing process after the manufacturing process shown in FIG. 30;

FIG. 31(B) is a section view showing an aspect when viewed in the direction intersecting with FIG. 31(A);

FIG. 31(C) is a section view showing an aspect of a peripheral circuit part in FIGS. 31(A) (B);

FIG. 32(A) is a section view showing a manufacturing process after the manufacturing process shown in FIG. 31;

FIG. 32(B) is a section view showing an aspect when viewed in the direction intersecting with FIG. 32(A);

FIG. 32(C) is a section view showing an aspect of a peripheral circuit part in FIGS. 32(A) (B);

FIG. 33(A) is a section view showing a manufacturing process after the manufacturing process shown in FIG. 32;

FIG. 33(B) is a section view showing an aspect when viewed in the direction intersecting with FIG. 33(A);

FIG. 33(C) is a section view showing an aspect of a peripheral circuit part in FIGS. 33(A) (B);

FIG. 34(A) is a section view showing a manufacturing process after the manufacturing process shown in FIG. 33;

FIG. 34(B) is a section view showing an aspect when viewed in the direction intersecting with FIG. 34(A);

FIG. 34(C) is a section view showing an aspect of a peripheral circuit part in FIGS. 34(A) (B);

FIG. 35(A) is a section view showing a manufacturing process after the manufacturing process shown in FIG. 34;

FIG. 35(B) is a section view showing an aspect when viewed in the direction intersecting with FIG. 35(A);

FIG. 35(C) is a section view showing an aspect of a peripheral circuit part in FIGS. 35(A) (B);

FIG. 36(A) is a section view showing a manufacturing process after the manufacturing process shown in FIG. 35;

FIG. 36(B) is a section view showing an aspect when viewed in the direction intersecting with FIG. 36(A);

FIG. 36(C) is a section view showing an aspect of a peripheral circuit part in FIGS. 36(A) (B);

FIG. 37(A) is a section view showing an aspect of only the side upper than a wire main body in FIG. 36(A);

FIG. 37(B) is a section view showing an aspect of only the side upper than the wire main body in FIG. 36(B);

FIG. 37(C) is a section view showing an aspect of only the side upper than the wire main body in FIG. 36(C);

FIG. 38(A) is a section view showing a manufacturing process after the manufacturing process shown in FIG. 37;

FIG. 38(B) is a section view showing an aspect when viewed in the direction intersecting with FIG. 38(A);

FIG. 38(C) is a section view showing an aspect of a peripheral circuit part in FIGS. 38(A) (B);

FIG. 39(A) is a section view showing a manufacturing process after the manufacturing process shown in FIG. 38;

FIG. 39(B) is a section view showing an aspect when viewed in the direction intersecting with FIG. 39(A);

FIG. 39(C) is a section view showing an aspect of a peripheral circuit part in FIGS. 39(A) (B);

FIG. 40(A) is a section view showing a manufacturing process after the manufacturing process shown in FIG. 39;

FIG. 40(B) is a section view showing an aspect when viewed in the direction intersecting with FIG. 40(A);

FIG. 40(C) is a section view showing an aspect of a peripheral circuit part in FIGS. 40(A) (B);

FIG. 41(A) is a section view showing a manufacturing process after the manufacturing process shown in FIG. 40;

FIG. 41(B) is a section view showing an aspect when viewed in the direction intersecting with FIG. 41(A);

FIG. 41(C) is a section view showing an aspect of a peripheral circuit part in FIGS. 41(A) (B);

FIG. 42(A) is a section view showing a manufacturing process after the manufacturing process shown in FIG. 41;

FIG. 42(B) is a section view showing an aspect when viewed in the direction intersecting with FIG. 42(A);

FIG. 42(C) is a section view showing an aspect of a peripheral circuit part in FIGS. 42(A) (B);

FIG. 43(A) is a section view showing a manufacturing process after the manufacturing process shown in FIG. 42;

FIG. 43(B) is a section view showing an aspect when viewed in the direction intersecting with FIG. 43(A);

FIG. 43(C) is a section view showing an aspect of a peripheral circuit part in FIGS. 43(A) (B);

FIG. 44 is a section view showing an aspect of a bit line according to a second embodiment;

FIG. 45 is an enlarged section view of the side upper than a digit line of the semiconductor device in FIG. 3 according to the present second embodiment;

FIG. 46 is a section view showing an aspect of a circuit on the periphery of a region in which a plurality of memory units is formed of the semiconductor device in FIG. 3 according to the present second embodiment;

FIG. 47(A) is a section view showing a manufacturing process after the manufacturing process shown in FIG. 28 in the present second embodiment;

FIG. 47(B) is a section view showing an aspect when viewed in the direction intersecting with FIG. 47(A);

FIG. 47(C) is a section view showing an aspect of a peripheral circuit part in FIGS. 47(A) (B);

FIG. 48(A) is a section view showing a manufacturing process after the manufacturing process shown in FIG. 47;

FIG. 48(B) is a section view showing an aspect when viewed in the direction intersecting with FIG. 48(A);

FIG. 48(C) is a section view showing an aspect of a peripheral circuit part in FIGS. 48(A) (B);

FIG. 49(A) is a section view showing a manufacturing process after the manufacturing process shown in FIG. 48;

FIG. 49(B) is a section view showing an aspect when viewed in the direction intersecting with FIG. 49(A);

FIG. 49(C) is a section view showing an aspect of a peripheral circuit part in FIGS. 49(A) (B);

FIG. 50(A) is a section view showing a manufacturing process after the manufacturing process shown in FIG. 49;

FIG. 50(B) is a section view showing an aspect when viewed in the direction intersecting with FIG. 50(A);

FIG. 50(C) is a section view showing an aspect of a peripheral circuit part in FIGS. 50(A) (B);

FIG. 51(A) is a section view showing an aspect of the side upper than a contact part in a manufacturing process after the manufacturing process shown in FIG. 50;

FIG. 51(B) is a section view showing an aspect when viewed in the direction intersecting with FIG. 51(A);

FIG. 51(C) is a section view showing an aspect of a peripheral circuit part in FIGS. 51(A) (B);

FIG. 52(A) is a section view showing a manufacturing process after the manufacturing process shown in FIG. 51;

FIG. 52(B) is a section view showing an aspect when viewed in the direction intersecting with FIG. 52(A);

FIG. 52(C) is a section view showing an aspect of a peripheral circuit part in FIGS. 52(A) (B);

FIG. 53(A) is a section view showing a manufacturing process after the manufacturing process shown in FIG. 52;

FIG. 53(B) is a section view showing an aspect when viewed in the direction intersecting with FIG. 53(A);

FIG. 53(C) is a section view showing an aspect of a peripheral circuit part in FIGS. 53(A) (B);

FIG. 54(A) is a section view showing a manufacturing process after the manufacturing process shown in FIG. 53;

FIG. 54(B) is a section view showing an aspect when viewed in the direction intersecting with FIG. 54(A);

FIG. 54(C) is a section view showing an aspect of a peripheral circuit part in FIGS. 54(A) (B);

FIG. 55(A) is a section view showing a manufacturing process after the manufacturing process shown in FIG. 54;

FIG. 55(B) is a section view showing an aspect when viewed in the direction intersecting with FIG. 55(A);

FIG. 55(C) is a section view showing an aspect of a peripheral circuit part in FIGS. 55(A) (B);

FIG. 56(A) is a section view showing a manufacturing process after the manufacturing process shown in FIG. 55;

FIG. 56(B) is a section view showing an aspect when viewed in the direction intersecting with FIG. 56(A);

FIG. 56(C) is a section view showing an aspect of a peripheral circuit part in FIGS. 56(A) (B);

FIG. 57 is a section view showing an aspect of a bit line according to a third embodiment;

FIG. 58 is an enlarged section view of the side upper than the wire main body of the semiconductor in FIG. 3 according to the present third embodiment;

FIG. 59(A) is a section view showing a manufacturing process after the manufacturing process shown in FIG. 38 in the present third embodiment;

FIG. 59(B) is a section view showing an aspect when viewed in the direction intersecting with FIG. 59(A);

FIG. 59(C) is a section view showing an aspect of a peripheral circuit part in FIGS. 59(A) (B);

FIG. 60(A) is a section view showing a manufacturing process after the manufacturing process shown in FIG. 59;

FIG. 60(B) is a section view showing an aspect when viewed in the direction intersecting with FIG. 60(A);

FIG. 60(C) is a section view showing an aspect of a peripheral circuit part in FIGS. 60(A) (B);

FIG. 61(A) is a section view showing a manufacturing process after the manufacturing process shown in FIG. 60;

FIG. 61(B) is a section view showing an aspect when viewed in the direction intersecting with FIG. 61(A);

FIG. 61(C) is a section view showing an aspect of a peripheral circuit part in FIGS. 61(A) (B);

FIG. 62(A) is a section view showing a manufacturing process after the manufacturing process shown in FIG. 61;

FIG. 62(B) is a section view showing an aspect when viewed in the direction intersecting with FIG. 62(A);

FIG. 62(C) is a section view showing an aspect of a peripheral circuit part in FIGS. 62(A) (B);

FIG. 63(A) is a section view showing a manufacturing process after the manufacturing process shown in FIG. 62;

FIG. 63(B) is a section view showing an aspect when viewed in the direction intersecting with FIG. 63(A);

FIG. 63(C) is a section view showing an aspect of a peripheral circuit part in FIGS. 63(A) (B);

FIG. 64 is a section view showing an aspect of a bit line according to fourth and fifth embodiments;

FIG. 65 is a section view of a semiconductor device corresponding to FIG. 3 in the fourth and fifth embodiments;

FIG. 66 is an enlarged section view of the side upper than the digit line of the semiconductor device in FIG. 3 according to the present fourth embodiment;

FIG. 67 is a section view showing an aspect of a circuit on the periphery of a region in which a plurality of memory units is formed of the semiconductor device in FIG. 3 according to the present fourth embodiment;

FIG. 68(A) is a section view showing a manufacturing process after the manufacturing process shown in FIG. 37 in the present fourth embodiment;

FIG. 68(B) is a section view showing an aspect when viewed in the direction intersecting with FIG. 68(A);

FIG. 68(C) is a section view showing an aspect of a peripheral circuit part in FIGS. 68(A) (B);

FIG. 69(A) is a section view showing a manufacturing process after the manufacturing process shown in FIG. 68;

FIG. 69(B) is a section view showing an aspect when viewed in the direction intersecting with FIG. 69(A);

FIG. 69(C) is a section view showing an aspect of a peripheral circuit part in FIGS. 69(A) (B);

FIG. 70(A) is a section view showing a manufacturing process after the manufacturing process shown in FIG. 69;

FIG. 70(B) is a section view showing an aspect when viewed in the direction intersecting with FIG. 70(A);

FIG. 70(C) is a section view showing an aspect of a peripheral circuit part in FIGS. 70(A) (B);

FIG. 71(A) is a section view showing a manufacturing process after the manufacturing process shown in FIG. 70;

FIG. 71(B) is a section view showing an aspect when viewed in the direction intersecting with FIG. 71(A);

FIG. 71(C) is a section view showing an aspect of a peripheral circuit part in FIGS. 71(A) (B);

FIG. 72 is an enlarged section view of the side upper than the digit line of the semiconductor device in FIG. 3 according to the present fifth embodiment;

FIG. 73(A) is a section view showing a manufacturing process after the manufacturing process shown in FIG. 37 in the present fifth embodiment;

FIG. 73(B) is a section view showing an aspect when viewed in the direction intersecting with FIG. 73(A);

FIG. 73(C) is a section view showing an aspect of a peripheral circuit part in FIGS. 73(A) (B);

FIG. 74(A) is a section view showing a manufacturing process after the manufacturing process shown in FIG. 73;

FIG. 74(B) is a section view showing an aspect when viewed in the direction intersecting with FIG. 74(A);

FIG. 74(C) is a section view showing an aspect of a peripheral circuit part in FIGS. 74(A) (B);

FIG. 75(A) is a section view showing a manufacturing process after the manufacturing process shown in FIG. 74;

FIG. 75(B) is a section view showing an aspect when viewed in the direction intersecting with FIG. 75(A);

FIG. 75(C) is a section view showing an aspect of a peripheral circuit part in FIGS. 75(A) (B);

FIG. 76(A) is a section view showing a manufacturing process after the manufacturing process shown in FIG. 75;

FIG. 76(B) is a section view showing an aspect when viewed in the direction intersecting with FIG. 76(A);

FIG. 76(C) is a section view showing an aspect of a peripheral circuit part in FIGS. 76(A) (B);

FIG. 77 is a section view showing an aspect of a bit line according to a sixth embodiment;

FIG. 78 is an enlarged section view of the side upper than the digit line of the semiconductor device in FIG. 3 according to the present sixth embodiment;

FIG. 79 is a section view showing an aspect of a circuit on the periphery of a region in which a plurality of memory units is formed of the semiconductor device in FIG. 3 according to the present sixth embodiment;

FIG. 80(A) is a section view showing a manufacturing process after the manufacturing process shown in FIG. 36 in the sixth embodiment;

FIG. 80(B) is a section view showing an aspect when viewed in the direction intersecting with FIG. 80(A);

FIG. 80(C) is a section view showing an aspect of a peripheral circuit part in FIGS. 80(A) (B);

FIG. 81(A) is a section view showing an aspect of only the side upper than a wire main body in the manufacturing process after the manufacturing process shown in FIG. 80;

FIG. 81(B) is a section view showing an aspect when viewed in the direction intersecting with FIG. 81(A);

FIG. 81(C) is a section view showing an aspect of a peripheral circuit part in FIGS. 81(A) (B);

FIG. 82(A) is a section view showing a manufacturing process after the manufacturing process shown in FIG. 81;

FIG. 82(B) is a section view showing an aspect when viewed in the direction intersecting with FIG. 82(A);

FIG. 82(C) is a section view showing an aspect of a peripheral circuit part in FIGS. 82(A) (B);

FIG. 83 is a section view showing an aspect of a configuration of a bit line of a semiconductor device as a comparative example of the present invention when viewed in the same direction as that in FIG. 3;

FIG. 84 is a section view showing an aspect of the bit line in FIG. 83 when viewed in the same direction as that in FIG. 4;

FIG. 85 is a section view showing a first modified example different from that in FIG. 84 of the bit line as a comparative example of the present invention; and

FIG. 86 is a section view showing a second modified example different from that in FIG. 85 of the bit line as a comparative example of the present invention.

### DETAILED DESCRIPTION OF PREFERRED EMBODIMENTS

Each embodiment of the present invention will be explained below with reference to the drawings. In each embodiment, the same reference symbol is attached to an element that serves the same function and its explanation is not repeated unless necessary. In the following embodiments to be explained, when referring to the number of elements, an amount, etc., the scope of the present invention is not necessarily restricted to the number of elements, the amount, etc., except when described particularly. Further, in the following embodiments, each element is not necessarily indispensable to the present invention except when described particularly.

### First Embodiment

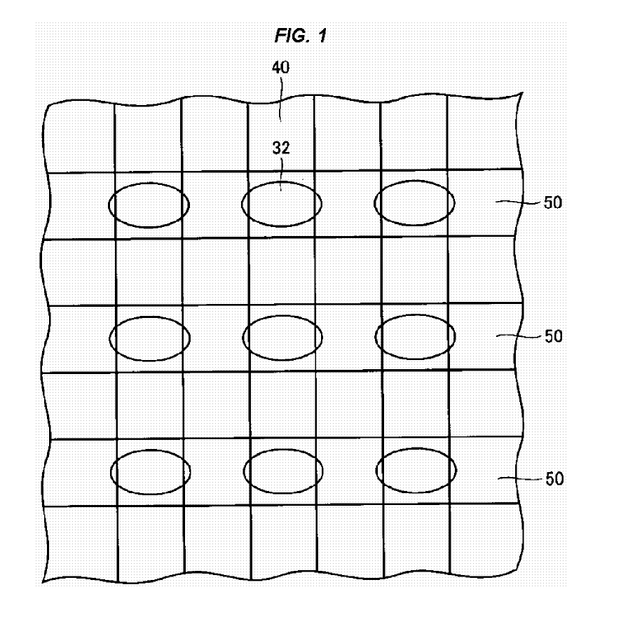

FIG. 1 is a plan view schematically showing a semiconductor device 200 according to a first embodiment. As shown in FIG. 1, a semiconductor substrate 100 comprises bit lines 40 extending in one direction, digit lines 50 located below the bit lines 40 and formed so as to intersect the bit lines 40, and magnetoresistive elements 32 located between the digit lines 50 and the bit lines 40 and formed in regions where the digit lines 50 and the bit lines 40 intersect.

A plurality of the bit lines 40 is formed extending in one direction and at the same time, with an interval in between. A plurality of the digit lines 50 is formed extending in the direction of arrangement of the bit lines 40, with an interval in between in the direction in which the bit lines 40 extend. The magnetoresistive element 32 is provided at each portion where the digit line 50 and the bit line 40 intersect.

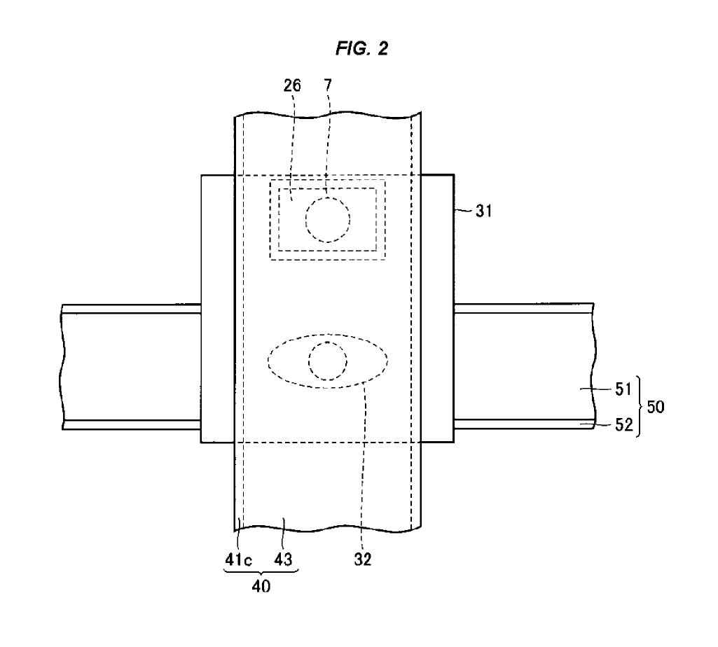

FIG. 2 is a plan view showing the magnetoresistive element and its periphery and as shown in FIG. 2, the magnetoresistive element 32 is formed inside the region where the digit line 50 and the bit line 40 intersect when viewed in a planar manner.

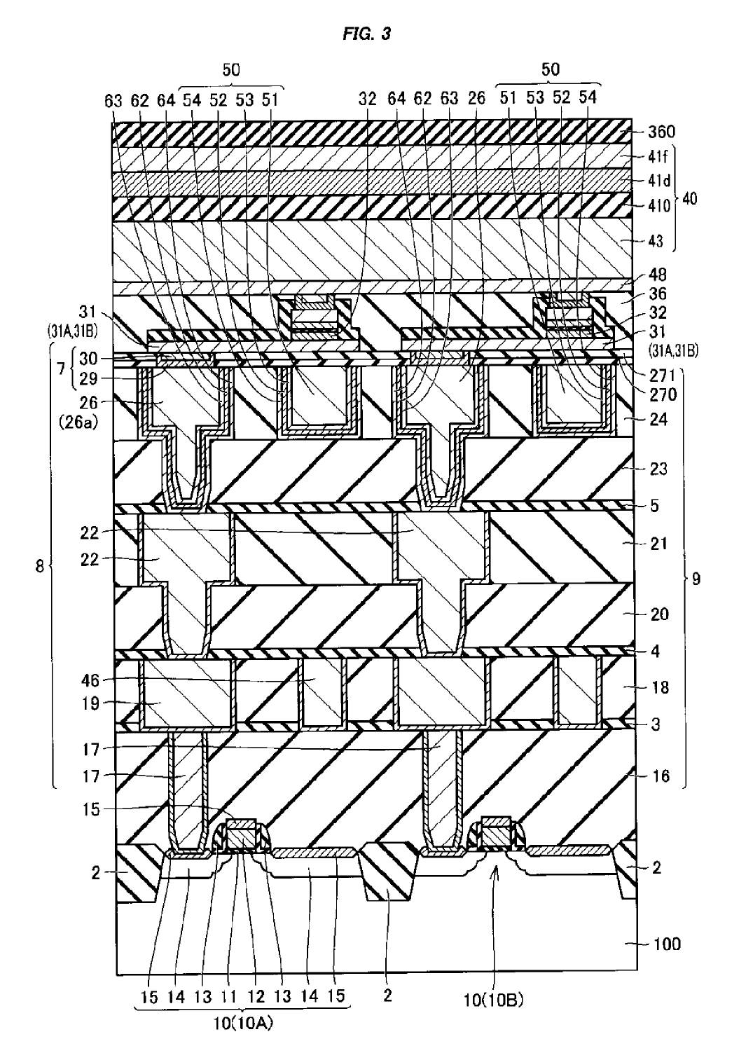

As shown in the section view in FIG. 3, the semiconductor device 200 comprises the semiconductor substrate 100, a plurality of MOS transistors (switching elements) 10 formed over the main surface of the semiconductor substrate 100, an interlayer insulating film 9 including a plurality of insulating films formed so as to cover the MOS transistor and flat insulating films 270, 271 formed over the insulating film, and a lower electrode 31 formed over the top surface of the flat insulating film 271 as a leader wire.

The semiconductor device 200 comprises a coupling wire 8 that couples the MOS transistor 10 and the lower electrode 31, and the magnetoresistive element 32 formed over the lower electrode 31. That is, as shown in FIG. 3, the configuration in the semiconductor device 200 is such that the magnetoresistive element 32 is located over the main surface of the semiconductor substrate 100.

In FIG. 3, the two lower electrodes 31 are provided with an interval in between and the magnetoresistive element 32 is formed over the top surface of the lower electrode 31. Below the magnetoresistive element 32, the digit line 50 is formed and above the magnetoresistive element 32, the bit line 40 is formed.

When an electric current flows through the digit line 50 and the bit line 40, a magnetic field is formed around the digit line 50 and the bit line 40. The resultant magnetic field of the magnetic field of the digit line 50 and the magnetic field of the bit line 40 is applied to the magnetoresistive element 32.

Over the main surface of the semiconductor substrate 100, a separation insulating film 2 that defines an active region is formed and the MOS transistor 10 is formed over the active region.

In the section shown in FIG. 3, a MOS transistor 10A and a MOS transistor 10B are formed with an interval in between.

The MOS transistor 10A comprises a channel region formed on the main surface of the semiconductor substrate 100, an impurity region 14 formed on both sides of the channel region, a gate insulating film 11, and a gate electrode 12 formed over the gate insulating film 11. The MOS transistor 10A includes a sidewall 13 formed on the side surface of the gate electrode 12, a metal film 15 formed over the top surface of the impurity region 14, and the metal film 15 formed over the gate electrode.

To the impurity region 14 that functions as a drain electrode, the coupling wire 8 is coupled and the other impurity region 14 functions as a source electrode.

To the impurity region 14 that functions as a source electrode, a contact part, not shown schematically, is coupled and is coupled to a source wire 46 formed in the interlayer insulating film 9. The MOS transistor 10B is formed in the same manner as the MOS transistor 10A.

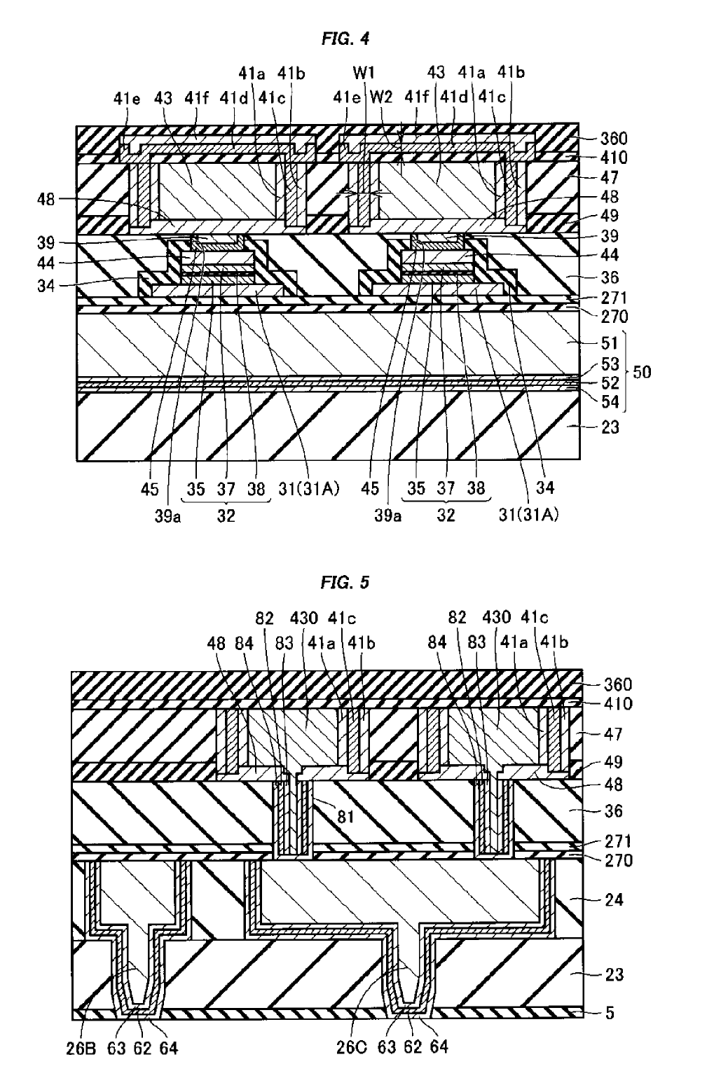

FIG. 4 is a section view showing a state where the two magnetoresistive elements 32 are put side by side when viewed in the direction intersecting with FIG. 3. Referring to FIG. 4 and FIG. 3, the magnetoresistive element 32 is formed over the main surface of one of the lower electrodes 31 (on the upper side). The magnetoresistive element 32 comprises a magnetization fixed layer 35 formed over the lower electrode 31 and coupled to the lower electrode 31, a tunnel insulating film 38 formed over the magnetization fixed layer 35, and a magnetization free layer 37 formed over the tunnel insulating film 38.

The magnetization free layer 37 can change the direction of magnetization when a magnetic filed is applied. The direction of magnetization of the magnetization fixed layer 35 is fixed and the magnetization fixed layer 35 is formed so that the direction of magnetization can be maintained unchanged even if a magnetic filed is applied from outside.

The magnetoresistive element 32 is coupled to the MOS transistor 10 via the lower electrode 31 and the coupling wire 8 shown in FIG. 3.

In the top surface of the magnetoresistive element 32, an upper electrode 44, which is a metal film, is formed and in the top surface of the upper electrode 44, a contact part 39 coupled to the bit line 40 is formed. In this manner, the magnetization free layer 37 of the magnetoresistive element 32 is coupled to the bit line 40.

An insulating film 34 is formed as a protective film so as to cover the side surfaces of the lower electrode 31, the magnetoresistive element 32 (the magnetization fixed layer 35, the tunnel insulating film 38, and the magnetization free layer 37), and the upper electrode 44.

A wire main body 43 of the bit line 40 is formed in the top surface of a barrier metal 48. The bit line 40 has a configuration in which a barrier metal 41a, a cladding layer 41c, and a barrier metal 41b are arranged in this order from the side of the wire main body 43 in such a manner as to cover the side surface of the wire main body 43. Further, in the top surface of the wire main body 43, a liner film 410, a cladding layer 41d, and a barrier metal 41f are arranged in this order from the side of the wire main body 43. Although the liner film 410 is arranged directly in the top surface of the wire main body 43, it is discontinuous in the horizontal direction in FIG. 4, for example, in the region over the top end part of the cladding layer 41c and the barrier metal 41b and in this region, a cladding layer end part 41e extending so that the cladding layer 41d is sunk is formed.

In other words, the barrier metal 41a is arranged so as to cover the side surface of the wire main body 43 and the liner film 410 is arranged so as to cover the top surface of the wire main body 43. These are arranged as a barrier layer that directly covers the side surface and the top surface of the wire main body 43. It is preferable that the barrier layer that covers the side surface of the wire main body 43 and the barrier layer that covers the top surface of the wire main body 43 are continuous over a section intersecting with the direction in which the bit line 40 shown in FIG. 4 extends. That is, it is preferable that a region is not present, where the wire main body 43 and the thin film (the cladding layers 41c, 41d, etc.) arranged outside the barrier layer are in contact with each other over the section.

Then, the cladding layer 41d, the cladding layer end part 41e, and the cladding layer 41c are continuous in the section view in FIG. 4. That is, in FIG. 4, the liner film 410 is discontinuous in the vicinity of the cladding layer end part 41e and the cladding layer end part 41e is arranged so as to fill in the discontinuous region. Because of this, the cladding layer 41d and the cladding layer end part 41e are continuous with the cladding layer 41c. In other words, the cladding layer is arranged so as to continuously cover the surface of the barrier layer facing the wire main body 43 and the surface on the opposite side (that is, the surface outside the barrier layer in FIG. 4).

FIG. 3 and FIG. 4 show only the aspect where the two magnetoresistive elements 32 are put in parallel. In fact, however, the aspect is such that the magnetoresistive elements 32 are arranged in the two dimensional directions in a plurality of columns (three or more columns) in parallel in the semiconductor device 200. That is, a plurality of memory units is formed, which comprise the magnetoresistive element 32, the wire main body 43 (wire located over the magnetoresistive element 32), the barrier layer, such as the barrier metal 41a and the liner film 410, and the cladding layer. Here, the wire main body 43 (wire), the barrier metals 41b, 41f (protective layers), the cladding layers 41c, 41d, the cladding layer end part 41e, the liner film 410 over the top surface of the wire main body 43, and the barrier metal 41a (barrier layer) are defined altogether as the bit line 40.

As shown in FIG. 4, the memory units are arranged in parallel in the direction (horizontal direction in FIG. 4) intersecting with the direction in which the wire main body extends. Then, as shown in FIG. 4, the respective cladding layers 41c, 41d of the bit line 40 over the two magnetoresistive elements 32 in parallel in the direction in which the digit line 50 extends are separated by the liner film 410 that couples the cladding layer end part 41e to another and a liner film 49 that couples the barrier metal 48 under the wire main body 43 to another. That is, the cladding layers 41c, 41d are separated between the memory units in parallel.

On the periphery of the memory units arranged in parallel when viewed in a planar manner as shown in FIG. 1 and FIG. 2, there are, for example, peripheral circuit parts that select each memory unit to read or write data and couple with an external load to supply electrical information and electric currents to an external load via an electrode pad. FIG. 5 shows an example of a section view of an upper region than an insulating film 5 in FIG. 3 of the peripheral circuit part of the semiconductor device 200. Referring to FIG. 5 and FIG. 3, electrically conductive layers, such as unit contact parts 26, 26B, 26C, formed so as to penetrate through insulating films 3, 4 and the insulating film 5 and insulating layers 23, 24, etc., are formed as well as a memory unit formation part and the peripheral circuit part of the semiconductor device 200. These are the members to bring into conduction from the semiconductor substrate 100 to the bit line 40, and further to the external load over an insulating layer 360. For example, the supply of electric current to a peripheral wire main body 430 formed at the same time as the wire main body 43 in the peripheral circuit part in FIG. 5 is performed by a unit contact part 81 and the unit contact part 26C thereunder. For example, the unit contact part 26C is formed at the same time as the unit contact part 26 shown in FIG. 3 and a cladding layer 62 and barrier metals 63, 64 of the unit contact part 26 are formed at the same time as the cladding layer 62 and the barrier metals 63, 64 of the unit contact part 26C. A cladding layer 82 and barrier metals 83, 84 similar to the cladding layer 62 and the barrier metals 63, 64 are formed on the inner surface of the unit contact part 81.

Here, the material and dimensions of each member described above are explained. It is preferable that the lower electrode 31 and the upper electrode 44 are formed by a thin film of metal materials, such as Ta (tantalum), TaN (tantalum nitride), Ru (ruthenium), and TiN (titanium nitride). Further, the lower electrode 31 and the upper electrode 44 may have a one-layer configuration or a configuration in which a plurality of thin films made of the different materials described above is laminated. It is preferable that the thickness of the lower electrode 31 (in the vertical direction in FIG. 3 and FIG. 4) is, for example, not less than 10 nm and not more than 70 nm, in particular, not less than 20 nm and not more than 50 nm. It is preferable that the thickness of the upper electrode 44 is, for example, not less than 30 nm and not more than 70 nm, in particular, not less than 35 nm and not more than 65 nm.

The magnetization fixed layer 35 is schematically shown as one layer in FIG. 3 and FIG. 4. However, in general, for the magnetization fixed layer 35, a two-layer structure in which a ferromagnetic layer is laminated over an antiferromagnetic layer, a four-layer structure in which a ferromagnetic layer, a non-magnetic layer, and a ferromagnetic layer are laminated in this order over an antiferromagnetic layer, a five-layer structure, etc., is used. However, the number of laminated layers and the order of layer lamination are not limited to these.

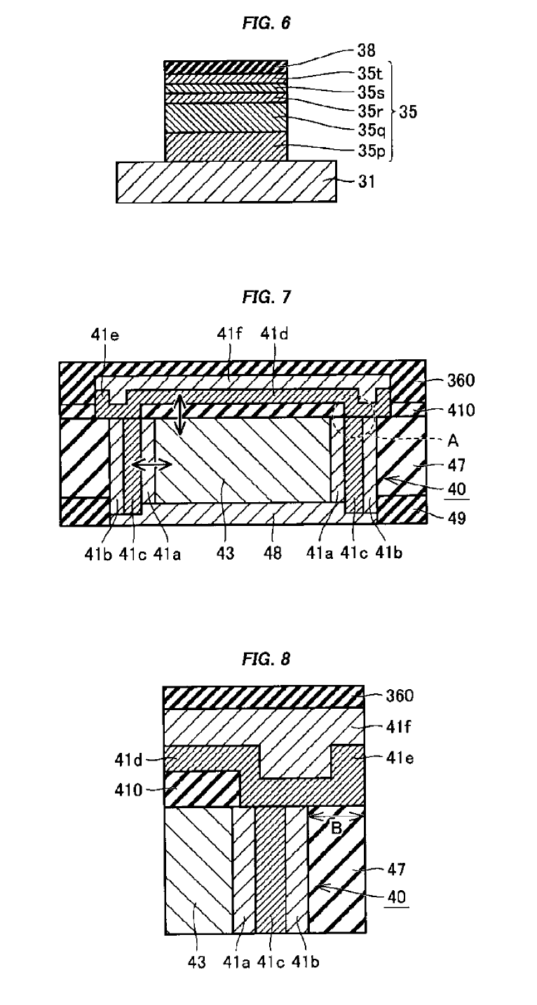

For example, when the magnetization fixed layer 35 has a five-layer structure, a configuration is preferable, in which a seed layer 35p, an antiferromagnetic layer 35q, a ferromagnetic layer 35r, a non-magnetic layer 35s, and a ferromagnetic layer 35t are laminated in this order from the lower side as shown in FIG. 6.

It is preferable that the seed layer 35p is a metal film made of an alloy of Ta, Ru, or Ni (nickel) and iron. Alternatively, the seed layer 35p may be a metal film made of an alloy of Ni, Fe, and Cr (chromium). It may also be possible to form the seed layer 35p by laminating a plurality of metal films made of various kinds of alloy described above. It is preferable that the total thickness of the seed layer 35p is not less than 0.5 nm and not more than 10 nm, in particular, not less than 1.0 nm and not more than 8.5 nm.

It is preferable that the antiferromagnetic layer 35q is a metal film made of any of an alloy of Pt (platinum) and Mn (manganese), an alloy of Ir (iridium) and Mn (manganese), and an alloy of Ru and Mn. It is preferable that the thickness thereof is not less than 10 nm and not more than 30 nm, in particular, not less than 12 nm and not more than 25 nm.

It is preferable that the ferromagnetic layer 35r is a film made of a single metal or alloy of one or more kinds of metal selected from a group including Ni, Co (cobalt), Fe, B (boron). Alternatively, the ferromagnetic layer 35r may have a configuration in which a plurality of alloy layers that combine these materials appropriately is laminated. It is preferable that the total thickness of the ferromagnetic layer 35r is not less than 1.2 nm and not more than 3.0 nm, in particular, not less than 1.5 nm and not more than 2.5 nm.

It is preferable that the non-magnetic layer 35s is a metal film made of Ru and having a thickness not less than 0.4 nm and not more than 1.0 nm. It is most preferable that the thickness of the non-magnetic layer 35s to be not less than 0.6 nm and not more than 0.9 nm.

Further, it is preferable that the ferromagnetic layer 35t is made of the same material as that of the ferromagnetic layer 35r. Preferably, the thickness thereof is set to a thickness with which the amount of magnetization is substantially the same as that of the ferromagnetic layer 35r.

Preferably, the tunnel insulating film 38 is an insulating film made of any of AlOₓ (aluminum oxide), MgO (magnesium oxide), and HfO (hafnium oxide). It is preferable that the thickness thereof is not less than 0.5 nm and not more than 2.0 nm, in particular, not less than 0.6 nm and not more than 1.5 nm.

Preferably, the magnetization free layer 37 is a thin film formed by a ferromagnetic layer. Specifically, it is preferable that the magnetization free layer 37 is a film made of a single metal or alloy configured by one or more kinds of metal selected from a group including Ni, Co, Fe, B, Ru. Alternatively, the magnetization free layer 37 may have a configuration in which a plurality of thin films made of the different materials described above is laminated. It is preferable that the total thickness is not less than 2.0 nm and not more than 10 nm, in particular, not less than 3.0 nm and not more than 9.0 nm.

Next, for the thin film configuring the peripheral part of the wire main body 43 of the bit line 40, as the barrier metals 41a, 41b, 41f, preferably, a thin film of non-magnetic tantalum or TaN (tantalum nitride), that is, tantalum to which nitrogen is added, is used. This also applies to the barrier metal 48. As the cladding layers 41c, 41d and the cladding layer end part 41e, it is preferable to use a soft magnetic material having a high magnetic permeability and very low residual magnetism. Specifically, it is preferable to use an alloy, such as NiFe (nickel ferrite), NiFeMo, CoNbZr (cobalt niobium zirconium), CoFeNb, CoFeSiB, CoNbRu, CoNbZrMoCr, and CoZrCrMo, or an amorphous alloy. The liner film 410 and the liner film 49 are arranged so as to couple neighboring memory units in the horizontal direction in FIG. 4. Because of this, it is preferable that the liner film 410 and the liner film 49 are made of a dielectric (insulator) material, such as SiN, SiC, SiON, and SiOC, different from the barrier metal 41a etc.

As shown in FIG. 4, the barrier metals 41a, 41b, 41f are electrically conductive materials, and therefore, it is necessary to separate them between neighboring memory units. Further, it is preferable to couple the linger films 410, between neighboring memory units because they are dielectric materials. As long as the above-mentioned condition is met, it may also be possible to use an electrically conductive material or a dielectric material as a barrier layer, or to combine both.

The operation principles of the semiconductor device 200 having the above-mentioned configuration are explained. When an electric current is caused to flow through the digit line 50 (wire main body 51) or the bit line 40 (wire main body 43), the directions of magnetization of the magnetization free layers 37 of all the magnetoresistive elements 32 laminated thereover are changed. At this time, when the electric current that flows through the digit line 50 and the bit line 40 (or the magnetic field produced by the electric current) is lower than the electric current necessary to reverse the direction of magnetization, after the electric current is terminated, the directions of magnetization of the magnetization free layers 37 of all the magnetoresistive elements 32 return to the state before the electric current flows. This means the case where the magnetic field produced by the electric current is weaker than the magnetic field necessary to reverse the direction of magnetization of the magnetization free layer 37. However, when the electric current is higher than the electric current necessary to reverse the direction of magnetization of the magnetization free layer 37, the state is brought about where the directions of magnetization of the magnetization free layers 37 of all the magnetoresistive elements 32 laminated over the digit line 50 and the bit line 40 are reversed after the electric current is terminated. This means the case where the magnetic field produced by the electric current is stronger than the magnetic field necessary to reverse the direction of magnetization of the magnetization free layer 37.

By utilizing the characteristics described above, first, an electric current (first current) lower than the electric current necessary to reverse the direction of magnetization of the magnetization free layer 37 is caused to flow through any one of the digit line 50 and the bit line 40. Next, in this state, an appropriate current (second current) is caused to flow through the other of the digit line 50 and the bit line 40.

Here, the appropriate current means an electric current having a value necessary for the resultant magnetic field produced by the first current and the second current to be stronger than the magnetic field necessary to reverse the direction of magnetization of the magnetization free layer 37 of the magnetoresistive element 32 only in the region where the wires through which the first current and the second current are caused to flow intersect.

By doing so, the direction of magnetization of the magnetization free layer 37 is reversed only in the magnetoresistive element 32 in the region where the digit line 50 and the bit line 40 through which these currents are caused to flow intersect and thereby data is rewritten. That is, when data is rewritten, the selection of the magnetoresistive element 32 to be rewritten and the rewrite are performed at the same time.

Specifically, the direction of magnetization of the magnetization free layer 37 becomes the same as the direction of magnetization of the magnetization fixed layer 35 or the direction of magnetization of the magnetization free layer 37 becomes opposite the direction of magnetization of the magnetization fixed layer 35. The electrical resistance of the magnetoresistive element 32 when the direction of magnetization of the magnetization free layer 37 is the same as the direction of magnetization of the magnetization fixed layer 35 is different from that when the direction of magnetization of the magnetization free layer 37 is opposite to the direction of magnetization of the magnetization fixed layer 35. The difference in the electrical resistance is utilized as information corresponding to “0” or “1”.

When the information of the selected magnetoresistive element 32 is read, the MOS transistor 10 coupled to the selected magnetoresistive element 32 is turned ON.

Then, a voltage is applied across the MOS transistor 10 and the bit line 40 and thus the resistance value of the selected magnetoresistive element 32 is detected and the electrical information stored in the magnetoresistive element 32 can be read.

Here, particularly, in order to cause the magnetic field produced by the electric current that flows through the bit line 40 to act on the magnetization free layer 37 of the magnetoresistive element 32 intensively, the cladding layer 41c is arranged so as to surround the lateral side of the wire main body 43 and the cladding layer 41d is arranged so as to surround the upper side of the wire main body 43. By doing so, the magnetic field produced by the electric current that flows through the bit line 40 (wire main body 43) concentrates inside the cladding layers 41c, 41d. This results from the magnetic shield effect of the cladding layers 41c, 41d having a high magnetic permeability.

Therefore, it possible to cause the magnetic field to act intensively on the magnetization free layer 37 of the magnetoresistive element 32 immediately under the bit line. Further, the cladding layer 41c on the lateral side of the wire main body 43 and the cladding layer 41d above the wire main body 43 are coupled at the upper end part of the cladding layer 41c on the lateral side. That is, the cladding layer 41c on the lateral side of the wire main body 43 and the cladding layer 41d on the upper side are continuous with each other. In a region A also, which is surrounded by a circular dotted line in FIG. 7, cladding layers extending in different directions are coupled with each other.

If the cladding layer 41c and the cladding layer 41d are discontinuous in part of the region, the magnetic field (magnetic flux) that runs through the inside of the cladding layers 41c, 41d leaks to the outside of the cladding layers in the discontinuous region where cladding layers are separated. If the magnetic field (magnetic flux) that has leaked enters, for example, the magnetoresistive element 32 of the neighboring memory unit shown in FIG. 4, information is written erroneously to the magnetoresistive element 32, and therefore, there is a possibility that an erroneous operation results. As described above, when the cladding layer 41c and the cladding layer 41d are continuous with each other, it is possible to suppress the leakage of the magnetic field, to cause the magnetic field to concentrate on the magnetoresistive element 32 of the memory unit selected by the semiconductor device 200, and to efficiently supply accurate information from the magnetoresistive element 32.

As to the thickness of the cladding layer, it is preferable that a thickness W1 (of the cladding layer 41c) on the lateral side of the wire main body 43 shown in FIG. 4 is greater than a thickness W2 (of the cladding layer 41d) on the upper side of the wire main body 43. The leakage of the magnetic field toward the neighboring magnetoresistive element 32 tends to occur from the lateral side rather than from the upper side of the magnetoresistive element 32 and the wire main body 43. Because of this, by setting W1 greater than W2, it is possible to enhance the magnetic shield effect of the cladding layer 41d and to suppress the leakage of magnetic field more securely. That is, it is possible to suppress an erroneous operation due to the leakage of magnetic field to the magnetoresistive element 32 neighboring the magnetoresistive element 32 in question.

Even if the thickness W2 is not set as great as W1, the possibility that erroneous information is written to the magnetoresistive element 32 of the neighboring memory unit is small. It is rather preferable to set W2 smaller than W1. By reducing W2, it is possible to improve the shape controllability when processing the cladding layer 41d. Thus, it is possible to suppress variations in magnitude of electric current (variations in produced magnetic field) with which information among the bit lines 40 and the digit lines 50 is written. By reducing W2, the thickness of the wire main body 43 can be increased relatively, and therefore, it is possible to reduce the resistance of the bit line 40.

Specifically, it is preferable that W1 is not less than 10 nm and not more than 30 nm, in particular, not less than 15 nm and not more than 25 nm. It is preferable that W2 is not less than 5 nm and not more than 20 nm, in particular, not less than 10 nm and not more than 15 nm.

The barrier layers (the barrier metal 41a and the liner film 410 over the top surface of the wire main body 43) are arranged so as to be sandwiched between the wire main body 43 and the cladding layer 41d to suppress the mutual diffusion of, for example, the copper atoms configuring the wire main body 43 and the atoms of the metal material configuring the cladding layers 41c, 41d. The barrier metals 41b, 41f (protective layers) are arranged so as to be sandwiched between an insulating layer 47 and the insulating layer 360 in direct contact therewith, and the cladding layer 41d to suppress the mutual diffusion of, for example, the silicon atoms configuring the insulating layers 47, 360 and the atoms of the metal material configuring the cladding layers 41c, 41d. In other words, the protective layer is arranged so as to cover the surface of the cladding layer facing the barrier layer and the surface on the opposite side (that is, the outer surface of the cladding layer in FIG. 4).

That is, by the arrangement of the barrier metal 41a and the liner film 410 as the barrier layer and further of the protective layers (insulating layers 47, 360) as shown in FIG. 7, it is possible to suppress the mutual diffusion of the atoms in the directions indicated by the arrows in FIG. 7 and to suppress the transformation and deformation of the wire main body 43, the cladding layers 41c, 41d, etc.

In order to give the sufficient function to suppress the mutual diffusion as described above, it is preferable that the thickness of the barrier metals 41a, 41f is not less than 3 nm and not more than 25 nm, in particular, not less than 10 nm and not more than 20 nm. If the thickness of the barrier metals 41a, 41f exceeds the above-described range, the region surrounded by the barrier metals becomes smaller and the sectional area of the wire main body 43 becomes smaller. As a result, there is a possibility that the resistance against the electric current that flows through the wire main body 43 becomes larger. Because of this, it is preferable to set the thickness of the barrier metals within the range described above.

It is preferable that the thickness of the liner film 410 is not less than 10 nm and not more than 80 nm, in particular, not less than 40 nm and not more than 70 nm. When the thickness becomes smaller than the lower limit value, there is a possibility that the quality of the copper wire of the wire main body 43 is reduced and the reliability of the wire is reduced. When the thickness exceeds the upper limit value, the region occupied by the liner film 410 is increased, and therefore, there is a possibility that the processing of a thin film becomes difficult. Thus, it is preferable to set the thickness of the liner film 410 within the range described above.

It is preferable to design a distance B from the outermost side (the outermost side of the barrier metal 41b) in the region in conduction with the wire main body 43 shown in FIG. 8 to the outermost side of the cladding layer end part 41e shown in FIG. 7 so that the distance to the outermost side in the region in conduction with the wire main body 43 of the memory units neighboring in the horizontal direction in FIG. 7 and FIG. 8 is wide enough to be capable of suppressing the deterioration of the TDDB (Time Dependent Dielectric Breakdown) characteristics between lines.

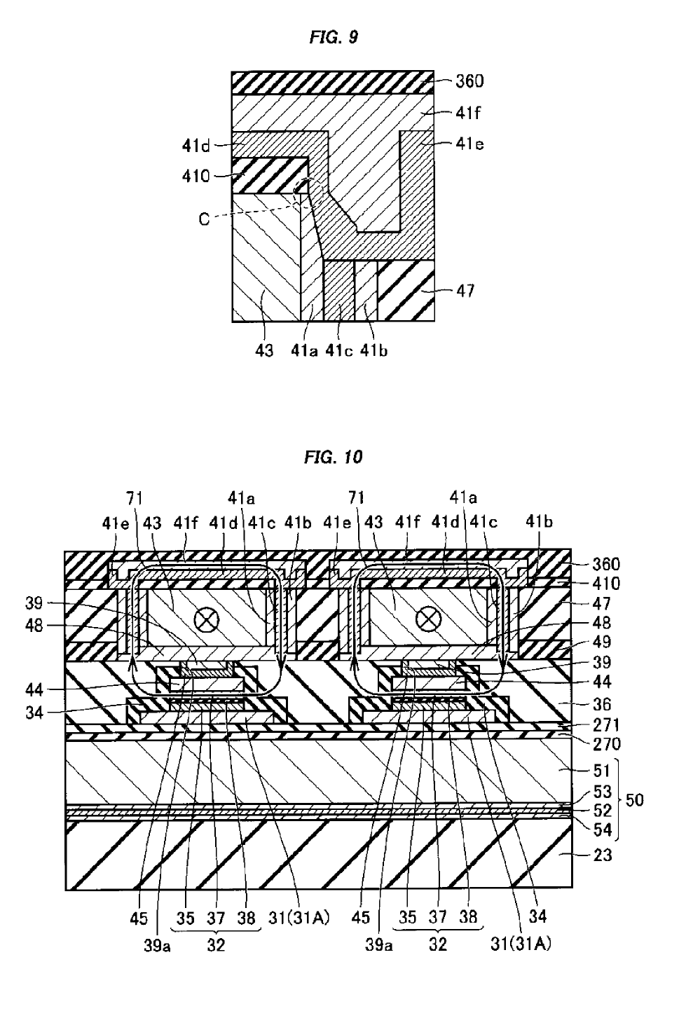

In the vicinity of the cladding layer end 41e, it is not necessary to cause the cladding layer 41c and the cladding layer 41d to intersect substantially perpendicularly. For example, as shown in FIG. 9, in the vicinity of the region where the cladding layer 41c and the cladding layer 41d are coupled (over the section intersecting with the direction in which the wire main body 43 extends), it may also be possible for the cladding layer to extend so as to form an acute angle with both the cladding layer 41c and the cladding layer 41d. In the region also, where the cladding layer is inclined, as shown in a region C surrounded by a circular dotted line, the barrier metal 41a and the liner film 410 are sandwiched between the cladding layer and the wire main body. Thus, it is possible to suppress the above-described mutual diffusion.

Here, a case is considered, where an electric current is caused to flow through the wire main body 43 from the front side to the deep side in the direction perpendicular to the plane of the paper. In this case, a magnetic line of force 71 in the clockwise direction in FIG. 10 is produced by the electric current through the wire main body 43. The magnetic line of force 71 acts on the magnetization free layer 37 of the magnetoresistive element 32 and reverses the direction of magnetization of the magnetization free layer 37. At this time, in the present first embodiment, it is possible to reduce the possibility that the magnetic line of force 71 that passes through the inside of the cladding layers 41c, 41d of one memory unit leaks toward the cladding layers 41c, 41d of the neighboring memory unit. This is because the cladding layers 41c, 41d between the neighboring memory units are separated from each other as shown in FIG. 10.

When the cladding layer 41c and the cladding layer 41d of one memory unit are continuous, the magnetic line of force 71 passes through the inside of the region in the shape of a loop composed of the cladding layers 41c, 41d due to the magnetic shield effect of the cladding layers 41c, 41d. If the cladding layers 41c between the neighboring memory units (such as the liner films 49, 410) are continuous, the magnetic line of force 71 that passes through the inside of the cladding layer 41c in one memory unit travels along the direction (in the horizontal direction in FIG. 10) in which the cladding layer that couples the neighboring memory units extends. That is, the magnetic line of force 71 travels toward the neighboring memory unit as a result. If this happens, there is a possibility of an erroneous operation because the neighboring memory unit not selected is affected by the magnetic line of force 71.

Because of this, as shown in FIG. 10, it is preferable to separate the cladding layers between neighboring memory units. By doing so, it is possible to suppress the leakage of the magnetic field to the neighboring memory unit. Thus, as shown in FIG. 10, it is possible to cause the magnetic line of force 71 to travel intensively toward the magnetoresistive element 32 (under the wire main body 43) of the memory unit selected by the semiconductor device 200 and to further improve the effect of supplying accurate information highly efficiently from the selected magnetoresistive element 32.

Next, a method of manufacturing the semiconductor device 200 described above will be explained. First, a process for preparing a backing wire is performed. Specifically, the process includes a process for preparing a semiconductor substrate having a main surface and a process for forming a backing circuit to form a memory unit over the main surface of the semiconductor substrate.

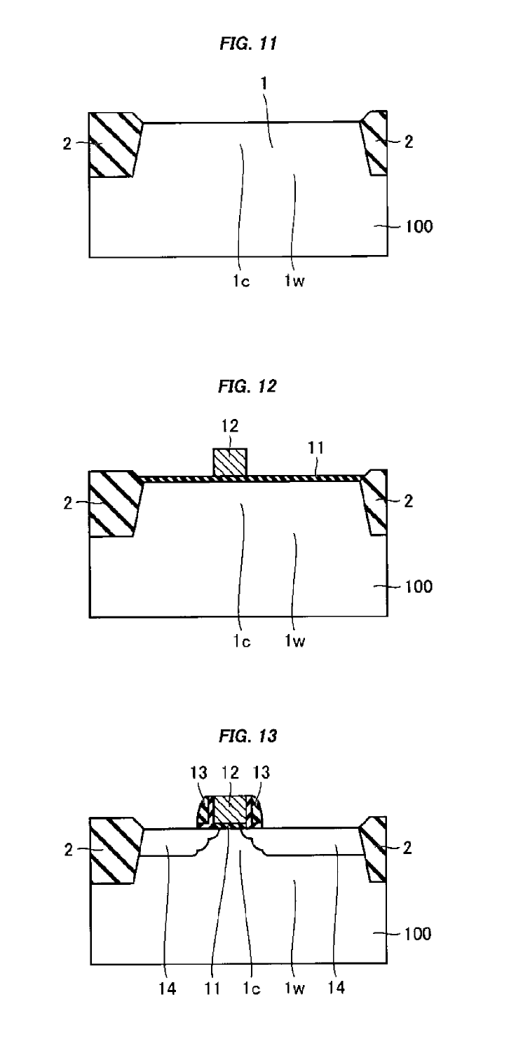

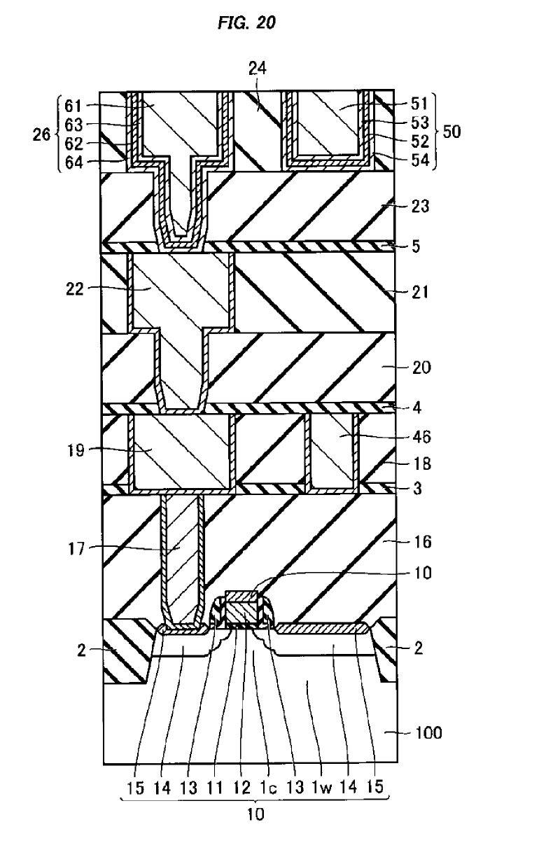

FIG. 11 to FIG. 18, and FIG. 20 to FIG. 27 are section views showing an aspect in each process when viewed in the same direction as that in FIG. 3. As shown in FIG. 11, the semiconductor substrate 100 having a main surface is prepared. The separation insulating film 2 is formed over the main surface of the semiconductor substrate 100. By the separation insulating film 2, an active region 1 is formed over the main surface of the semiconductor substrate 100.

Next, impurities are introduced into the active region by the ion implantation method etc. and a well region 1w and a channel region 1c are formed sequentially.

As shown in FIG. 12, by the thermal oxidation processing method, the gate insulating film 11 is formed over the main surface of the channel region 1c. Subsequently, a polycrystalline silicon film etc. is deposited and the gate electrode 12 is formed over the gate insulating film 11 by patterning the polycrystalline silicon film etc.

Next, as shown in FIG. 13, by using the gate electrode 12 as a mask, predetermined conduction-type impurities are introduced into the active region 1. Further, an insulating film, such as a silicon oxide film, is formed on the side surface of the gate electrode 12 and after the formation of the insulating film, impurities are introduced again into the active region 1.

After impurities are introduced for the second time, an insulating film, such as a silicon oxide film and a silicon nitride film, is deposited. The sidewall 13 is formed by dry-etching the deposited insulating film. After forming the sidewall 13, impurities are introduced into the channel region 1c again. Due to this, the impurity region 14 that functions as a source or a drain is formed.

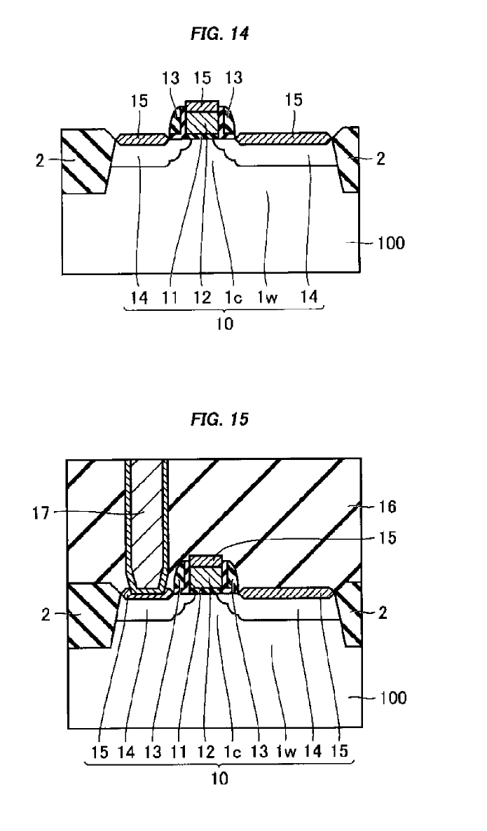

As shown in FIG. 14, a metal film is formed by sputtering and by patterning the metal film, the metal film 15 is formed in the top surface of the impurity region 14 and in the top surface of the gate electrode 12. In this manner, the MOS transistor 10 is formed.

As shown in FIG. 15, after forming the MOS transistor 10, for example, an insulating layer 16 formed by a silicon oxide film etc. is formed so as to cover the MOS transistor 10.

A contact hole is formed by subjecting the insulating layer 16 formed to photolithography and etching. The contact hole is formed so as to reach the metal film 15 formed over the impurity region 14.

After that, by sputtering etc., a barrier metal is formed on the inner surface of the contact hole. After the barrier metal is formed, the contact hole is filled with an electrically conductive film of copper etc. and by subjecting the electrically conductive film to the CMP (Chemical Mechanical Polishing) processing, a unit contact part 17 is formed.

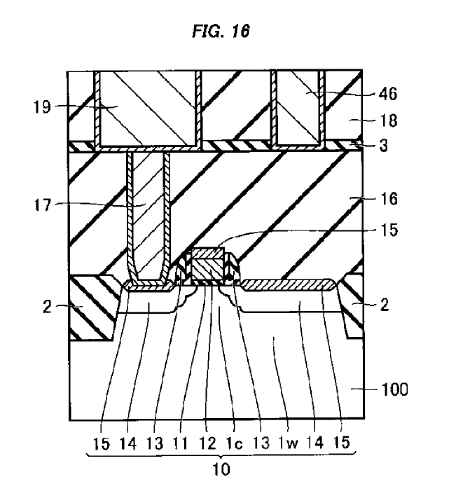

Next, as shown in FIG. 16, the insulating film 3 and an insulating layer 18 are formed sequentially over the top surface of the insulating layer 16. Then, a groove part is formed in the insulating layer 18 and the insulating film 3. A barrier metal is formed in the groove part formed and the groove part is filled with an electrically conductive film. By flattening the electrically conductive film, a unit contact part 19 and the source wire 46 are formed in the insulating layer 18 and the insulating film 3.

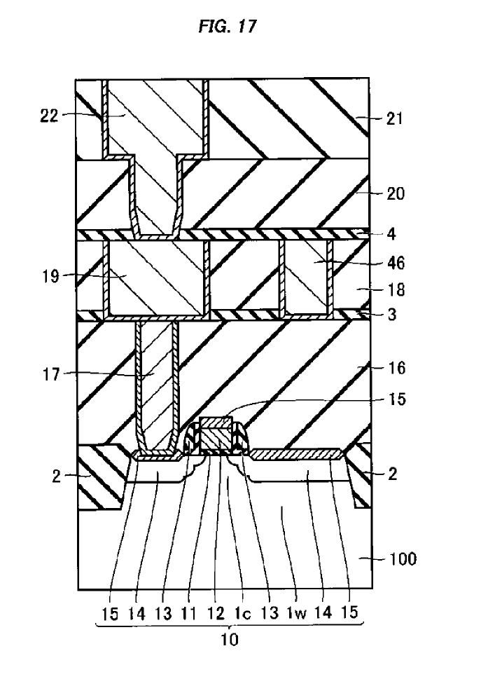

Next, as shown in FIG. 17, the insulating film 4, insulating layers 20, 21 are formed sequentially. After that, a hole part is formed in the insulating films 4, 20, 21 and a barrier metal is formed on the inner surface of the hole part. By filling an electrically conductive film over the barrier metal and flattening the electrically conductive film, a unit contact part 22 is formed.

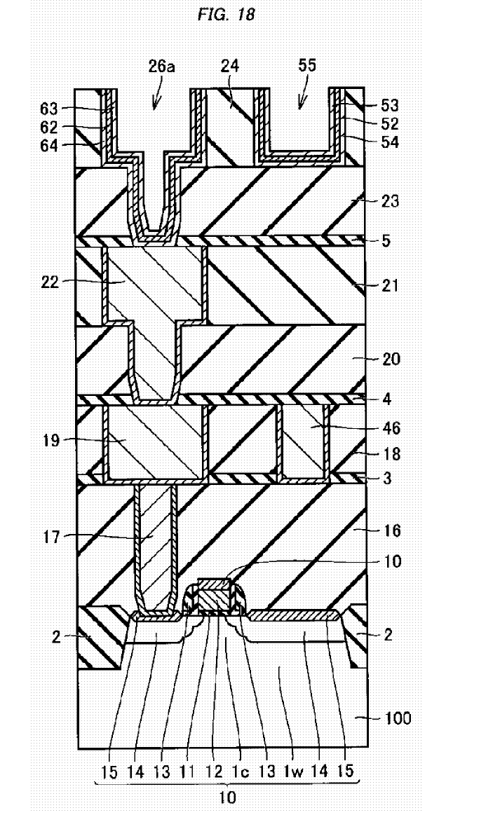

As shown in FIG. 18, the insulating film 5, and the insulating layers 23, 24 are formed sequentially over the top surface of the insulating layer 21. After that, a contact hole 26a is formed in the insulating films 5, 23, 24 and at the same time, a digit wire groove part 55 is formed in the insulating layer 24.

Then, the barrier metal 64 is formed in the contact hole 26a and at the same time, a barrier metal 54 is formed on the inner surface of the digit wire groove part 55. Preferably, these metals are made of the same material as that of the barrier metals 41a, 41b, 41f, 48 described above.

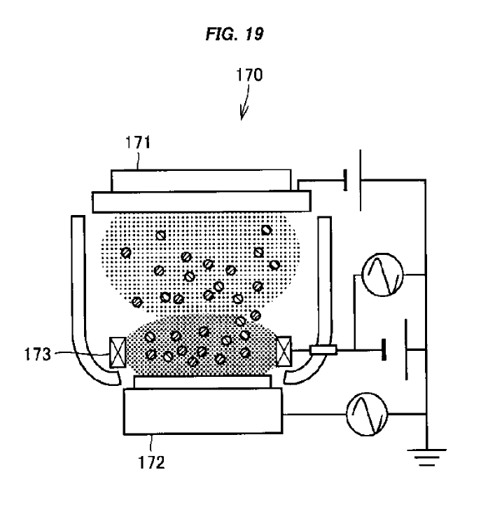

The barrier metals 54, 64 are formed by using a sputtering device 170 shown in FIG. 19. The sputtering device 170 is arranged in the chamber and comprises a stage 172 in the top surface of which a semiconductor substrate during manufacturing process is arranged, a target 171 on which a target is arranged, a direct current coil 173, and a high frequency coil 174.

Then, by the magnetic force produced by the direct current coil 173 and the high frequency coil 174, it is possible to adjust the directionality of the particle in the chamber.

When forming the barrier metals 54, 64, to the stage 172, an alternating current power of about, for example, 200 W to 230 W is applied. Then, the side coverage of the barrier metals 54, 64 can be increased.

Here, the side coverage is a ratio of the film forming rate at which a film is formed on the inner surfaces of the contact hole 26a and the digit wire groove part 55 to the reference film formation rate at which a film is formed in the top surface of the insulating layer 24 shown in FIG. 18.

After the barrier metals 54, 64 are formed, a cladding layer 52 and the cladding layer 62 shown in FIG. 18 are formed. Preferably, these cladding layers are made of the same material as that of the cladding layer 41d described above.

When forming the cladding layers 52, 62, to the high frequency coil 174, a power of about, for example, 2,000 W is applied. To the direct current coil 173, a power of about, for example, 0 W to 500 W is applied. Further, the pressure in the chamber is set to about 0.2 Pa. Furthermore, a predetermined power is applied to the target 171 and the stage 172.

When the cladding layer is formed under the conditions described above, the film formation rate at which a film is formed on the inner surface of the barrier metal 54 becomes higher than the film formation rate at which a film is formed on the bottom of the barrier metal 54.

That is, the side coverage when forming the cladding layer is higher than that when forming the barrier metal 54.

The side coverage when forming the cladding layer is a ratio of the film formation rate of the cladding layer formed on the inner surfaces of the barrier metals 54, 64 to the reference film formation rate of the cladding layer formed in the top surface of the insulating layer 24. Due to this, the thickness of the sidewall part of the cladding layer 52 to be formed is greater than that of the bottom wall part.

As described above, after forming the cladding layer, a barrier metal 53 and the barrier metal 63 are formed over the top surface of the cladding layer. The film formation conditions of the barrier metals 53, 63 are set to be the same as those of the barrier metals 54, 64.

After forming the barrier metals 53, 63, an electrically conductive film of copper etc. is filled over the barrier metals 53, 63. After filling the electrically conductive film, the unit contact part 26 and the digit line 50 are formed by flattening the top surface of the insulating layer 24 by the CMP method as shown in FIG. 20. Then, it is possible to form the unit contact part 26 at the same time as the formation of the digit line 50.

In this manner, by sequentially laminating the insulating layer 16, the insulating film 3, the insulating layer 18, the insulating film 4, the insulating layer 20, the insulating layer 21, the insulating film 5, the insulating layer 23, and the insulating layer 24, the interlayer insulating film 9 is formed.

Further, by sequentially forming the unit contact parts 17, 19, 22, 26, the coupling wire 8 is formed.

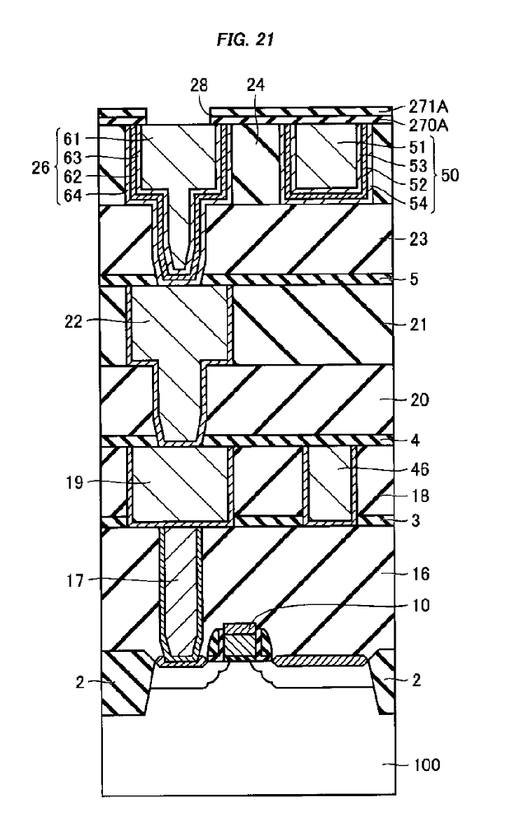

Next, as shown in FIG. 21, over the top surface of the insulating layer 24, an insulting film 270A formed by a silicon nitride film (SiN) etc. is formed. Over the top surface of the insulating film 270A, an insulating film 271A formed by a silicon oxide film (SiO₂) etc. is formed. In these insulating films, a through-hole 28 is formed.

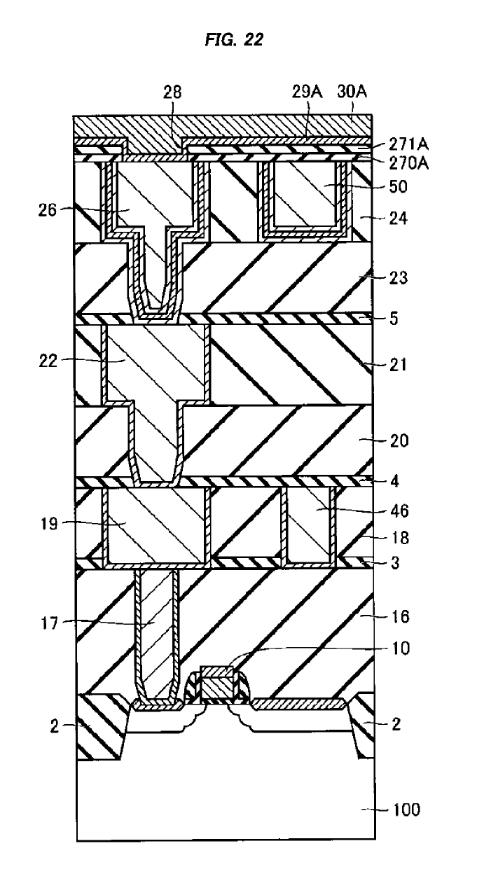

Then, as shown in FIG. 22, a barrier metal 29A is formed over the insulating films 270A, 271A and on the inner circumferential surface of the through-hole 28. An electrically conductive film 30A is deposited over the barrier metal 29A.

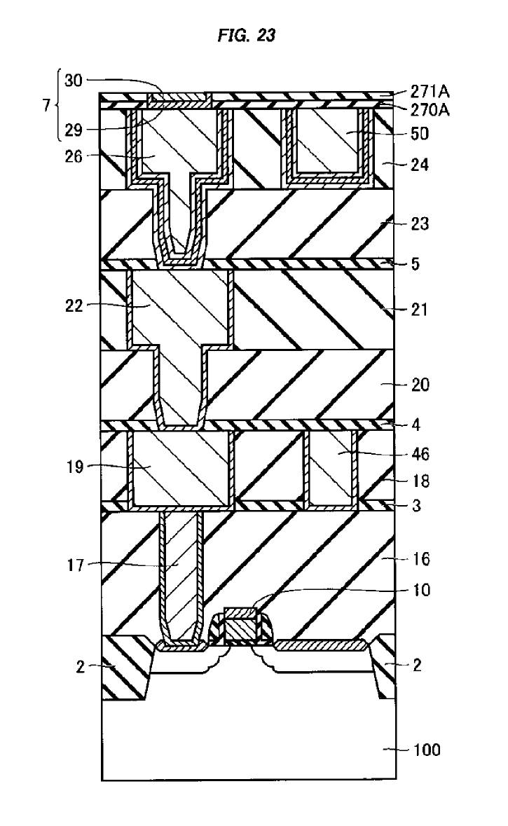

After that, as shown in FIG. 23, by the CMP method, the barrier metal 29A and the electrically conductive film 30A formed over the insulating film 271A are removed using the insulating film 270A as a stopper film.

In this manner, a coupling part 7 including a barrier metal 29 and an electrically conductive film 30 is formed. On the other hand, the top surfaces of the insulating films 270A, 271A are flattened and the flat insulating films 270, 271 are formed.

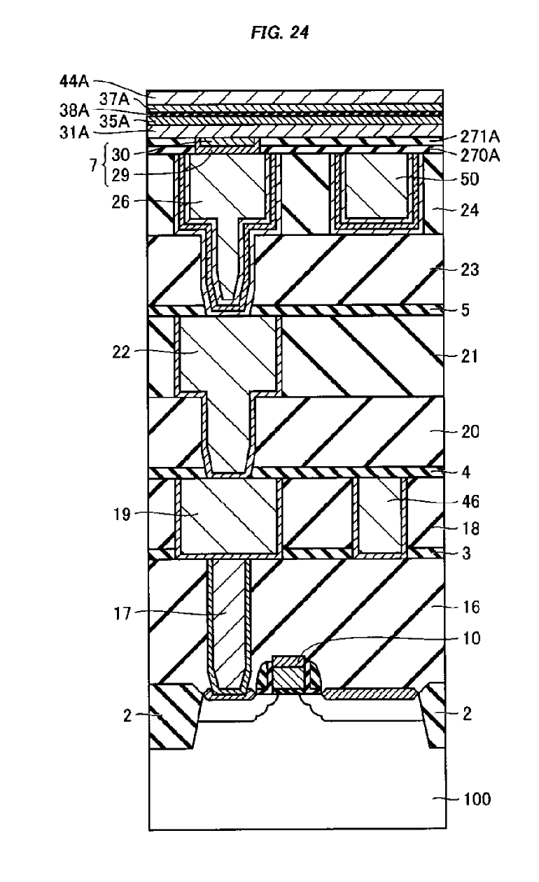

Next, as shown in FIG. 24, an electrically conductive film 31A is formed over the flat insulating film 271A (coupling part 7) and an electrically conductive film 35A, an insulating film 38A, an electrically conductive film 37A, and an electrically conductive film 44A are formed in this order over the electrically conductive film 31A. The electrically conductive film 31A is a layer that should become the lower electrode 31 and the electrically conductive film 35A, the insulating film 38A, the electrically conductive film 37A, and the electrically conductive film 44A are layers that should become the magnetization fixed layer 35, the tunnel insulating film 38, the magnetization free layer 37, and the upper electrode 44, respectively. Because of this, it is preferable to select the material configuring each layer described above and set the thickness thereof so that the material thereof is the same material configuring the lower electrode 31, the magnetization fixed layer 35, etc., and the thickness thereof is the same as that of them.

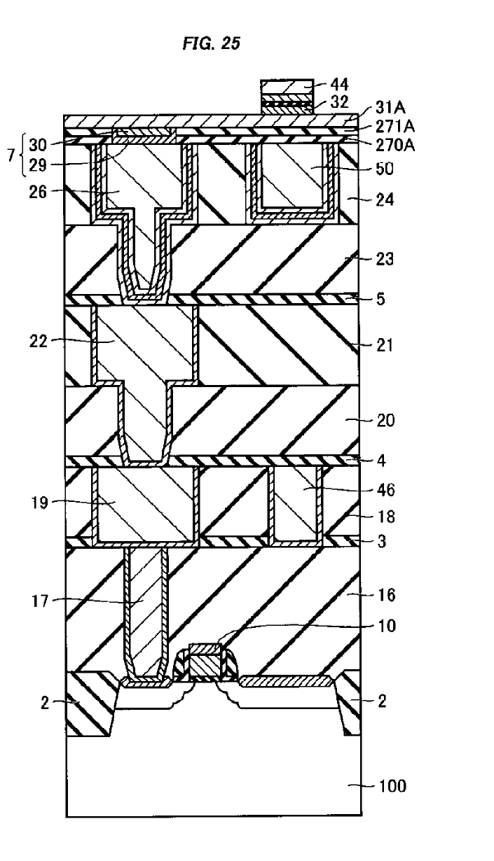

As shown in FIG. 25, by patterning the electrically conductive film 35A, the insulating film 38A, the electrically conductive film 37A, and the electrically conductive film 44, the magnetoresistive element 32 and the upper electrode 44 formed over the top surface of the magnetoresistive element 32 are formed.

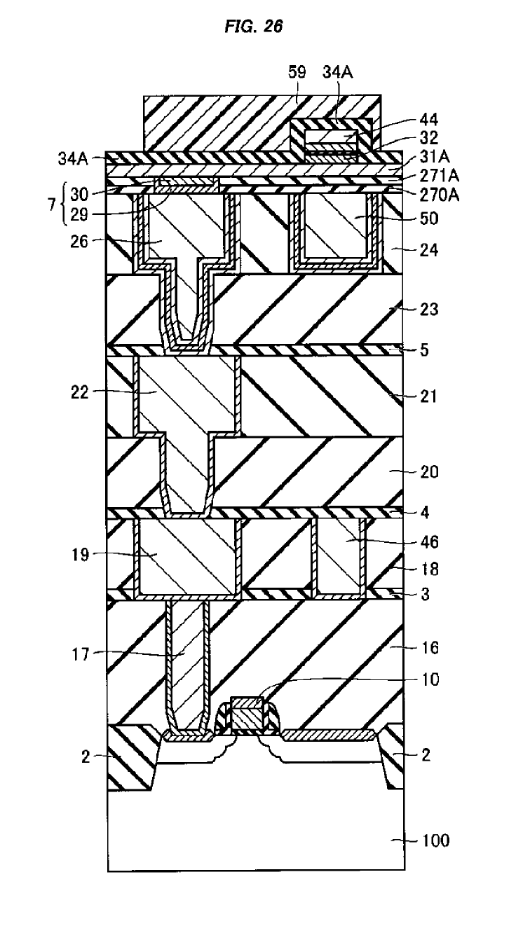

As shown in FIG. 26, an insulating film 34A formed by a silicon nitride film etc. is formed as a liner film over the electrically conductive film 31A so as to cover the magnetoresistive element 32. The insulating film 34A is a layer that should become the insulating film 34 (protective film). The insulating film 34 serves to suppress trouble, such as a leakage of a magnetic field, when the side surfaces, particularly, of the magnetization free layer 37 and the magnetization fixed layer 35 configuring the magnetoresistive element 32 are oxidized. Preferably, the insulating film 34A is formed by using the CVD (Chemical Vapor Deposition) method etc. It is preferable that the thickness of the insulating film 34A is not less than 10 nm and not more than 80 nm, in particular, not less than 40 nm and not more than 70 nm.

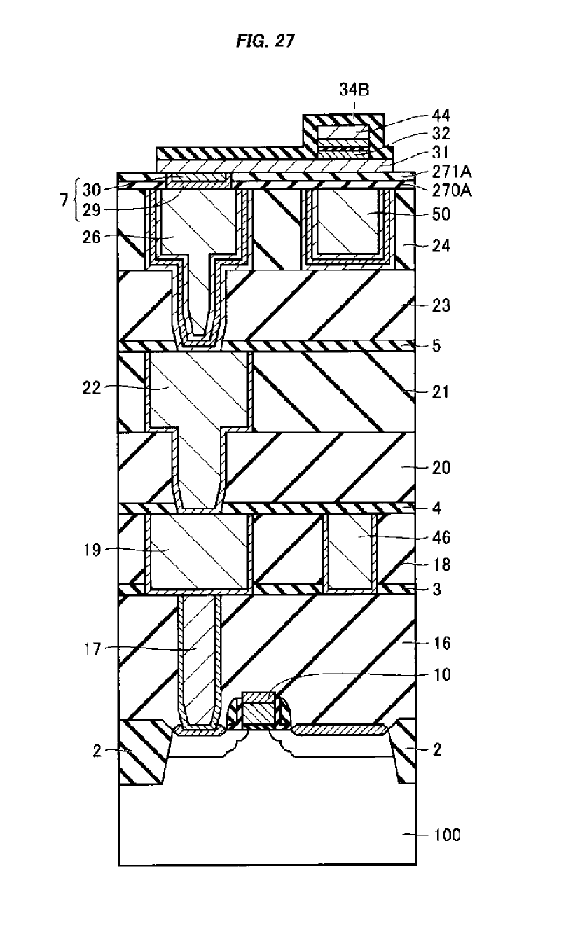

Over the insulating film 34A, a resist film is formed and by patterning the resist film to form the lower electrode 31, a resist pattern 59 is formed. By patterning the insulating film 34A and the electrically conductive film 31A using the resist pattern as a mask, an insulating film 34B and the lower electrode 31 are formed as shown in FIG. 27.

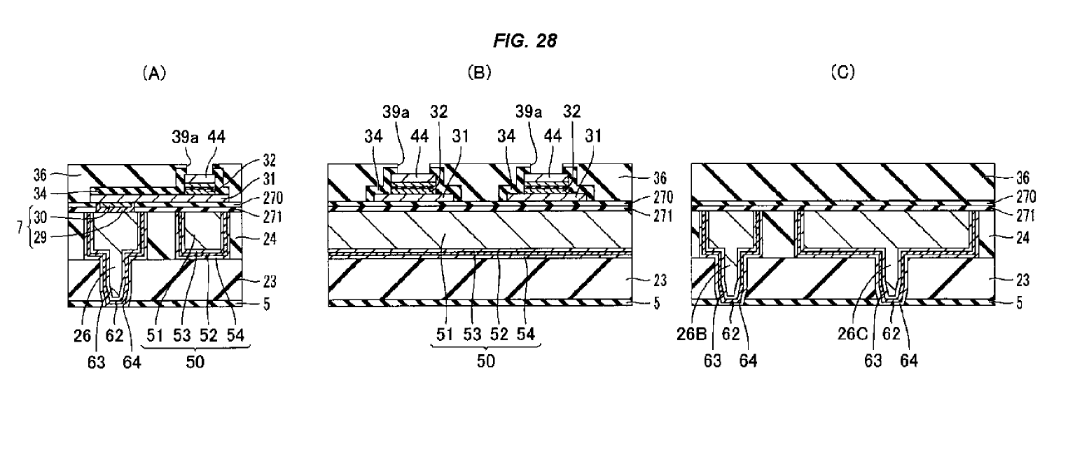

Hereinafter, in FIG. 28 to FIG. 36, the processes that follow FIG. 27 are aspects of only the upper side than the insulating film 5 in FIG. 27 and the side lower than the insulating layer 21 in FIG. 27 is omitted and not shown schematically. Each Fig. (A) shows a diagram when viewed in the same direction as that in FIG. 27 and Fig. (B) is a diagram when the region on the side upper than the insulating film 5, similar to Fig. (A), is viewed in the direction intersecting with the direction in FIG. 27, that is, in the same direction as that in FIG. 4. Then, Fig. (C) is a diagram showing an aspect of the part of the peripheral circuit part described above in the same layer (the region on the upper side than the insulating film 5) as that in each of Fig. (A) and Fig. (B) relative to the direction of lamination.

As shown in FIGS. 28(A) (B), an insulating layer including a silicon oxide film etc. is formed so as to cover over the insulating film 34B of the magnetoresistive element 32 in FIG. 27 and the perimeter of the lower electrode 31 and the insulating layer is subjected to the CMP processing. Then, a resist pattern to form a contact hole 39a is formed over the insulating layer. After that, by using the resist patter, the contact hole 39a is formed. In this manner, an insulating layer 36 and the insulating film 34 having a desired shape are formed.

The peripheral circuit part shown in FIG. 28(C) is in the condition in which the unit contact part 26 in FIG. 5 is formed. In this region, the memory unit is not present, and therefore, the aspect in the process in FIG. 28 remains unchanged.

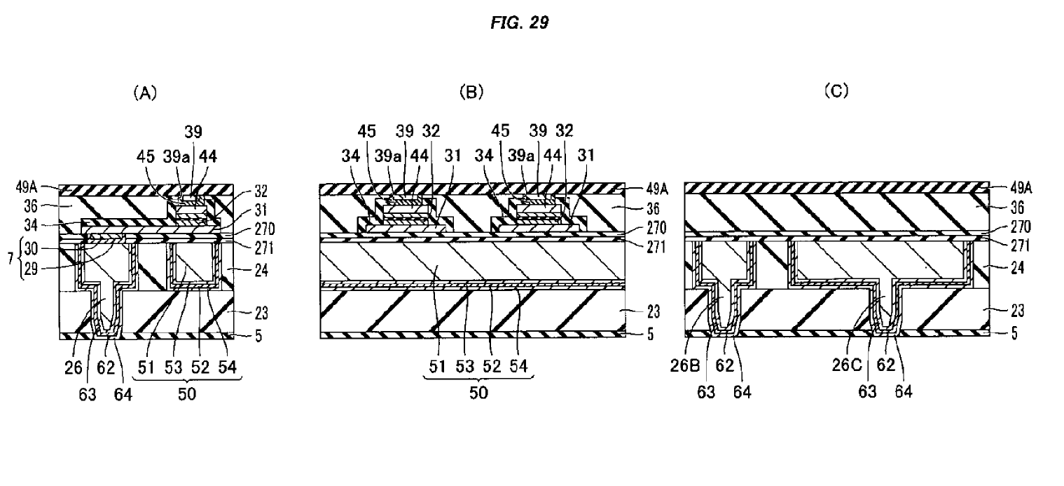

Next, a barrier metal is formed on the uppermost surface of the insulating layer 36 and on the inner surface of the contact hole 39a in FIG. 28 and further, the contact hole 39a in which the barrier metal is formed is filled with an electrically conductive film. Then, the electrically conductive film and the barrier metal are flattened by the CMP processing. In this manner, a barrier metal 45 and the electrically conductive film filled in the contact hole 39a are formed and thereby the contact part 39 is formed. The electrically conductive film may be made of copper like the wire main body 43, however, it may be made of W (tungsten). When the electrically conductive film is made of copper, preferably, the barrier metal 45 is made of Ta or TaN, however, when the electrically conductive film is made of tungsten, preferably, the barrier metal 45 is made of Ti (titanium) or TiN (titanium nitride). After that, a liner film 49A, which should become the liner film 49, is formed on, for example, the entire surface over the insulating layer 36 including the contact part 39. That is, it is preferable to form the liner 49A so that the material and thickness of the liner film 49 are desired ones. It is preferable to form the liner film 49A by the CVD (Chemical Vapor Deposition) method etc. It is preferable that the thickness of the liner film 49A is not less than 10 nm and not more than 80 nm, in particular, not less than 40 nm and not more than 70 nm. In this manner, those shown in FIGS. 29(A) to (C) are obtained.

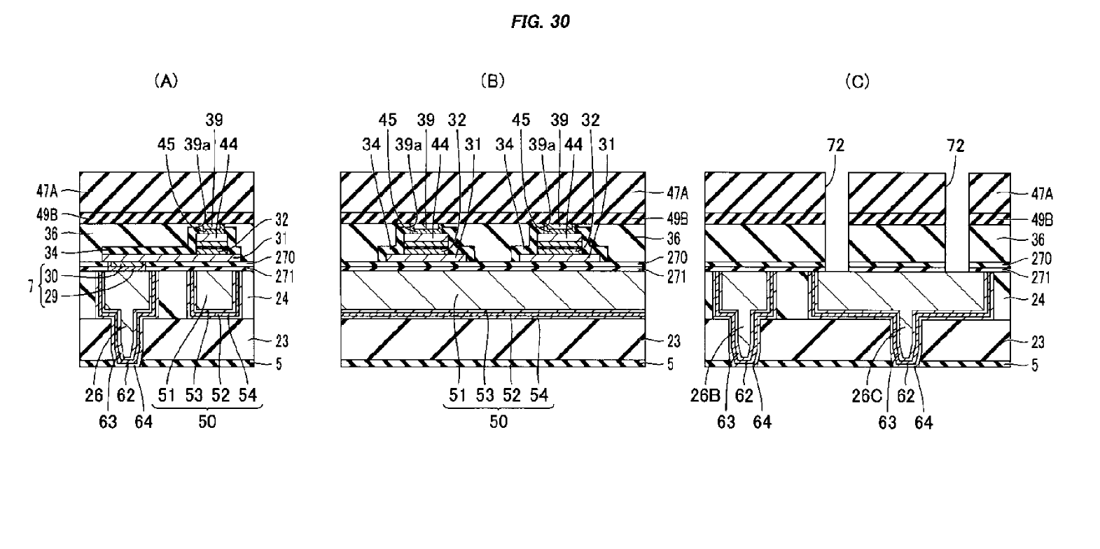

Next, over the uppermost surface of the liner film 49A, an insulating layer 47A including a silicon oxide film etc. is formed by the CVD method etc. Photolithography, etching, etc., are performed so that an opening referred to as a via 72 is formed in the region of the insulating layer 47A, particularly, the region corresponding to the upper part of the unit contact part 26C of the peripheral circuit part. The via 72 is formed by etching the liner film 49A at the upper part of the unit contact part 26C and the flat insulating films 270, 271. In this manner, those as shown in FIGS. 30(A) to (C) are obtained (the liner film 49A becomes a liner film 49B).

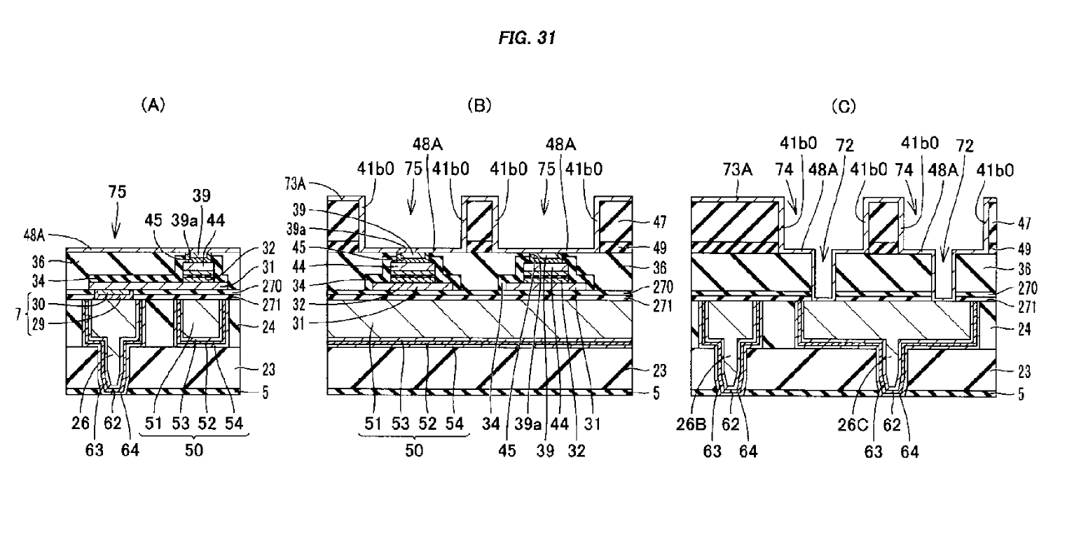

Next, photolithography, etching, etc., are performed so that the region of the insulating layer 47A and the liner film 49B, particularly, the region corresponding to the upper part of the magnetoresistive element 32 and the region around the via 72 are removed. In this manner, as shown in FIGS. 31(B) (C), a groove 75 is formed in the upper part of the magnetoresistive element 32 and a groove 74 is formed in the upper part of the unit contact part 26C. The region in which the insulating layer 47A is not etched becomes the insulating layer 47 and the region in which the liner film 49B is not etched becomes the liner film 49. As shown in FIGS. 31(A) (B), the groove 75 extends so as to spread over the upper parts of the neighboring magnetoresistive elements 32.

Then, as shown in FIGS. 31(A) to (C), barrier metals are formed on the uppermost surface that is exposed, that is, the uppermost surface of the insulating layer 36, on the inner surface of the grooves 75, 74, the via 72, etc., by sputtering etc. Preferably, these barrier metals are made of Ta or TaN. These barrier metals are formed simultaneously as a single unit and here, the barrier metal formed on the uppermost surface of the insulating layer 47 is referred to as a barrier metal 73A, that formed on the inner surface of the grooves 75, 74 as a barrier metal 41b0, and that formed on the inner bottom of the grooves 75, 74 as a barrier metal 48A.

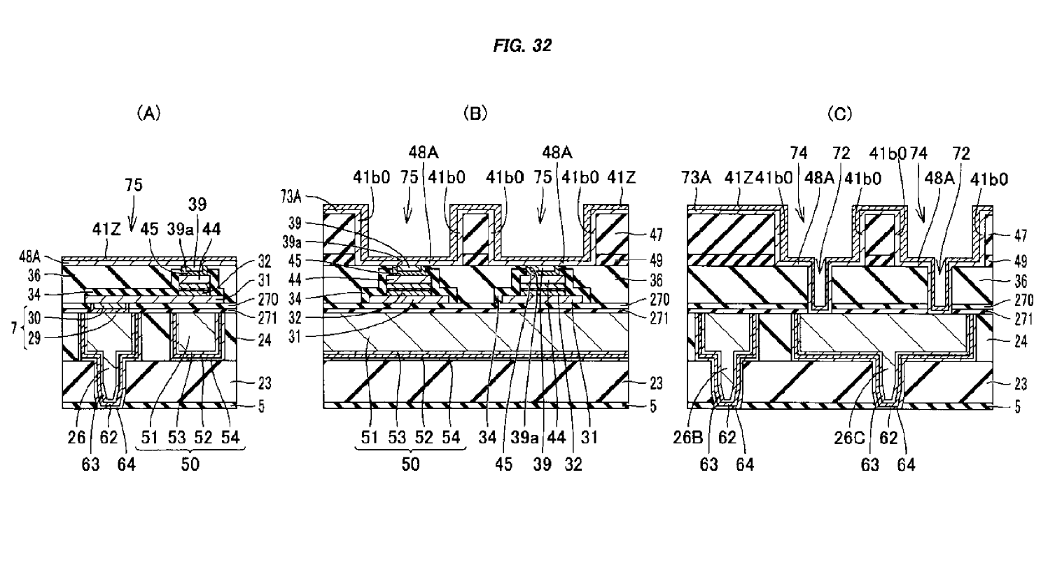

Next, on the uppermost surface that is exposed, that is, over the surfaces of the barrier metals 73A, 41b0, 48A described above, a cladding layer 41Z is formed at a time. The cladding layer 41 Z is a layer that should become the cladding layer 41c in FIG. 4, FIG. 5. Consequently, it is preferable to form the cladding layer 41Z so that the material and thickness thereof are the same as those of the cladding layer 41c. In this manner, the aspects shown in FIGS. 32(A) to (C) are brought about.

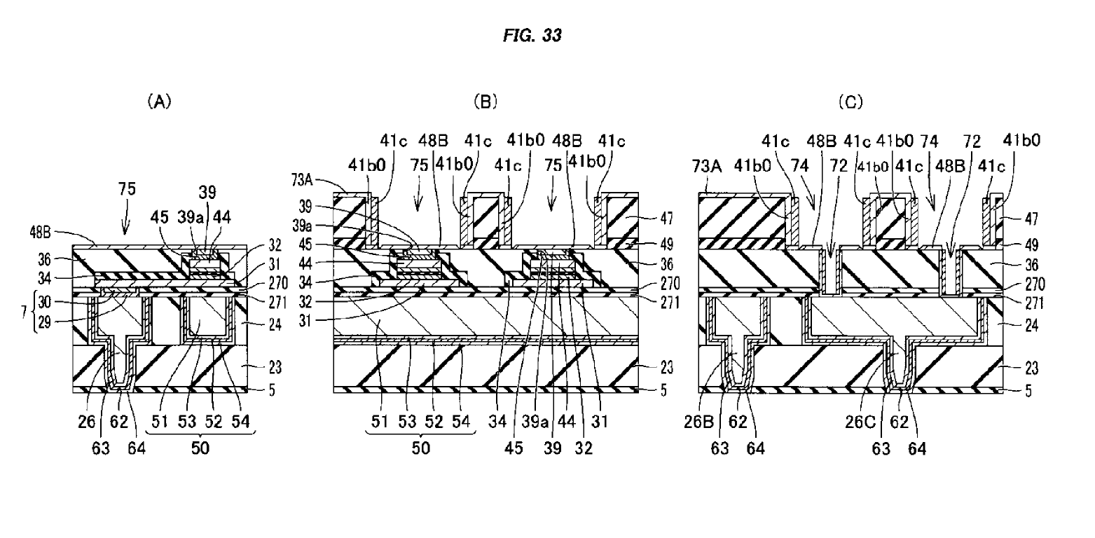

Next, the component of the cladding layer 41Z along the direction of the main surface (surface intersecting with the direction of lamination) of the insulating layer 36 is removed by sputtering etc. Due to this, only the cladding layer formed on the side surface remains as the cladding layer 41c as shown in FIGS. 33(A) to (C). At this time, the etching rate at the time of sputtering at the end part is high, and therefore, there may be a case where the end part of the barrier metal 48A in FIGS. 33(B) (C) is etched in an oblique direction and becomes a barrier metal 48B.

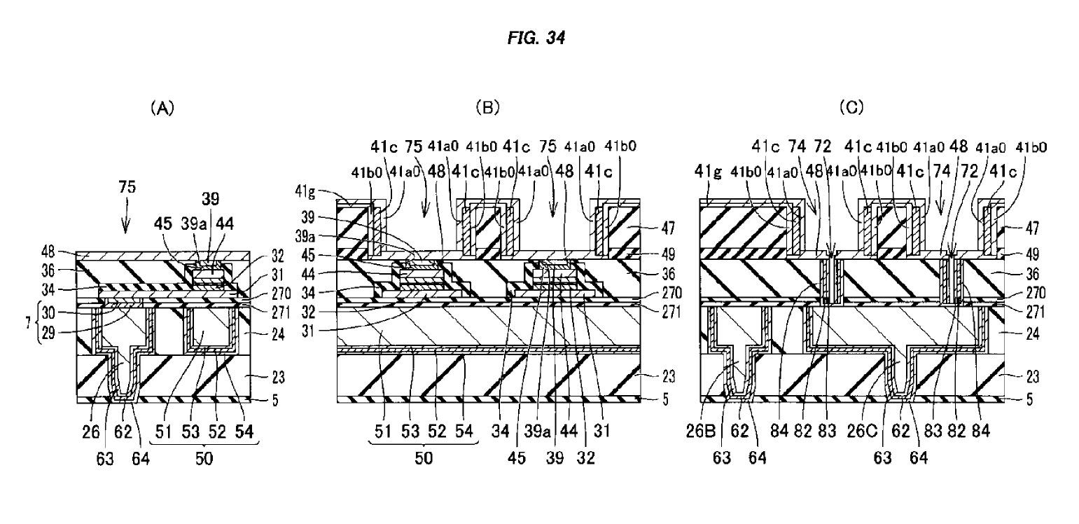

Next, as shown in FIGS. 34(A) to (C), barrier metals are formed over the exposed uppermost surfaces, that is, over the surfaces of the barrier metals 73A, 48B, and the cladding layer 41c, by sputtering etc. Preferably, these barrier metals are made of Ta or TaN like the barrier metals formed in FIGS. 31(A) to (C). These metals are formed simultaneously as a single unit and here, the part where a barrier metal formed over the barrier metal 73A and the barrier metal 73A are integrated into one unit is referred to as a barrier metal 41g, the part where a barrier metal formed over the barrier metal 48B and the barrier metal 48B are integrated into one unit is referred to as the barrier metal 48, and the barrier metal formed over the cladding layer 41c is referred to as a barrier metal 41a0.

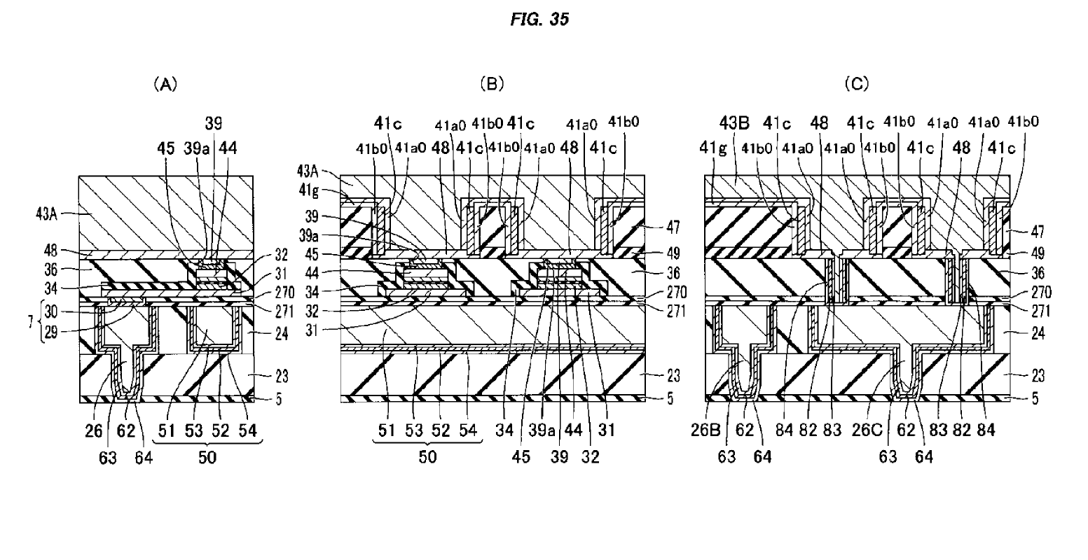

Next, the grooves 75, 74 in which the barrier metals are formed as shown in FIGS. 35(A) to (C) are filled with an electrically conductive film made of, for example, copper. The electrically conductive film over the region in which the memory unit is formed in FIGS. 35(A) (B) is referred to as an electrically conductive film 43A, and the electrically conductive film over the peripheral circuit part in FIG. 35(C) is referred to as an electrically conductive film 43B.

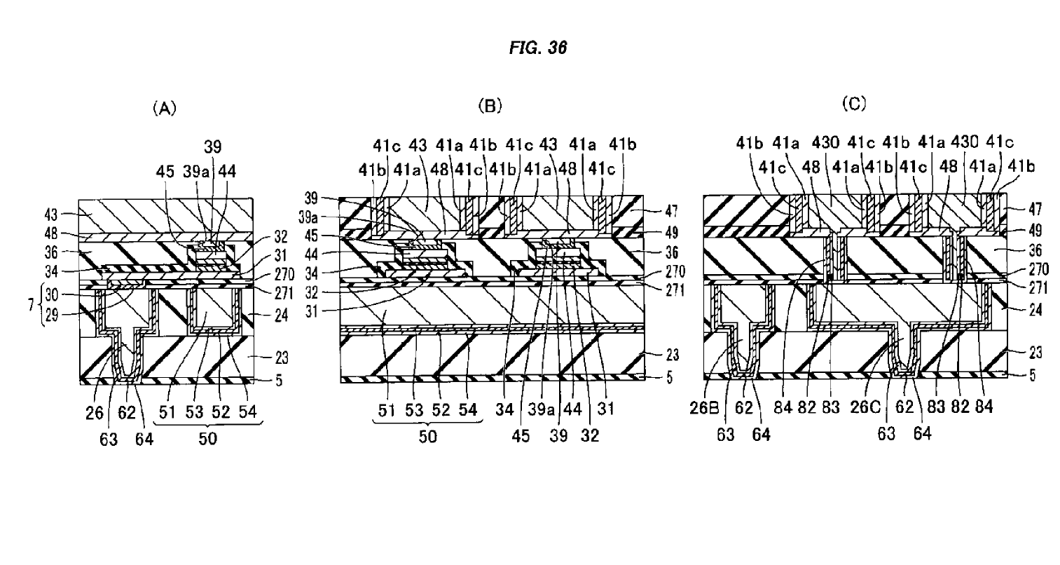

Then, as shown in FIGS. 36(A) to (C), the CMP processing is performed down to a predetermined depth on the side of the top surface in FIG. 35 to remove the whole barrier metal 41g. In this manner, the electrically conductive film in the groove 75 becomes the wire main body 43 of the bit line 40 and the electrically conductive film in the groove 74 becomes the peripheral wire main body 430 of the peripheral circuit part. The barrier metal 41a0 becomes the barrier metal 41a and the barrier metal 41b0 becomes the barrier metal 41b.

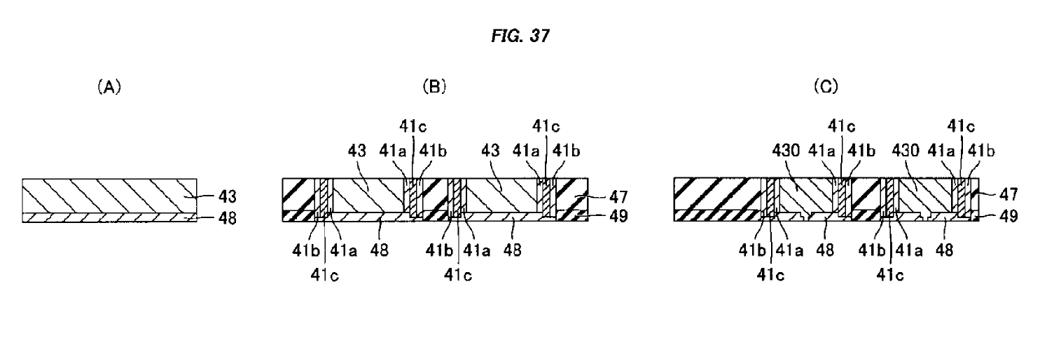

Hereinafter, in FIG. 37 to FIG. 43, the processes that follow FIG. 36 are sequential aspects of only the side upper than the wire main body 43 in FIG. 36 and the lower side is omitted and not shown schematically. Each of Figs. (A) to (C) shows a diagram when viewed in the same direction as that in Figs. (A) to (C) in FIG. 28 to FIG. 36.

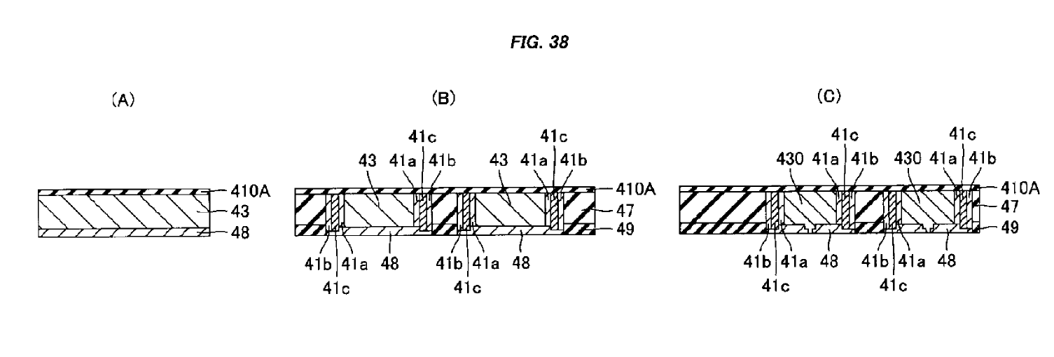

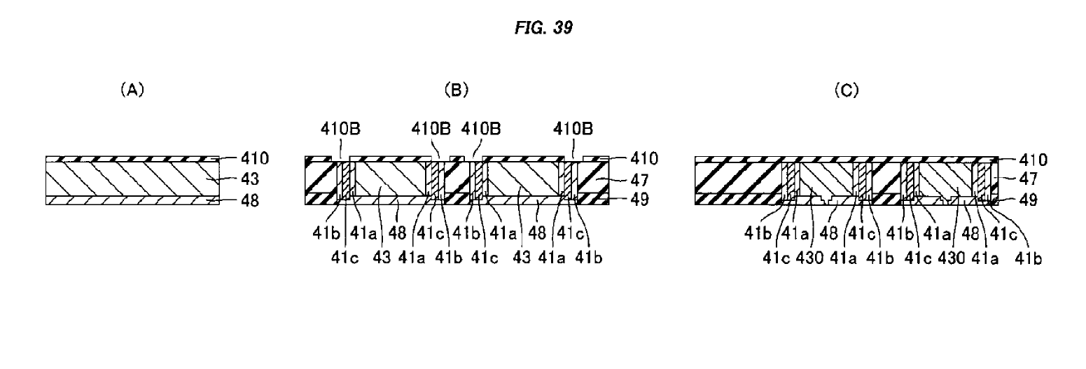

The aspects in FIGS. 37(A) to (C) are the same as the aspects of only the side upper than the wire main body 43 in FIGS. 36(A) to (C). In this state, next, as shown in FIGS. 38(A) to (C), a liner film 410A that should become the liner film 410 is formed. Further, as shown in FIGS. 39(A) to (C), the liner film 410A is etched by photolithography, etching, etc., and becomes the liner film 410.

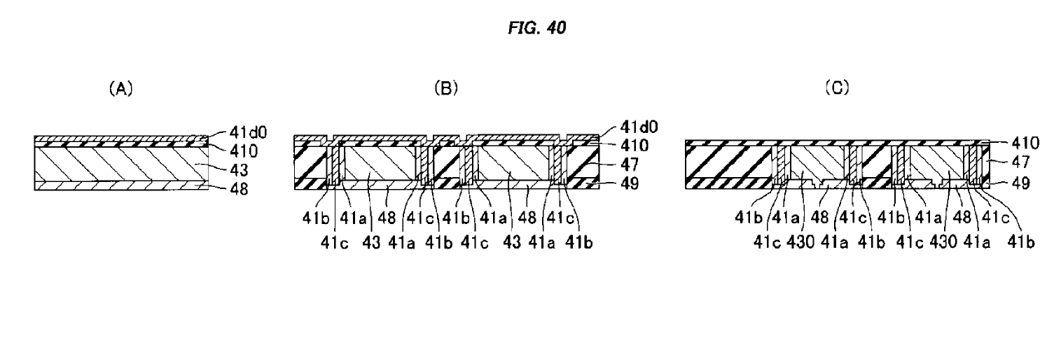

Subsequently, as shown in FIGS. 40(A) to (C), a cladding layer 41d0 that should become the cladding layer 41d is formed over the surface of the liner film 410 and over the inner surface of a groove 410B in FIG. 39(B). At this time, the thickness of the cladding layer 41d0 formed over the inner surface of the groove 410B is substantially the same as that of, for example, the cladding layer 41d0 formed over the surface of the liner film 410. Because of this, the shape is such that the inside of the groove 410B is sunk downward as shown in FIG. 40(B).

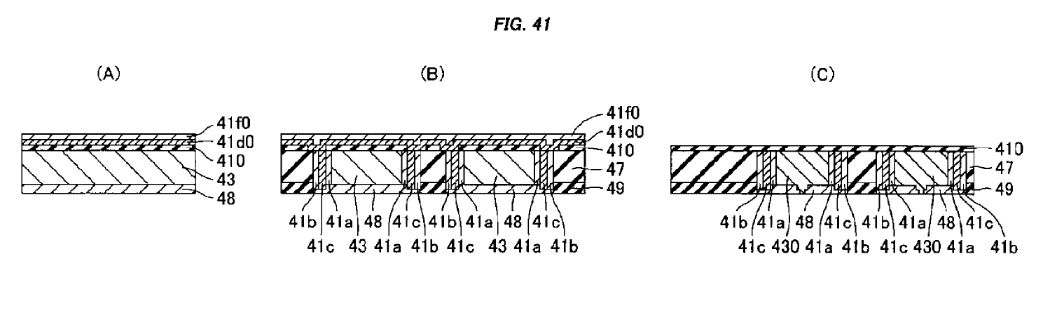

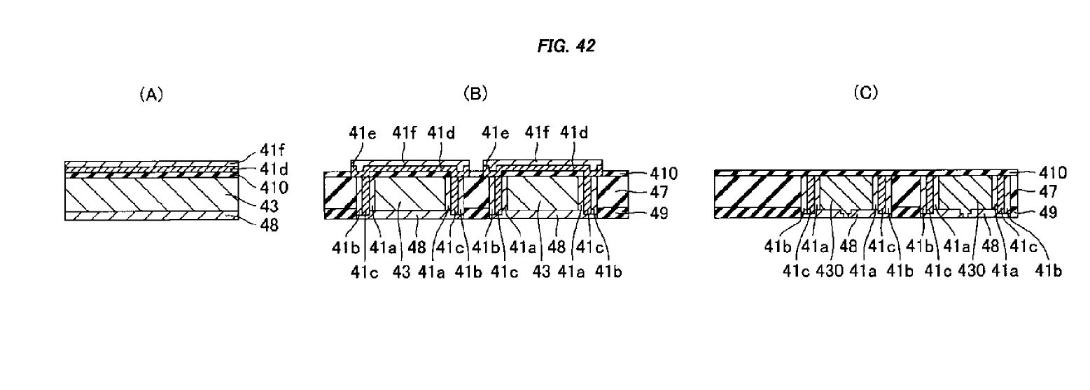

Next, as shown in FIGS. 41(A) to (C), over the surface of the cladding layer 41d0, a barrier metal 41f0, a layer that should become the barrier metal 41f, is formed. Then, lithography and etching are performed so that the cladding layer 41d0 and the barrier metal 41f0 are separated between the neighboring memory units as shown in FIGS. 42(A) to (C). Due to this, the aspects shown in FIGS. 42(A) to (C) are brought about and the cladding layer 41d0 becomes the cladding layer 41d and the barrier metal 41f0 becomes the barrier metal 41f.

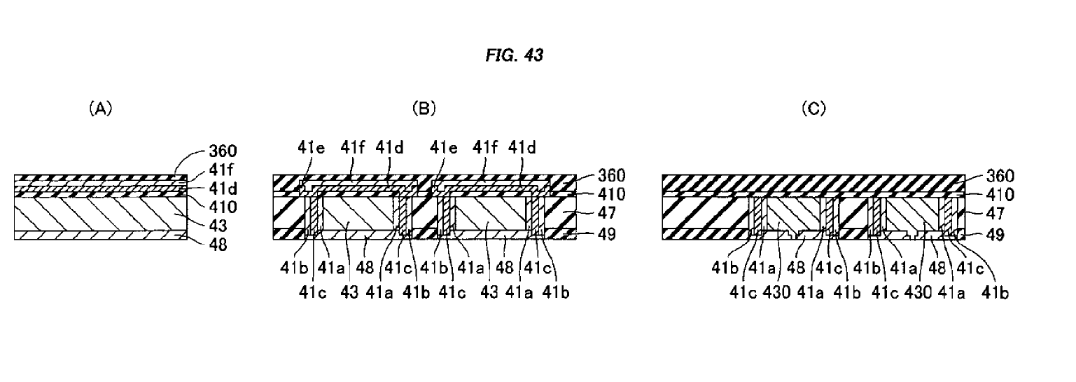

Finally, as shown in FIGS. 43(A) to (C), an insulating layer including a silicon oxide film etc. is formed so as to cover the top surface of the barrier metal 41f and the top surface of the exposed liner film 410. This insulating layer is formed in order to suppress an electrical short circuit with an external load arranged at the further upper part. Consequently, the insulating layer 360 is formed by etching the insulating layer and by forming a wire to electrically couple the insulating layer and the outside in, for example, the region on the periphery of the region in which the magnetoresistive elements 32 are arranged side by side. The aspect of the part of the bit line 40 in FIG. 43(B) is the same as that of the corresponding part in FIG. 4, FIG. 7, FIG. 10. By the above-described procedure, the bit line 40 and the semiconductor device 200 including the bit line 40 in the present first embodiment are completed.

### Second Embodiment

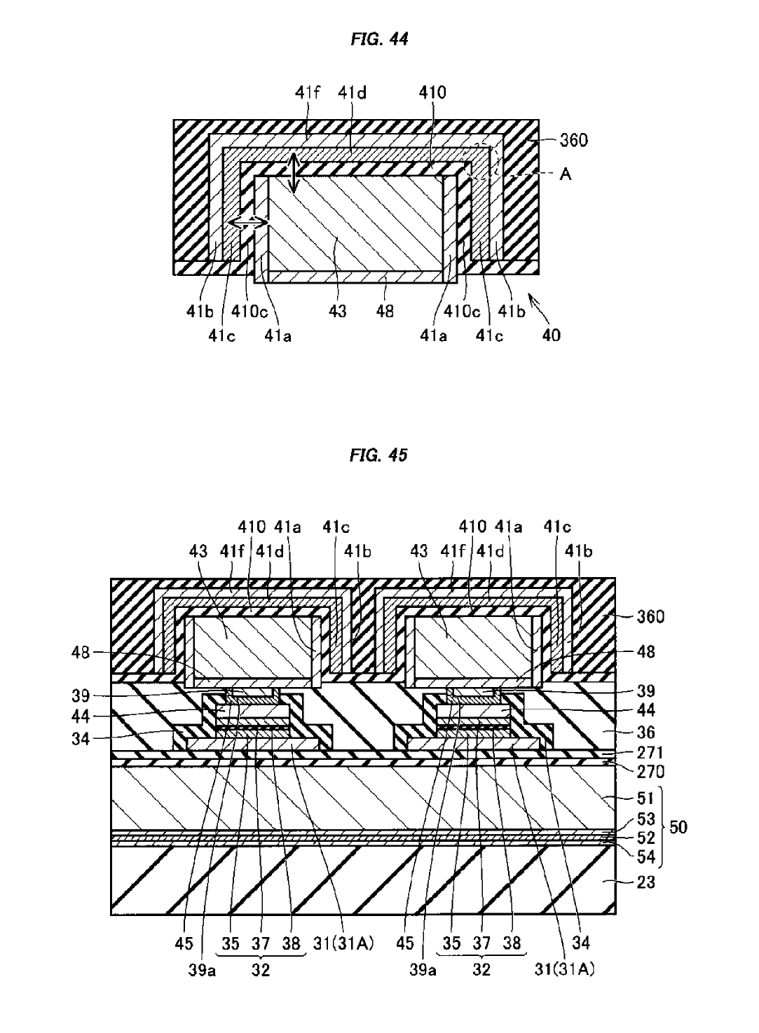

The semiconductor device 200 according to a second embodiment comprises substantially the same configuration of the semiconductor device 200 in the first embodiment. However, the configuration of the bit line 40 is somewhat different. Specifically, when FIG. 44 is compared with FIG. 7, in the bit line 40 in FIG. 44, the barrier metal 41a (barrier layer) is arranged so as to cover the side surface of the wire main body 43 (wire) and the liner film 410 (barrier layer) is arranged so as to cover the top surface of the wire (wire main body 43). In the section view shown in FIG. 44, there are a component that covers the top surface of the wire main body 43 and a component that covers the side surface of the wire main body 43 in the liner film 410. The component that covers the top surface of the wire main body 43 and the component that covers the side surface of the wire main body 43 are formed at the same time and integrated into one unit.

The cladding layers 41c, 41d are arranged so as to cover the outside of the liner film 410 whose lateral component and upper component are integrated into one unit, and the barrier metals 41b, 41f (protective layers) are further arranged so as to cover the outside of the cladding layers 41c, 41d. In other words, the cladding layers 41c, 41d are arranged so as to continuously cover the surface of the barrier layer facing the wire main body 43 and the surface on the opposite side (that is, the surface outside the barrier layer in FIG. 44). Further, the barrier metals 41b, 41f, which are the protective layers, are arranged so as to cover the surfaces of the cladding layers 41c, 41d facing the barrier layer and the surfaces on the opposite side (that is, the surfaces outside the cladding layer in FIG. 44).

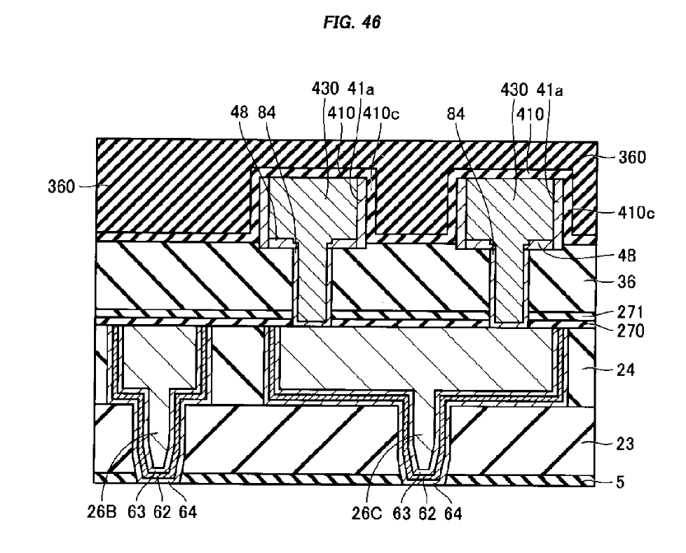

Similar to the liner film 410, in the cladding layer also, the cladding layer 41c, which is the lateral component of the wire main body 43, and the cladding layer 41d, which is the upper component of the wire main body 43, are formed integrally into one unit. In the protective layer also, the barrier metal 41b, which is the lateral component of the wire main body 43, and the barrier metal 41f, which is the upper component of the wire main body 43, are formed integrally into one unit. This can be seen also from FIG. 45 and FIG. 46. Similar to FIG. 4, FIG. 45 is a section view showing the state where the two memory units are arranged side by side when viewed in the direction intersecting with FIG. 3. Similar to FIG. 5, FIG. 46 is a section view of the peripheral circuit part.

Consequently, the cladding layer 41d is continuous at the bent part (region surrounded by the circular dotted line Ain FIG. 44), which is the boundary part between the lateral side and the upper side. Because of this, the configuration is such that the leakage of the magnetic field (magnetic line of force) that passes through the inside of the cladding layer to the outside of the cladding layer is suppressed by the presence of the region in which the cladding layer is separated, as in the first embodiment.

By the barrier metal 41a and the liner film 410, the barrier layer is arranged so as to continuously cover the side surface and the top surface of the wire main body 43. Because of this, as in the first embodiment, the mutual diffusion shown by the arrows in FIG. 44 is suppressed between the cladding layer and the wire main body. Further, as in the first embodiment, both the barrier metal 41a made of an electrically conductive material and the liner film 410 made of a dielectric material are used as barrier layers.

Furthermore, as shown in FIG. 45, the cladding layer 41d is discontinuous between the two neighboring memory units. Because of this, as in the first embodiment, it is possible to suppress the possibility that the magnetic line of force 71 that passes through the inside of the cladding layer 41d of one memory unit propagates and leaks toward the cladding layer 41d of the neighboring memory unit. That is, similar to FIG. 10, the magnetic line of force 71 travels intensively toward the magnetoresistive element 32 of the selected one memory unit, and therefore, it is possible to cause the magnetoresistive element 32 to operate efficiently and accurately. At the same time, the magnetic line of force leaks toward the magnetoresistive element 32 that neighbors the selected one memory unit and which is not selected, and therefore, it is possible to suppress trouble, such as an erroneous operation, when the magnetoresistive element 32 of the neighboring memory unit is affected by the magnetic line of force 71.

In addition to the same effects as those in the first embodiment, the semiconductor device 200 in the second embodiment exhibits the following effects. For example, FIG. 45 and FIG. 4 are compared and examined. Here, it is assumed that the distance between the two wire main bodies 43 in FIG. 45 is equal to the distance between the two wire main bodies 43 in FIG. 4.

The distance between the regions (barrier metal regions) in conduction with the wire main body 43 between the two bit lines in FIG. 45 and FIG. 4 is considered. First, in FIG. 4, the wire main body 43 and the barrier metal 41a, the cladding layer 41c, and the barrier metal 41b are in conduction with one another. Because of this, the distance between the end parts outside the barrier metal 41b is the distance between the regions (barrier metal regions) in conduction with the wire main body 43 between the two bit lines. In FIG. 4, the end part of the barrier metal 41f is outside the end part of the barrier metal 41b, however, the barrier metal 41f is not in conduction with the wire main body 43.

In contrast to this, in FIG. 45, the distance between the end parts outside the barrier metal 41a in direct contact with the wire main body 43 is the distance between the regions (barrier metal regions) in conduction with the wire main body 43 between the two bit lines. This is because the outside of the barrier metal 41a is covered with the liner film 410, which is a dielectric. That is, in FIG. 45, the wire main body 43 and the cladding layers 41c, 41d are electrically insulated.

Consequently, if it is assumed that the thickness of the barrier metal 41a in FIG. 4 is equal to that of the barrier metal 41a in FIG. 45, the distance between the regions in conduction with the wire main body 43 in FIG. 45 is longer than the distance between the regions in conduction with the wire main body 43 in FIG. 4.

The reliability of the wire depends on the distance between the regions in conduction with the wire main body 43. The longer the distance between the regions in conduction with the wire main body 43, the higher the reliability of the wire (TDDB). Because of this, by employing the configuration of the bit line 40 as in the second embodiment, it is possible to improve the reliability of the wire.

Subsequently, a method of manufacturing the semiconductor device 200 according to the second embodiment will be explained. The processes shown in FIG. 11 to FIG. 28 are the same as those in the method of manufacturing the semiconductor device 200 according to the first embodiment, and therefore, their explanation is omitted here. Each of Figs. (A) to (C) is a diagram when viewed in the same direction as that in Figs. (A) to (C) in FIG. 28 to FIG. 43.

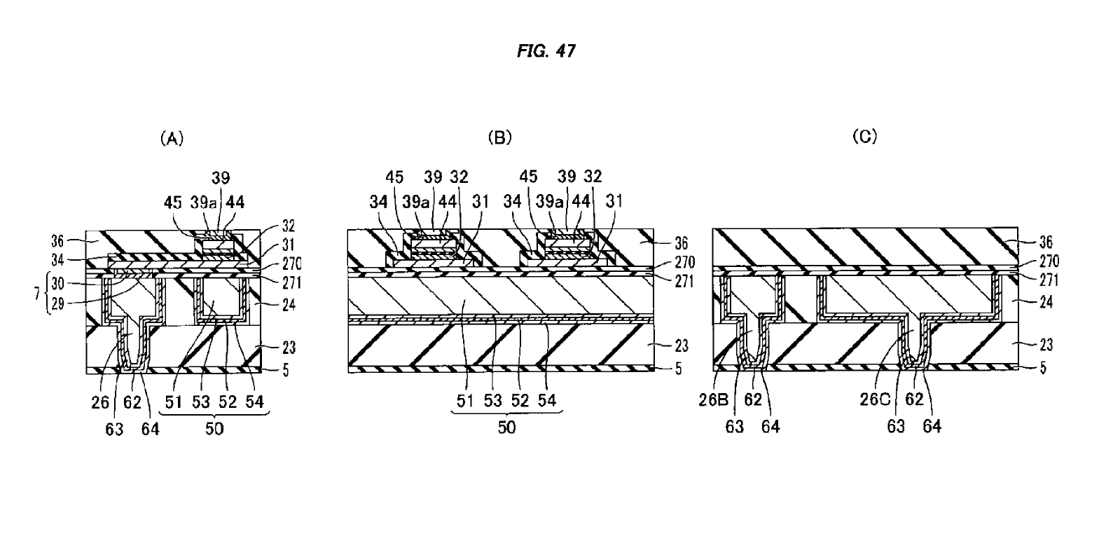

As the processes that follow the aspects shown in FIGS. 28(A) to (C), the same processing as that in FIGS. 29(A) to (C) is performed as shown in FIGS. 47(A) to (C). However, unlike FIGS. 29(A) to (C), the processing to form the liner film 49A is not performed. That is, similar to FIGS. 29(A) to (C), the barrier metal 45 and an electrically conductive film are formed and the contact part 39 is formed.

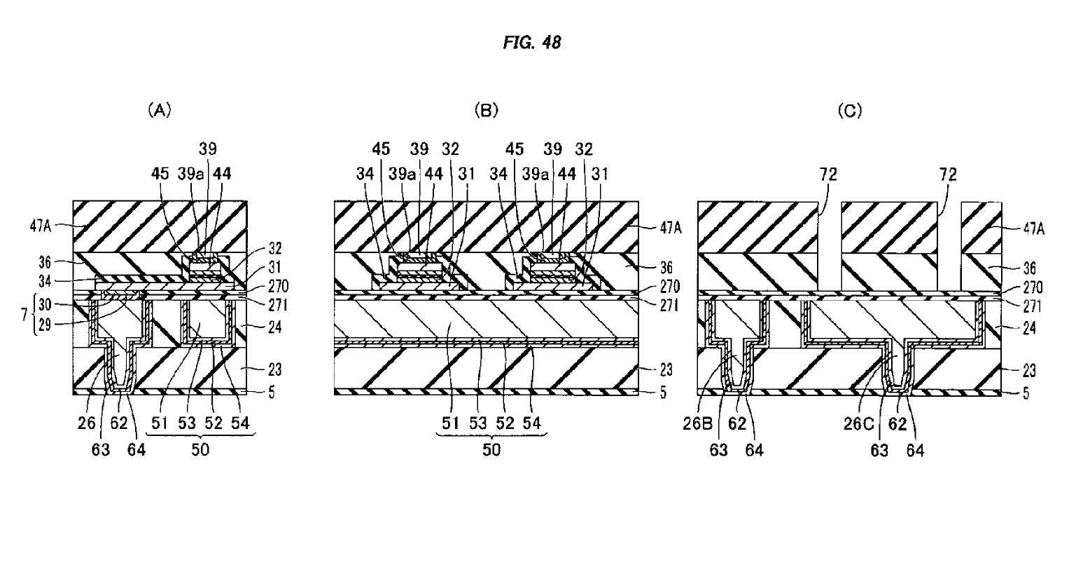

Next, as shown in FIGS. 48(A) to (C), the same processing as that in FIGS. 30(A) to (C) is performed. Because the liner film 49A is not formed, the insulating layer 47A is formed over the insulating layer 36 and via 72 is formed as shown in FIG. 48(C). In the present second embodiment, it may also be possible to form the liner film 49A as in the first embodiment. The liner film 49A plays a role as an etching stopper when forming the groove of the bit line by etching. This is not necessarily required when the depth of the groove 75 can be formed under control when performing etching.

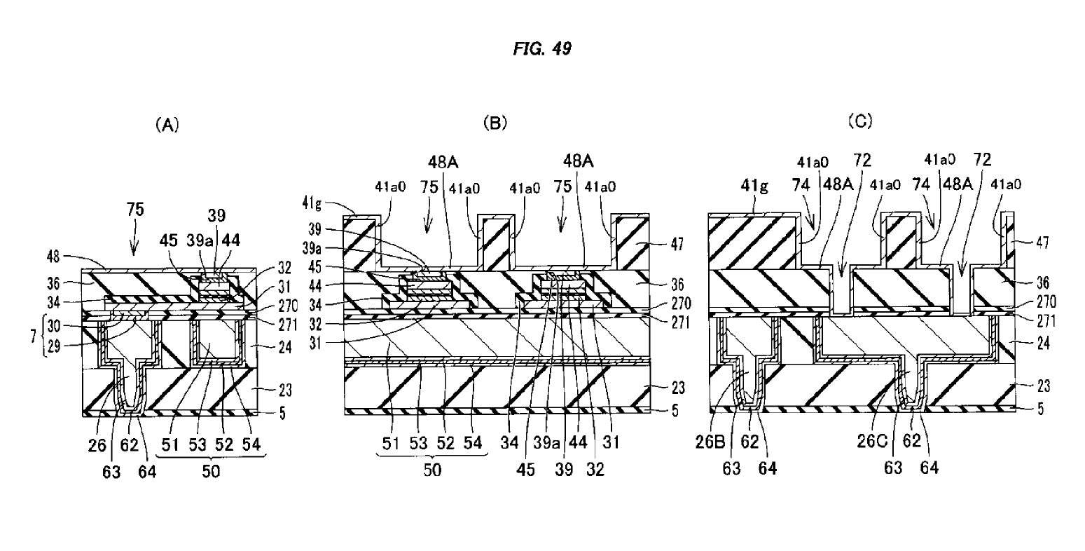

Next, as shown in FIGS. 49(A) to (C), the same processing as that in FIGS. 31(A) to (C) is performed. As in FIG. 31, these barrier metals formed here are simultaneously formed integrally into one unit and here, the barrier metal formed on the uppermost surface of the insulating layer 47 is referred to as the barrier metal 41g, the barrier metal formed on the inner surfaces of the grooves 75, 74 is referred to as the barrier metal 41a0, and the barrier metal formed on the bottom surfaces of the grooves 75, 74 is referred to as the barrier metal 48A.

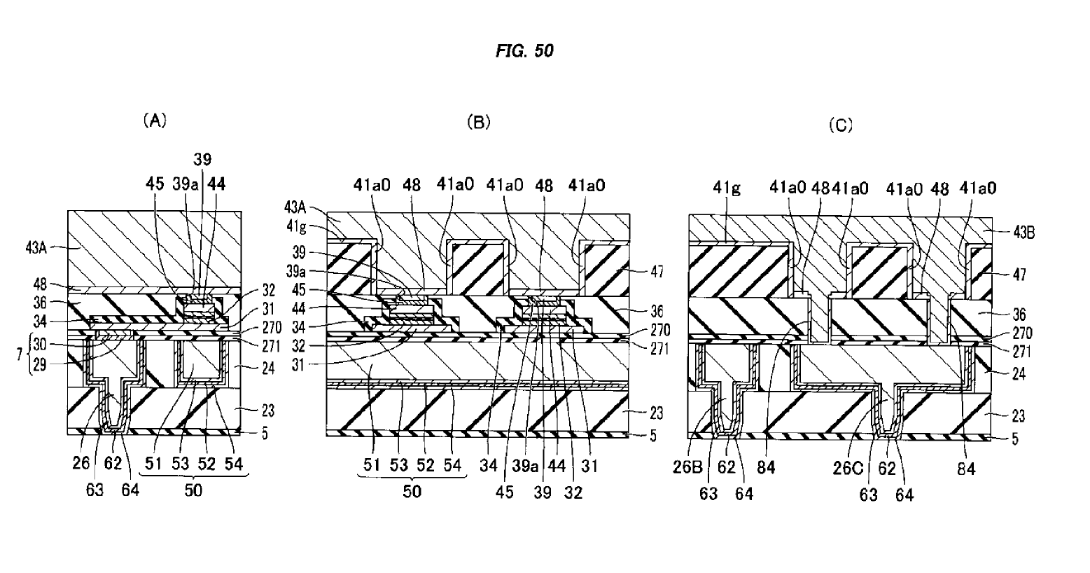

Then, as shown in FIGS. 50(A) to (C), the electrically conductive films 43A, 43B are filled as in FIGS. 35(A) to (C). Hereinafter, as shown in FIG. 50(C), the barrier metal formed on the inner surfaces of the grooves 75, 74 of the barrier metals formed in FIG. 49 is referred to as the barrier metal 48 according to FIG. 34 in the first embodiment. Further, the barrier metal on the side surface of the via 72 is referred to as the barrier metal 84 according to FIG. 34 in the first embodiment.

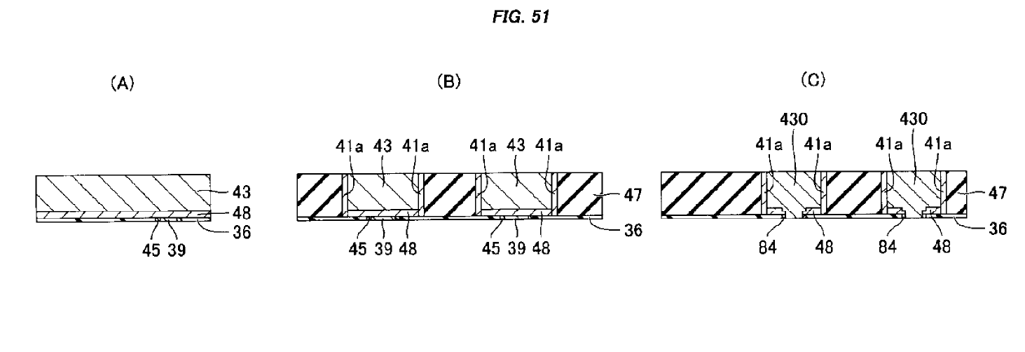

Hereinafter, in FIG. 51 to FIG. 56, the processes that follow FIG. 50 are sequential aspects of only the side upper than the contact part 39 in FIG. 36 and the lower side is omitted and not shown schematically. Each of Figs. (A) to (C) shows a diagram when viewed in the same direction as that in Figs. (A) to (C) in FIG. 28 to FIG. 36.

As shown in FIGS. 51(A) to (C), the CMP processing is performed to remove the whole barrier metal 41g as in FIGS. 36(A) to (C). In this manner, the electrically conductive film in the groove 75 becomes the wire main body 43 of the bit line 40 and the electrically conductive film in the groove 74 becomes the peripheral wire main body 430 of the peripheral circuit part. The barrier metal 41a0 becomes the barrier metal 41a.

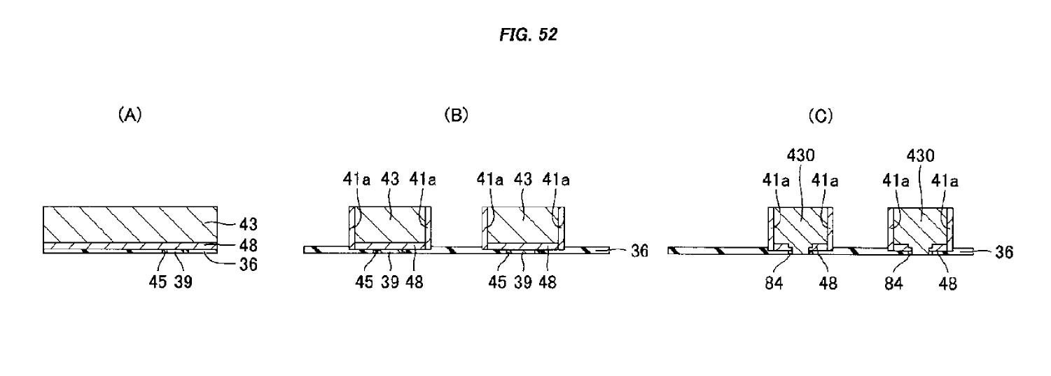

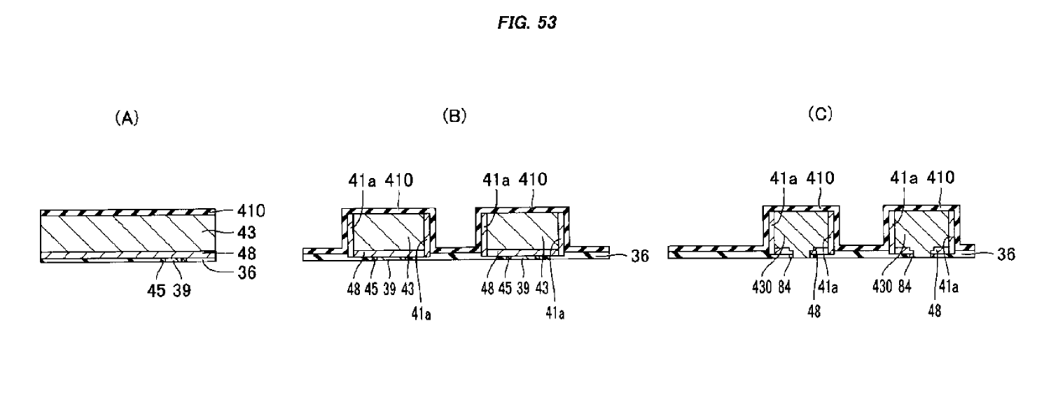

Next, as shown in FIGS. 52(A) to (C), the insulating layer 47 is removed by photolithography, etching, etc. The liner film 410 is formed over the exposed uppermost surface, that is, the top surface of the wire main body 43, over the surface of the barrier metal 41a, and over the uppermost surface of the insulating layer 36 as shown in FIGS. 53(A) to (C).

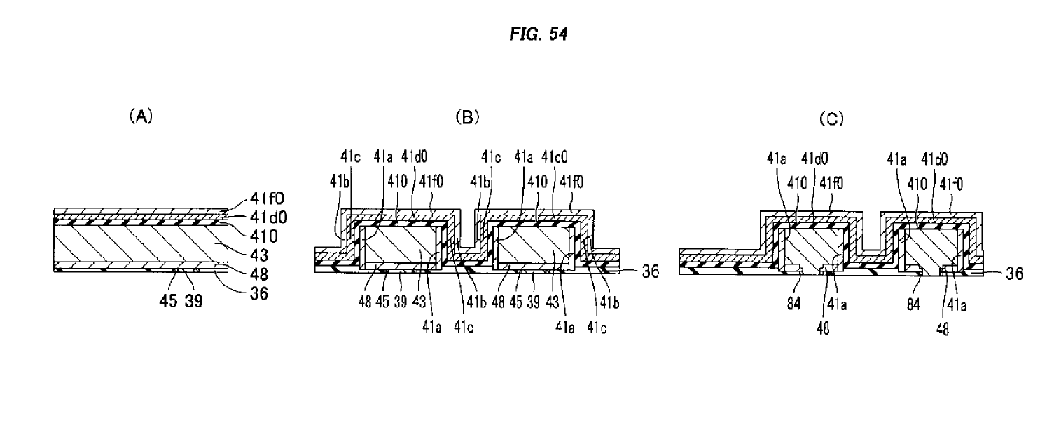

Next, as shown in FIGS. 54(A) to (C), the cladding layer 41d0 is formed so as to cover the surface of the liner film 410 and further, the barrier metal 41f0 is formed so as to cover the surface thereof. The cladding layer 41d0 is a layer that should become the cladding layers 41c, 41d in FIG. 44 and FIG. 45. The barrier metal 41f0 is a layer that should become the barrier metals 41b, 41f in FIG. 44 and FIG. 45. Consequently, it is preferable to form the cladding layers and the barrier metals so that their materials and thicknesses are the same as those of the cladding layers 41c, 41d and the barrier metals 41b, 41f, respectively.

However, the cladding layer 41c and the cladding layer 41d are formed at a time as the cladding layer 41d0, and therefore, it is difficult, for example, to form the cladding layer 41c on the lateral side of the wire main body 43 thicker than the cladding layer 41d above the wire main body 43 as in the first embodiment. Because of this, in order to make the cladding layer 41c thicker than the cladding layer 41d, it is preferable to perform etching back of the entire surface by sputtering or dry etching after, for example, once forming the cladding layer. By doing so, it is possible to leave the cladding layer in the shape of a wall only on the sidewall of the wire main body 43. After that, when the cladding layer is formed again, the cladding layer on the sidewall is formed thicker by an amount corresponding to the thickness of the cladding layer in the shape of a wall formed previously. As a result, it is possible to form the cladding layer 41c thicker than the cladding layer 41d.

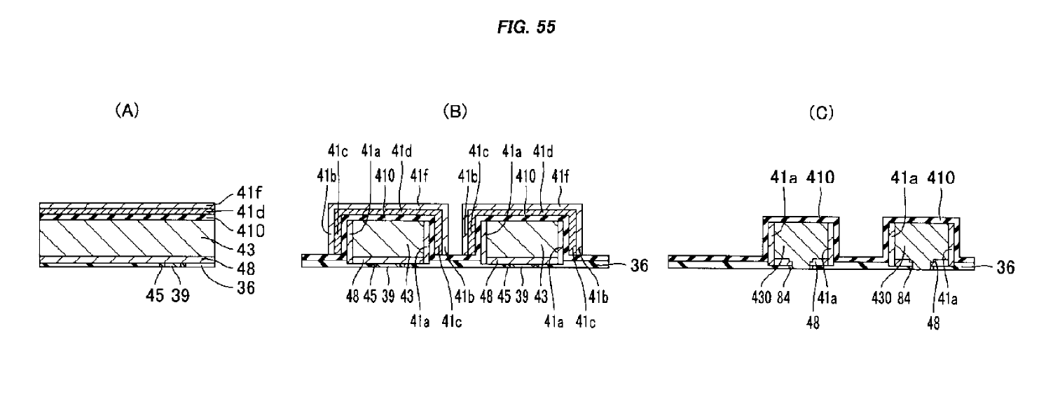

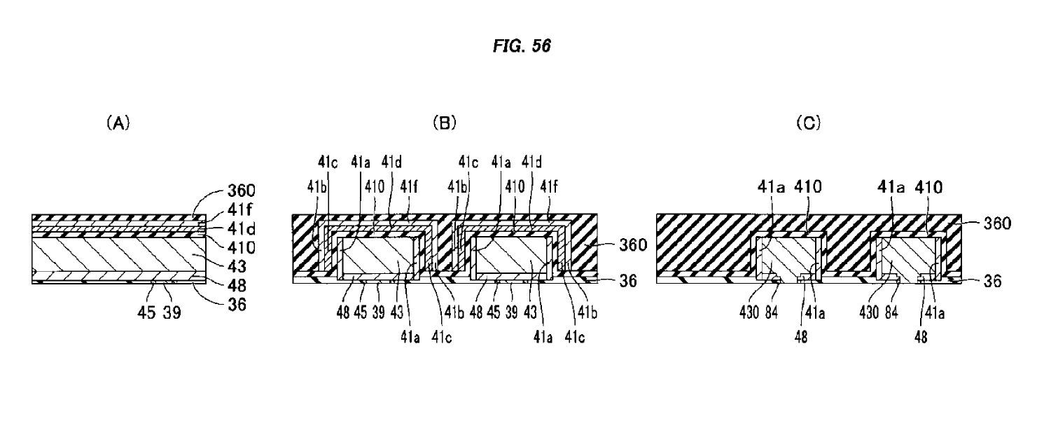

Next, as shown in FIGS. 55(A) to (C), photolithography, etching, etc., are performed in order to remove the cladding layer 41d and the barrier metal 41f0 in the region sandwiched by the neighboring wire main bodies 43 and the cladding layer 41d and the barrier metal 41f0 in the peripheral circuit part. Finally, as shown in FIGS. 56(A) to (C), the insulating layer 360 is formed on the uppermost surface as in FIGS. 43(A) to (C). By the above-described procedure, the bit line 40 and the semiconductor device 200 including the bit line 40 in the present second embodiment are completed.

As described above, in the second embodiment, the cladding layer 41c on the lateral side and the cladding layer 41d on the upper side of the wire main body 43, and the barrier metal 41b as the protective layer on the lateral side and the barrier metal 41f as the protective layer on the upper side of the wire main body 43 are formed at the same time. By doing so, the number of processes is small, and therefore, the stability of film quality of the cladding layers 41c, 41d to be formed is improved.

When the cladding layer 41c and the cladding layer 41d are formed in separate processes as in the first embodiment, the number of processes increases, and therefore, there is a possibility that the cladding layer, particularly one formed in the preceding process is damaged by wet etching processing etc. to be performed for each process. In particular, there is a possibility that the sidewall of the thin film in the cladding layer or the part where the cladding layer on the lateral side and the cladding layer on the upper side are connected receives damage resulting from processing or is oxidized. If such damage or oxidization happens, there is a possibility that the performance of the cladding layer is deteriorated.

However, as in the second embodiment, the cladding layer 41c and the cladding layer 41d are formed at the same time, and therefore, there exist no coupling part of the cladding layer 41c and the cladding layer 41d. Because of this, it is possible to reduce the region having a possibility of receiving damage of processing and as a result, the quality of the cladding layer to be formed can be stabilized.

The second embodiment of the present invention differs from the first embodiment of the present invention only in the respective points described above. That is, the configurations, conditions, procedures, effects, etc., not described in the second embodiment of the present invention are all quite the same as those in the first embodiment of the present invention. That is, the effects in the present second embodiment are also the effects in the first embodiment and the effects described in the present second embodiment are the effects that follow the effects in the first embodiment.

### Third Embodiment

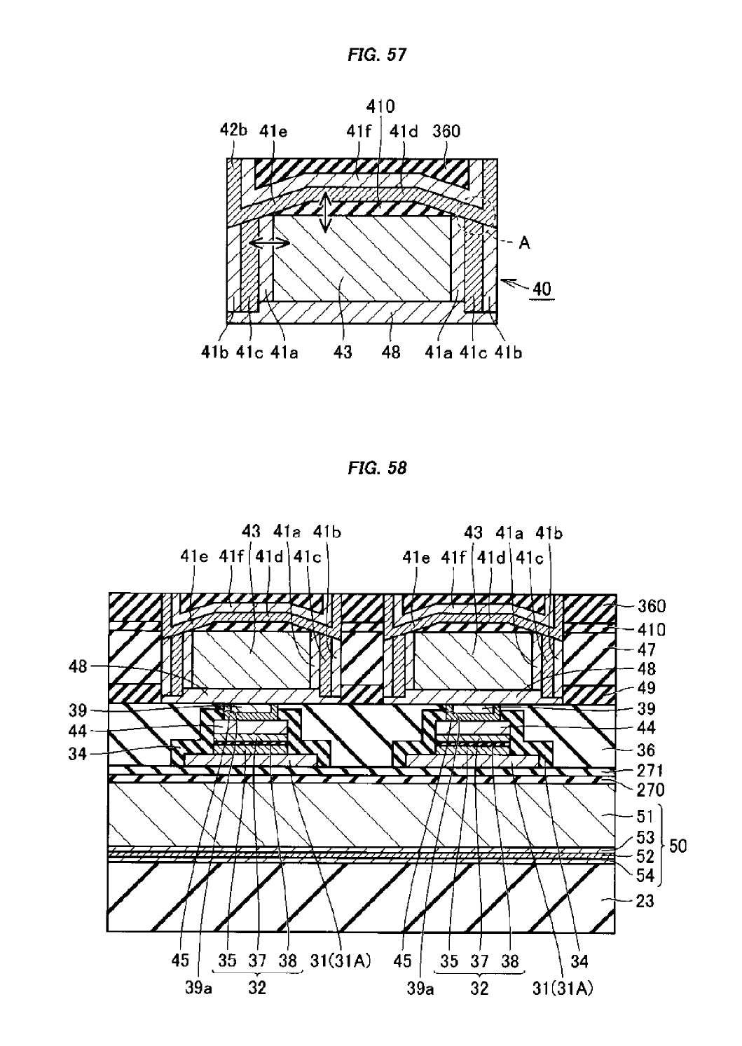

The semiconductor device 200 according to a third embodiment comprises substantially the same configuration as that of the semiconductor device 200 in the first embodiment. However, the configuration of the bit line 40 is somewhat different. Specifically, when FIG. 57 is compared with FIG. 7, the arrangement in the bit line 40 in FIG. 57 is similar to that in the bit line 40 in FIG. 7, however, at the corner part (region surrounded by the circular dotted line A in FIG. 57) where the cladding layer 41c on the lateral side of the wire main body 43 and the cladding layer 41d on the upper side of the wire main body 43 intersect with each other and are connected, the direction in which the cladding layer 41c extends and the direction in which the cladding layer 41d extends, both the cladding layers to be connected, form an obtuse angle more than 90° and less than 180°. In contrast to this, in the bit line in FIG. 7, the directions in which the cladding layer 41c and the cladding layer 41d extend form about 90° at the corner part. In this point, the third embodiment is different from the first embodiment.

Similar to FIG. 4, FIG. 58 is a section view showing a state where two memory units are arranged side by side when viewed in the direction intersecting with FIG. 3. The peripheral circuit part is the same as that in FIG. 5 in the first embodiment, and therefore, it is omitted and not shown schematically.

As shown in FIG. 57, also in the bit line 40 in the third embodiment, the cladding layer 41c and the cladding layer 41d are continuous in the region surrounded by the circular dotted line A. Because of this, the configuration is such that the leakage of the magnetic field (magnetic line of force) that passes through the inside of the cladding layer to the outside of the cladding layer is suppressed by the presence of the region in which the cladding layer is separated, as in the first embodiment.

In the bit line 40 in the third embodiment also, the barrier metal 41a and the liner film 410 are arranged as a barrier layer on the side surface and the top surface of the wire main body 43 and both are continuous. Because of this, the mutual diffusion between the wire main body 43 and the cladding layer as shown by the arrows in FIG. 57 is suppressed.

In the bit line 40 in the third embodiment also, the cladding layer is discontinuous between the two neighboring memory units. Because of this, the magnetic line of force (refer to FIG. 10) leaks toward the neighboring memory unit that is not selected, and therefore, it is possible to suppress trouble, such as an erroneous operation, of the magnetoresistive element 32 of the neighboring memory unit.

In addition to the same effects as those in the first embodiment, the semiconductor device 200 in the third embodiment exhibits the following effects. For example, FIG. 57 and FIG. 7 are compared and examined. In the bit line 40 in the first embodiment in FIG. 7, the directions in which the cladding layer 41c and the cladding layer 41d extend form about 90° in the section view in FIG. 7. In this case, at the corner part where the cladding layer 41c and the cladding layer 41d intersect, there is produced a part where the magnetic line of force that passes through the inside of the cladding layer changes 90°.

As shown in FIG. 7, when the directions in which the cladding layer 41c and the cladding layer 41d extend, respectively, form an angle of 90° or less, the above-mentioned corner part will be a region where the magnetization changes sharply when causing an electric current to flow through the wire main body 43 to generate the magnetic line of force that passes through the inside of the cladding layer. Then, the corner part is brought into an unstably magnetized state where energy is high.

At this time, the cladding layers 41c, 41d tend to move into a stable state where energy is lower. Because of this, there is a possibility that the magnetized state is disturbed in the vicinity of the corner part. Here, the wording “the magnetized state is disturbed” means that the magnetic line of force to travel essentially in the directions in which the cladding layers 41c, 41d extend travels in other directions. When the magnetized state is disturbed as described above, it is necessary to cause a higher current to flow through the wire main body 43 in order to make the direction of the magnetic line of force closer to the directions in which the cladding layers 41c, 41d extend, which is an ideal state.

However, as shown in FIG. 57, when the directions in which the cladding layers 41c, 41d extend at the corner where they intersect form an angle of more than 90°, the change of magnetization at the corner part is not so sharp compared to that at the corner part in FIG. 7. Because of this, there is a small possibility that the magnetized state at the corner in FIG. 57 is such an unstably magnetized state where energy is high at the corner part in FIG. 7.

Consequently, with the configuration in FIG. 57, it is possible to reduce the possibility that the magnetized state in the vicinity of the corner part is disturbed. Because of this, it is possible to reduce the electric current caused to flow through the wire main body 43. That is, it is possible to further reduce the power consumed by the semiconductor device 200.

Subsequently, a method of manufacturing the semiconductor device 200 according to the third embodiment will be explained. The processes shown in FIG. 11 to FIG. 38 are the same as those in the method of manufacturing the semiconductor device 200 according to the first embodiment, and therefore, their explanation is omitted here. Each of Figs. (A) to (C) is a diagram when viewed in the same direction as that in Figs. (A) to (C) in FIG. 28 to FIG. 43.

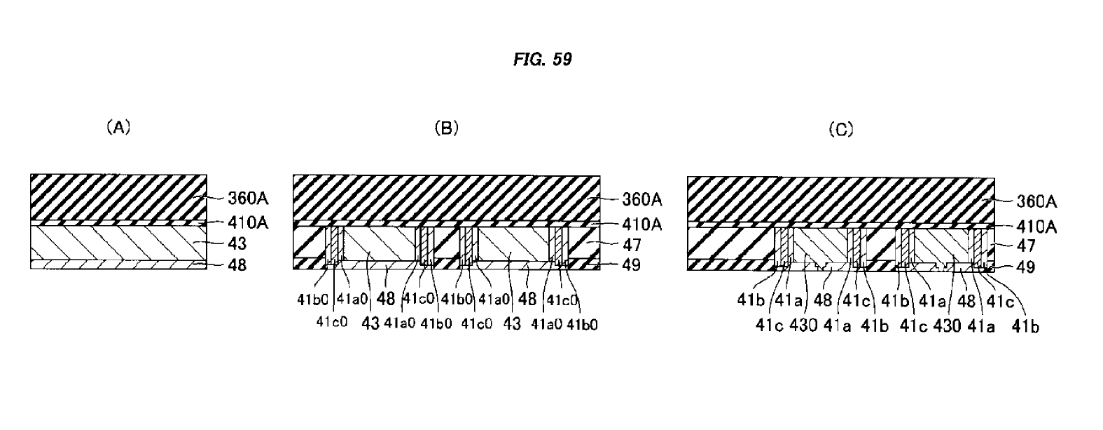

In FIG. 59 to FIG. 63, the aspects of only the side upper than the wire main body 43 are shown sequentially as in FIG. 37 to FIG. 43 and the lower side is not shown schematically.

As shown in FIGS. 38(A) to (C), when the liner film 410A that should become the liner film 410 is formed, an insulating layer 360A including a silicon oxide film etc. is formed so as to cover the top surface of the liner film 410A as shown in FIGS. 59(A) to (C). This is a layer that should become the insulating layer 360 described above.

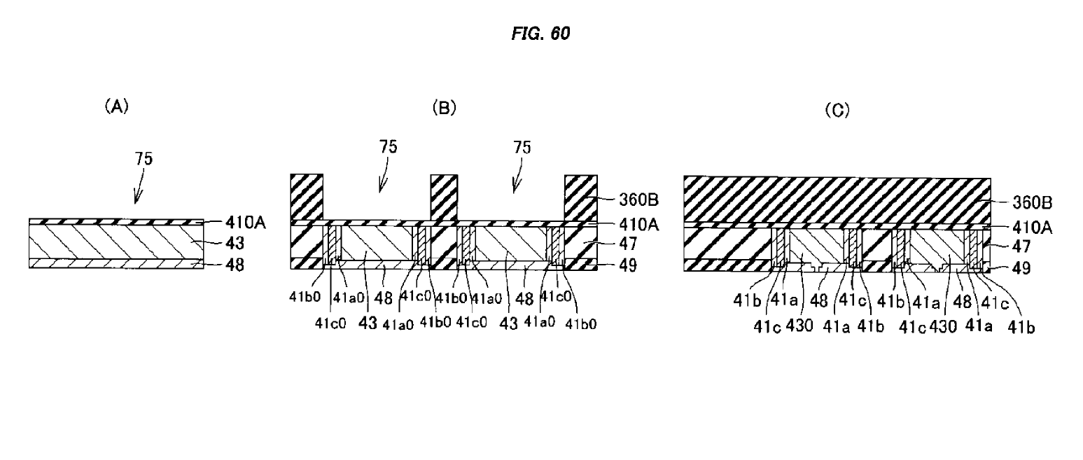

Subsequently, photolithography, etching, etc. are performed to remove the region corresponding to the insulating layer 360A, particularly, to the upper part of the wire main body 43. In this manner, the groove 75 is formed in the upper part of the wire main body 43 as shown in FIGS. 60(A) (B). The region where the insulating layer 360A is not etched becomes an insulating layer 360B. The groove 75 extends so as to spread over the upper parts of the neighboring wire main bodies 43 as shown in FIGS. 60(A) (B).

When etching the insulating layer 360A, it is preferable to remove part of the region corresponding to the insulating layer 360A, particularly, to the upper part of the peripheral wire main body 430, although not shown schematically in FIG. 60(C). By doing so, it is possible to form a groove for forming the unit contact part that can be coupled electrically with an external load to be arranged over the insulating layer 360 that is formed finally.

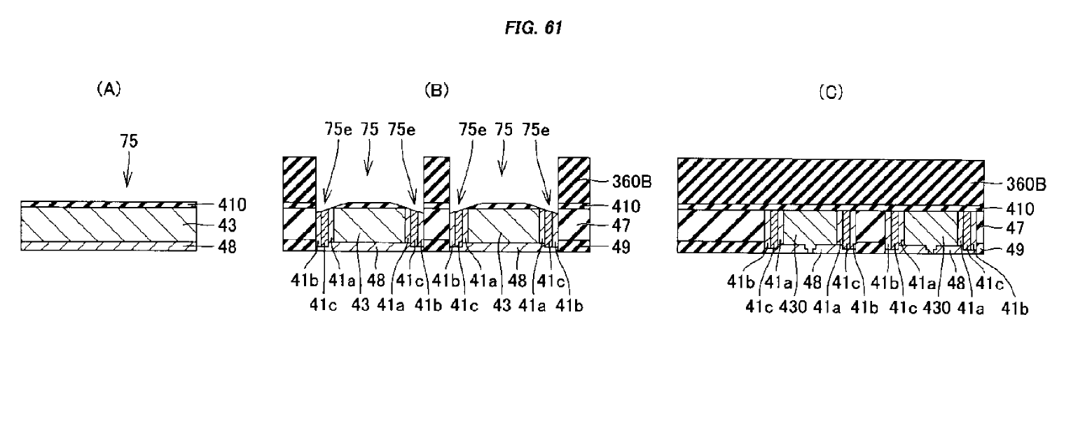

Next, the bottom of the groove 75 is etched and removed by sputtering etc. By doing so, part of the liner film 410A in the direction of thickness (vertical direction) is removed inside the groove 75, and therefore, the liner film 410A is thinned as shown in FIGS. 61(A) (B). In this manner, the liner film 410A is formed. At this time, the etching rate when sputtering at the end part in the vicinity of the sidewall of the groove 75 is high, and therefore, as shown in FIG. 61(B), an oblique direction etching region 75e is formed in the liner film 410 inside the groove 75 as a result. The oblique direction etching region 75e is formed in this manner, and therefore, it is also possible to expose a partial region of the upper end part in the barrier metal 41b and the cladding layer 41c.

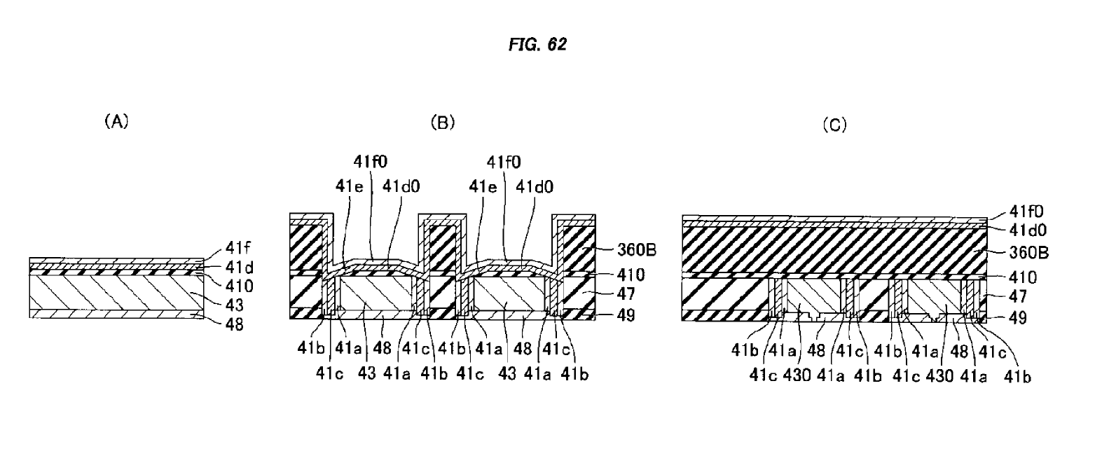

Next, the cladding layer 41d0 and the barrier metal 41f0 are formed over the exposed uppermost surface, that is, the side surface and the top surface of the insulating layer 360B, the liner film 410 inside the groove 75, and the oblique direction etching region 75e. This aspect is shown in FIGS. 62(A) to (C).

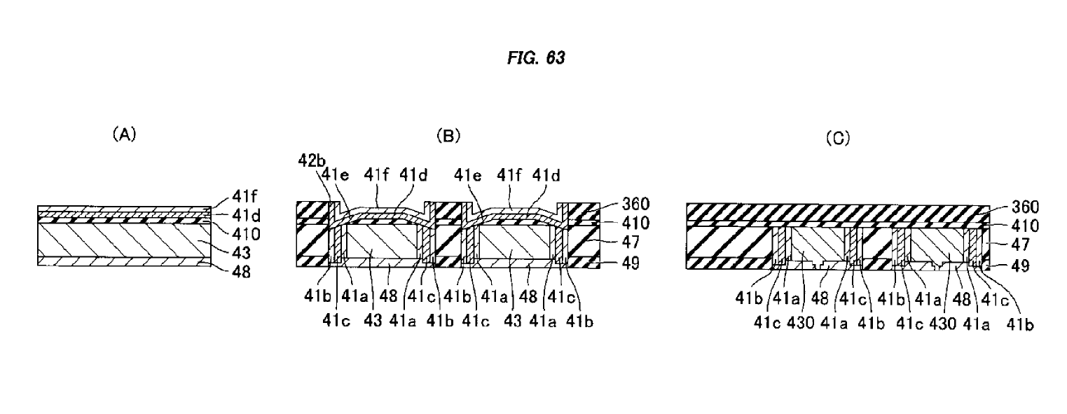

Finally, by removing the region on the comparatively upper side of the cladding layer 41d0 and the barrier metal 41f0 in FIGS. 63(B) (C) by, for example, the CMP processing, the insulating layer 360, the cladding layer 41d, and the barrier metal 41f the top surfaces of which are flattened in FIG. 63(A) to (C) are formed. In this process, it may also be possible to perform the same processing by performing photolithography, etching, etc., instead of the CMP processing.

In order to perform the processing for flattening the top surface shown in FIGS. 63(A) to (C), a projecting end part 42b that extends in such a manner that the cladding layer and barrier metal project upward is formed in the cladding layer end part 41e. However, the projecting end part 42b is an adjunct region that is produced to form the cladding layer 41d0 and the barrier metal 41f0 over the side surface of the groove 75 as shown in FIG. 62(B). Because of this, it is possible to reduce the dimensions of the projecting end part 42b as small as possible by adjusting (increasing) the amount of the top surface part to be removed in the removal process shown in FIG. 63. The projecting end part 42b is a region that does not affect directly the operation of the bit line 40, and therefore, for example, the cladding layer configuring the projecting end part 42b may come into direct contact with the insulating layer 360 formed by a silicon oxide film etc.

By the above-described procedure, the bit line 40 and the semiconductor device 200 including the bit line 40 in the present third embodiment are completed. As described above, the obtuse angle formed by the direction in which the cladding layer 41d extends and that in which the cladding layer 41c extends is formed by utilizing the oblique direction etching region 75e produced by the difference in the etching rate at the time of sputtering of the end part of the groove 75.

The third embodiment of the present invention differs from the first embodiment of the present invention only in the respective points described above. That is, the configurations, conditions, procedures, effects, etc., not described in the third embodiment of the present invention are all quite the same as those in the first embodiment of the present invention. That is, the effects in the present third embodiment are also the effects in the first embodiment and the effects described in the present third embodiment are the effects that follow the effects in the first embodiment.

### Fourth Embodiment

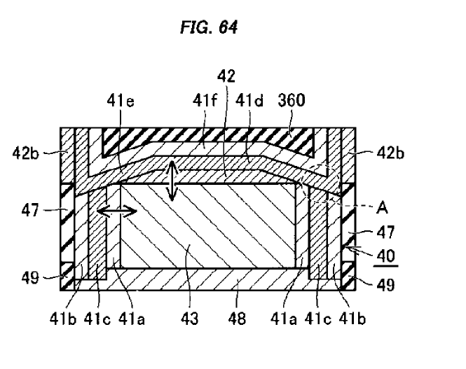

The semiconductor device 200 according to a fourth embodiment comprises substantially the same configuration as that of the semiconductor device 200 in the third embodiment. However, the configuration of the bit line 40 is somewhat different. Specifically, when FIG. 64 is compared with FIG. 57, in the bit line 40 in FIG. 64, the region sandwiched between the wire main body 43 and the cladding layer 41d is the barrier metal 42 instead of the liner film 410. Then, in the projecting end part 42 also, barrier metals made of the same material as that of the barrier metal 42 are arranged so as to sandwich the cladding layer from both sides. In this point the fourth embodiment differs from the third embodiment.

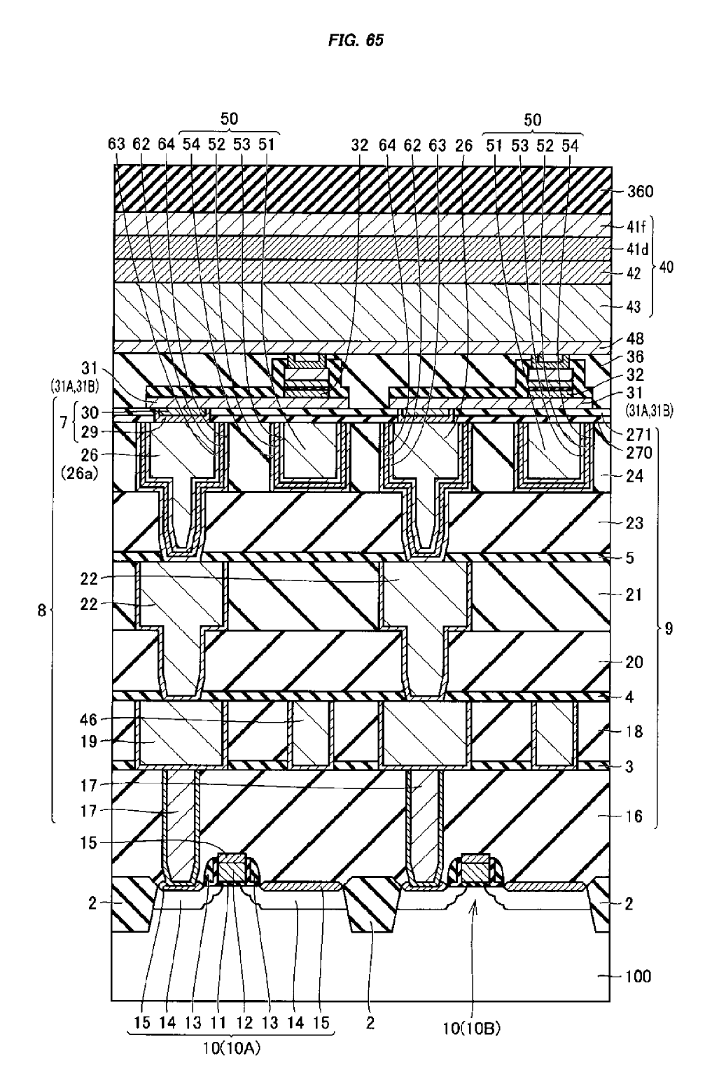

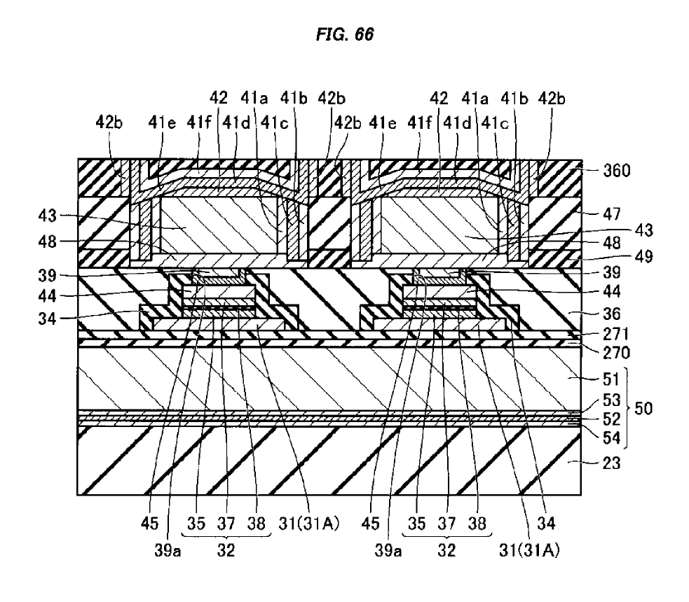

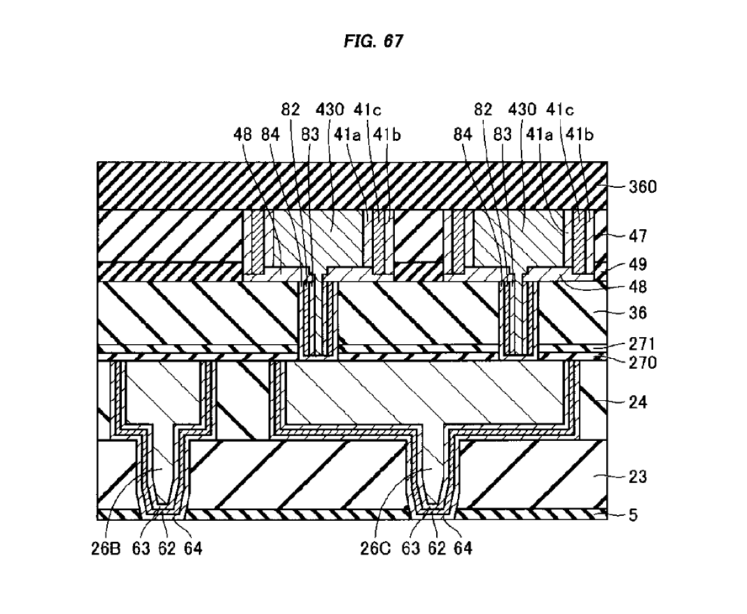

The arrangement of the barrier metal 42 instead of the liner film 41 is shown in FIG. 65. FIG. 65 differs from FIG. 3 only in that the barrier metal 42 is arranged instead of the liner film 410. Similar to FIG. 4, FIG. 66 is a section view showing a state where two memory units are arranged side by side when viewed in the direction intersecting with FIG. 3. Similar to FIG. 5, FIG. 67 is a section view of the peripheral circuit part.

Preferably, the barrier metal 42 is made of the same material as that of the other barrier metals (barrier metals 41a, 41b, 41f). By doing so, the barrier layers (barrier metals 41a, 42) and the protective layers (barrier metals 41b, 41f) of the bit line 40 are made of the same material.

Similar to the bit line 40 in the first to third embodiments, the bit line 40 in the fourth embodiment also has effects of, for example, the suppression of mutual diffusion in a region indicated by the arrow in FIG. 65, the suppression of leakage of the magnetic field in a region surrounded by the circular dotted line A, and the suppression of leakage of the magnetic field to the neighboring memory unit due to the fact that the neighboring bit lines 40 are not coupled by the cladding layer as shown in FIG. 66. In addition to these effects, the semiconductor device 200 in the fourth embodiment has the following effects.

Here, FIG. 64 and FIG. 57 are compared and examined. In the bit line 40 in the third embodiment shown in FIG. 57, the barrier layer on the lateral side of the wire main body 43 is the barrier metal 41a made of a Ta-based metal material. However, the barrier layer on the upper side of the wire main body 43 is the liner film 410 made of a dielectric material. That is, in the bit line 40 in the third embodiment, the barrier layer on the lateral side of the wire main body 43 and the barrier layer on the upper side of the wire main body 43 are made of different materials. However, in the bit line 40 in the fourth embodiment in FIG. 64, the barrier layer on the lateral side and the barrier layer on the upper side of the wire main body 43 are made of the same material (Ta-based metal material).

The crystalline structure configuring the cladding layer 41c receives the influence of the barrier layer on the lateral side of the wire main body 43 in contact therewith. Similarly, the crystalline structure configuring the cladding layer 41d receives the influence of the barrier layer on the upper side of the wire main body 43 in contact wherewith.

If the material of the barrier layer on the lateral side of the wire main body 43 is different from the material of the barrier layer on the upper side of the wire main body 43, there may be a case where the internal crystalline structure considerably differs between the cladding layers 41c and the cladding layer 41d. If the crystalline structure of the cladding layer 41c differs considerably from that of the cladding layer 41d, there is produced a region (magnetic domain wall) where the direction of magnetization changes at the grain boundary of crystal between the cladding layer 41c and the cladding layer 41d. As a result, there is a possibility that the structure is a multiple magnetic domain structure in which the number of directions of magnetization of the cladding layer 41c and the cladding layer 41d is two or more. The multiple magnetic domain structure may deteriorate the magnetic characteristics of the cladding layer 41c and the cladding layer 41d.

In order to eliminate (move) the magnetic domain wall produced inside the cladding layer, it is necessary to apply high energy to the cladding layer. In order to do so, it is necessary to cause a high current to flow through the wire main body 43.

However, if the material of the barrier layer on the lateral side of the wire main body 43 and the material of the barrier layer on the upper side of the wire main body 43 are the same, it is possible to reduce the difference of the internal crystalline structure between the cladding layer 41c and the cladding layer 41d. This is because of the tendency of the crystal growth of the cladding layers 41c, 41d to follow the crystallinity of the barrier layer in contact therewith. Because of this, if the material of the barrier layer on the lateral side of the wire main body 43 and the material of the barrier layer on the upper side of the wire main body 43 are the same, it is possible to cause both the cladding layer 41c and the cladding layer 41d to have a structure having the same crystallinity.

If the difference of the crystal structure between the cladding layer 41c and the cladding layer 41d is reduced, the possibility that the magnetic domain wall is produced at the grain boundary of the crystal between the cladding layer 41c and the cladding layer 41d is reduced. Because of this, it is possible to reduce the electric current to be caused to flow through the wire main body 43. That is, it is possible to further reduce the power consumed by the semiconductor device 200.

Subsequently, a method of manufacturing the semiconductor device 200 according to the fourth embodiment will be explained. The processes shown in FIG. 11 to FIG. 37 are the same as those in the method of manufacturing the semiconductor device 200 according to the first embodiment, and therefore, their explanation is omitted here. Each of Figs. (A) to (C) is a diagram when viewed in the same direction as that in Figs. (A) to (C) in FIG. 28 to FIG. 43.

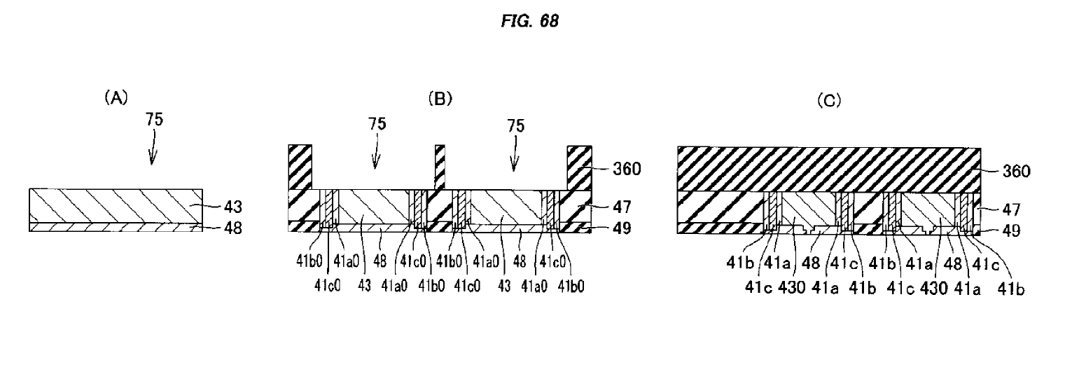

In FIG. 68 to FIG. 71, the aspects of only the side upper than the wire main body 43 are shown sequentially as in FIG. 37 to FIG. 43 and the lower side is not shown schematically.

Next, an insulating layer including a silicon oxide film etc. is formed so as to cover, for example, the entire surface of the uppermost surface that is exposed in the conditions shown in FIGS. 37(A) to (C). This is a layer that should become the insulating layer 360 described above.

Subsequently, photolithography, etching, etc. are performed to remove the region corresponding to the insulating layer, particularly, to the upper part of the wire main body 43. In this manner, the groove 75 is formed in the upper part of the wire main body 43 as shown in FIGS. 68(A) (B). The region where the insulating layer is not etched becomes the insulating layer 360. The groove 75 extends so as to spread over the upper parts of the neighboring wire main bodies 43 as shown in FIGS. 60(A) (B).

When etching the insulating layer to form the insulating layer 360, it is preferable to remove part of the region corresponding to the insulating layer, particularly, to the upper part of the peripheral wire main body 430, although not shown schematically in FIG. 68(C). By doing so, it is possible to form a groove for forming the unit contact part that can be coupled electrically with an external load to be arranged over the insulating layer 360 that is formed finally.

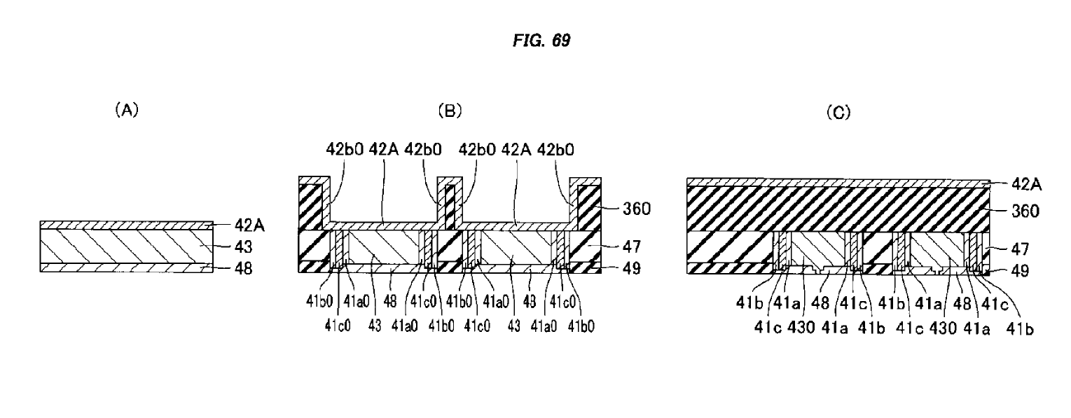

Next, barrier metals are formed by sputtering etc. so as to cover the entire surface of the uppermost surface that is exposed, that is, the uppermost surface of the insulating layer 360 or the inner surface of the groove 75. These barrier metals are formed integrally as a single unit at the same time and here, the barrier metals formed on the uppermost surface of the insulating layer 360 and the bottom of the groove 75 are referred to as a barrier metal 42A and the barrier metal formed on the inner surface of the groove 75 is referred to as a barrier metal 42b0. This aspect is shown in FIGS. 69(A) to (C).

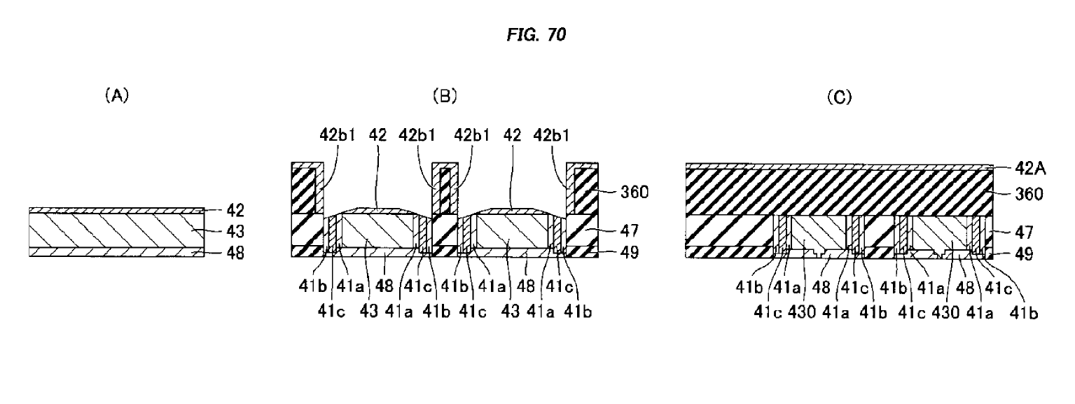

Next, etching and removal processing by sputtering etc. are performed so as to thin the barrier metal 42A in particular. This aspect is the same as the processing for thinning the liner film 410A in FIGS. 61(A) (B) and is shown in FIGS. 70(A) to (C). Consequently, at this time, the etching rate when sputtering at the end part in the vicinity of the sidewall of the groove 75 is high, and therefore, as shown in FIG. 70(B), the oblique direction etching region 75e is formed as a result. The oblique direction etching region 75e is formed in this manner, and therefore, it is also possible to expose a partial region of the upper end part in the barrier metal 41b and the cladding layer 41c. The barrier metal 42b0 becomes a barrier metal 42b1 and the barrier metal 42A becomes a barrier metal 42.

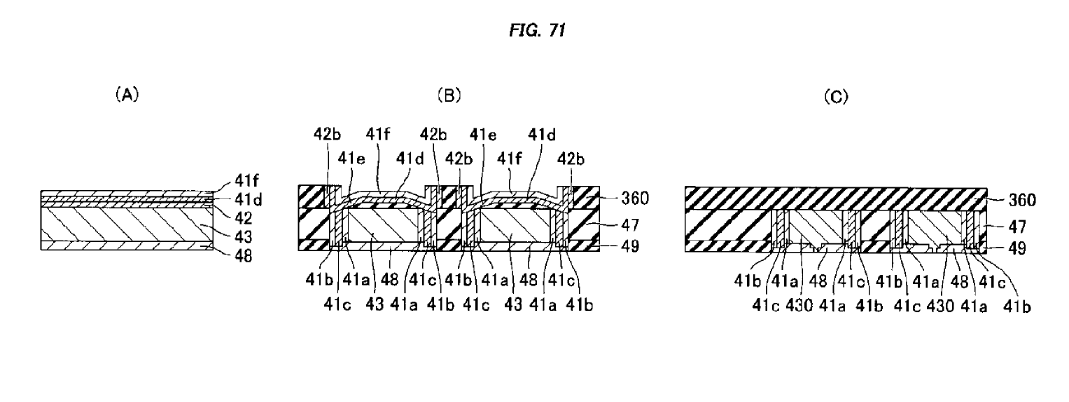

Next, cladding layers and barrier metals are formed over the uppermost surface that is exposed, that is, over the barrier metals 42, 42b1, 42A. Finally, the region on the comparatively upper side of the cladding layer and the barrier metal is removed as in FIG. 63. In this manner, the cladding layer 41d, the barrier metal 41f, and the projecting end part 42b shown in FIGS. 71(A) to (C) are formed.

In the bit line 40 in FIG. 64, barrier metals are arranged at the projecting end part 42b so as to sandwich the cladding layer from both sides. This is because one of the barrier metals is formed at the same time with the barrier metal 42 (barrier metal 42A) as the barrier metal 42b0 in the process in FIG. 69. The projecting end part 42b does not have a technical effect, and therefore, even if the barrier metal is not present, no functional problem will arise.

The fourth embodiment of the present invention differs from the first and third embodiments of the present invention only in the respective points described above. That is, the configurations, conditions, procedures, effects, etc., not described in the fourth embodiment of the present invention are all quite the same as those in the first and third embodiments of the present invention. That is, the effects in the present fourth embodiment are also the effects in the first and third embodiments and the effects described in the present fourth embodiment are the effects that follow the effects in the first and third embodiments.

### Fifth Embodiment

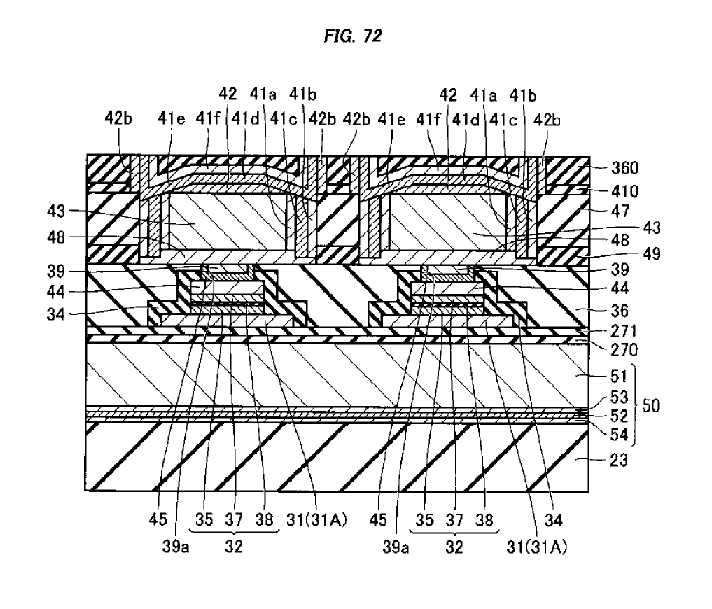

The semiconductor device 200 according to a fifth embodiment comprises substantially the same configuration as that of the semiconductor device 200 in the fourth embodiment. Similar to FIG. 4 and FIG. 66, FIG. 72 is a section view showing a state where two memory units are arranged side by side when viewed in the direction intersecting with FIG. 3. When FIG. 72 is compared with FIG. 66, in the fourth embodiment (FIG. 66), neighboring memory units are not coupled by the liner film 410, however, in the fifth embodiment (FIG. 72), neighboring memory units are coupled by the liner film 410. In the peripheral circuit part also, the liner film 410 is not arranged between the insulating layer 360 and the insulating layer 47 in the fourth embodiment (FIG. 67). However, the aspect of the peripheral circuit part of the semiconductor device 200 in the fifth embodiment is the same as that of the peripheral circuit part in FIG. 5 (first embodiment) and the liner film 410 is arranged between the insulating layer 360 and the insulating layer 47. This liner film 410 is arranged so as to couple different unit contact parts etc. in the peripheral circuit part. The fifth embodiment differs from the fourth embodiment in the above-described points.

As described above, when the fifth embodiment is compared with the fourth embodiment, only the aspect of the region between pluralities of units is different. Consequently, for example, as in FIG. 64 in the fourth embodiment, when only a section intersecting with the direction in which one of the bit lines 40 extends is viewed, the aspect in the fifth embodiment is the same as the aspect in FIG. 64.

Even if the liner film 410 is arranged so as to couple a plurality of memory units, the same effects as those in the fourth embodiment in which the liner film 410 is not arranged basically are exhibited.

Subsequently, a method of manufacturing the semiconductor device 200 according to the fifth embodiment will be explained. The processes shown in FIG. 11 to FIG. 37 are the same as those in the method of manufacturing the semiconductor device 200 according to the first embodiment, and therefore, their explanation is omitted here. Each of Figs. (A) to (C) is a diagram when viewed in the same direction as that in Figs. (A) to (C) in FIG. 28 to FIG. 43.

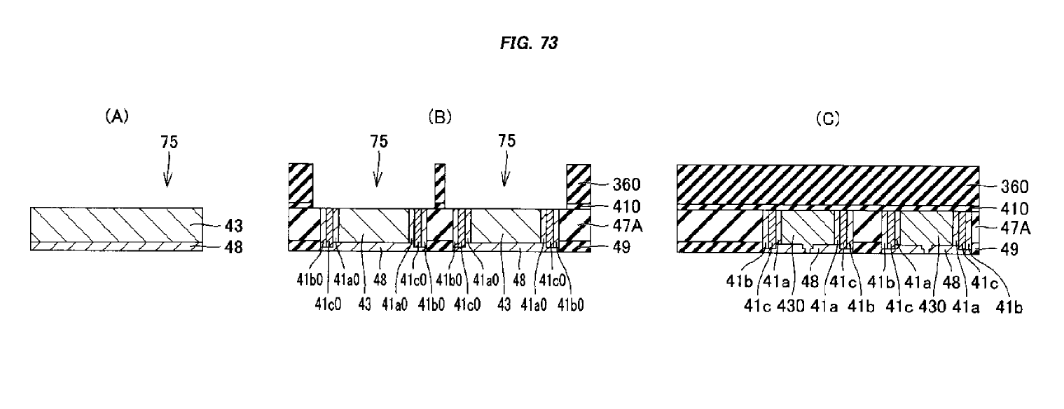

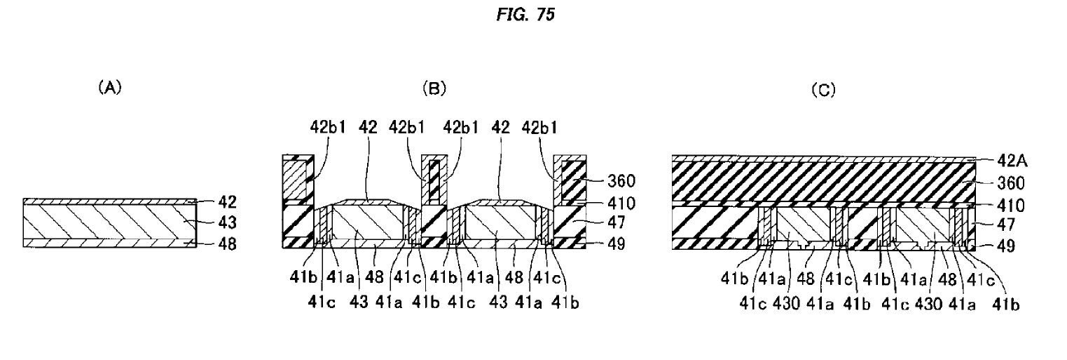

In FIG. 73 to FIG. 76, the aspects of only the side upper than the wire main body 43 are shown sequentially as in FIG. 37 to FIG. 43 and the lower side is not shown schematically.

Next, a layer that should become the liner film 410 is formed so as to cover, for example, the entire surface of the uppermost surface that is exposed next in the states shown in FIGS. 37(A) to (C). Over the layer, the same insulating layer including a silicon oxide film etc. as that in FIG. 68 is formed. This is a layer that should become the insulating layer 360 described above.

Subsequently, photolithography, etching, etc., are performed so as to remove the region corresponding to the layer that should become the insulating layer 360 and the layer that should become the liner film 410, particularly, to the upper part of the wire main body 43. In this manner, as shown in FIGS. 73(A) (B), the groove 75 is formed in the upper part of the wire main body 43. The region in which the insulating layer is not etched becomes the insulating layer 360. At this time, although not shown schematically in FIG. 73(C), it is preferable to etch part of the insulating layer 360 of the peripheral circuit part to form a groove which allows electrical coupling with an external load.

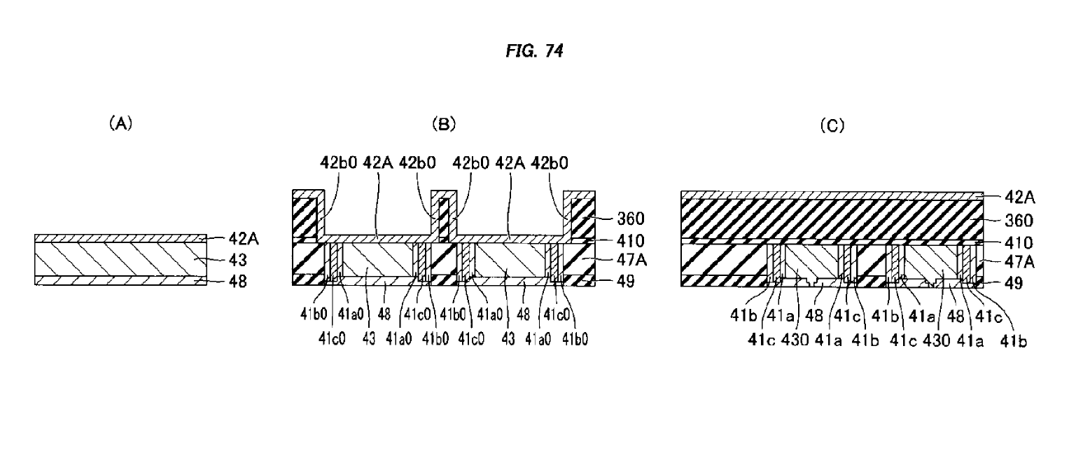

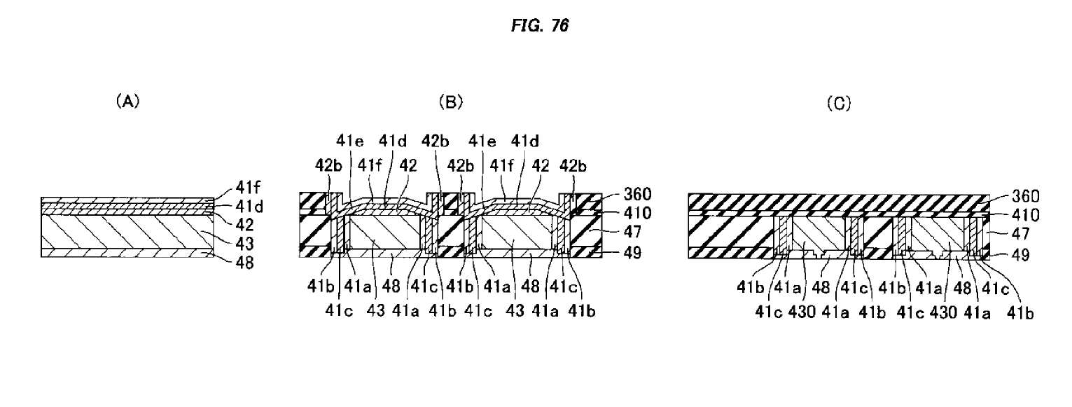

Each subsequent process in FIG. 74 to FIG. 76 is the same as each process in FIG. 69 to FIG. 71, respectively. In this manner, the cladding layer 41d, the barrier metal 41f, and the projecting end part 42b shown in FIGS. 76(A) to (C) are formed.

The fifth embodiment of the present invention differs from the fourth embodiment of the present invention only in the respective points described above. That is, the configurations, conditions, procedures, effects, etc., not described in the fifth embodiment of the present invention are all quite the same as those in the fourth embodiment of the present invention. That is, the effects in the present fifth embodiment are also the effects in the fourth embodiment and the effects described in the present fifth embodiment are the effects that follow the effects in the fourth embodiment.

### Sixth Embodiment

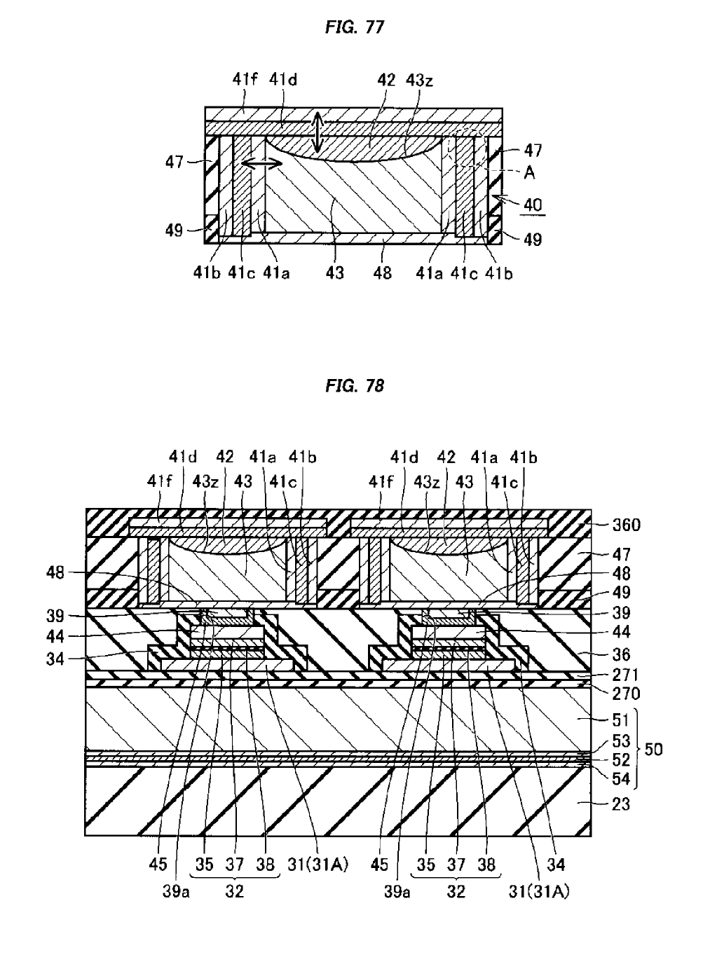

The semiconductor device 200 according to a sixth embodiment comprises substantially the same configuration as that of the semiconductor device 200 in the fourth embodiment. However, the configuration of the bit line 40 is somewhat different. Specifically, when FIG. 77 is compared with FIG. 64, in the fourth and fifth embodiments, as in the third embodiment, at the corner part of the cladding layer 41c and the cladding layer 41d, the angle formed by the directions in which the cladding layer 41c and the cladding layer 41d extend, respectively, in a section in which both the cladding layer 41c and the cladding layer 41d intersect with the direction in which the bit line 40 extends is obtuse. However, as in the sixth embodiment, the angle may be 90°.

In FIG. 77, the top surface of the wire main body 43 is a curved surface part 43z that is bent into a concave shape. With such an aspect, the distance between the curved surface part 43z and the cladding layer 41d of the wire main body 43 (in the vertical direction in FIG. 77) is longer than the distance between the top surface and the cladding layer 41d when, for example, the top surface of the wire main body 43 is a flat surface and its height is equal to the height of the uppermost part of the side surface of the wire main body 43. Because of this, it is possible to suppress more securely the mutual diffusion between the wire main body 43 and the cladding layer 41d in the vertical direction shown by the arrow in FIG. 77.

Other effects, such as the suppression of leakage of the magnetic field in the region surrounded by the circular dotted line A in FIG. 77, the suppression of leakage of the magnetic field to the neighboring memory unit, and the reduction in electric current by setting the crystal structures of the cladding layers 41c, 41d to be substantially the same, are all the same as those in the fourth and fifth embodiments.

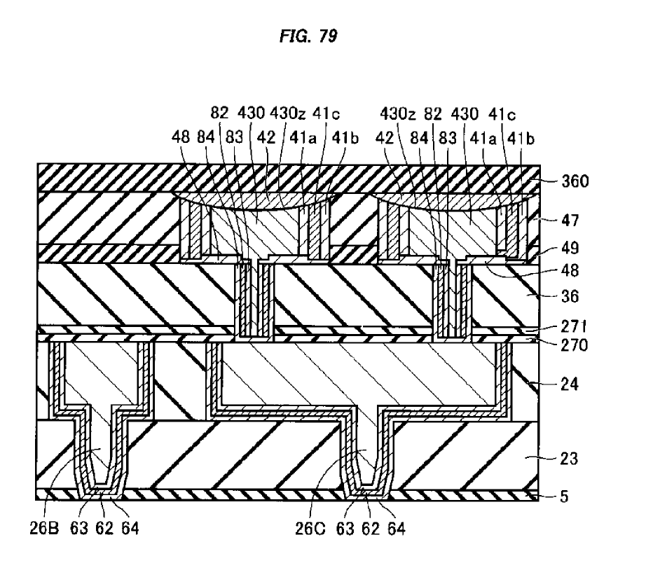

Similar to FIG. 4, FIG. 78 is a section view showing a state where two memory units are arranged side by side when viewed in the direction intersecting with FIG. 3. Similar to FIG. 5, FIG. 79 is a section view of the peripheral circuit part. Similar to FIG. 66 and FIG. 67 in the fourth embodiment, in FIG. 78 and FIG. 79, the liner film 410 is not arranged between the insulating layer 360 and the insulating layer 47. However, in the sixth embodiment also, the configuration may be such one in which the liner film 410 is arranged between the insulating layer 360 and the insulating layer 47 as, for example, in FIG. 72 in the fifth embodiment.

Subsequently, a method of manufacturing the semiconductor device 200 according to the sixth embodiment will be explained. The processes shown in FIG. 11 to FIG. 36 are the same as those in the method of manufacturing the semiconductor device 200 according to the first embodiment, and therefore, their explanation is omitted here.

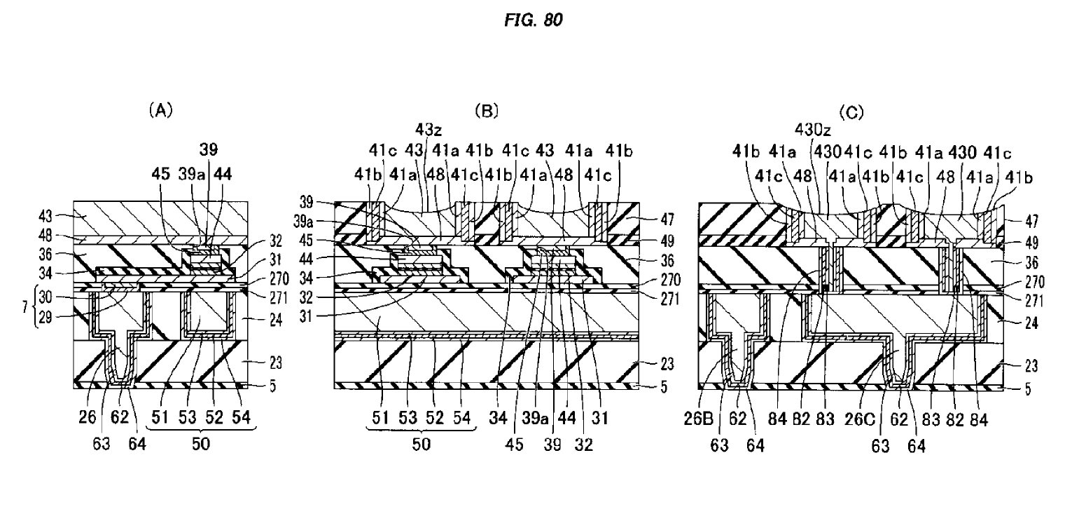

In the processes following the aspects shown in FIGS. 36(A) to (C), a fixed depth from the top surface of the wire main body 43 is subjected to the CMP processing as shown in FIGS. 80(A) to (C) so that the top surface becomes the curved surface part 43z in FIG. 80(B) and a curved surface part 430z in FIG. 80(C).

For example, when the electrically conductive film 43B is polished by the CMP processing for the certain depth on the side of the top surface in FIG. 35, it may also be possible to perform processing so that the curved surface parts 43z, 430z shown in FIGS. 80(B) (C) are formed (that is, the state in FIG. 80 is brought about from that in FIG. 35 without the state shown in FIG. 36).

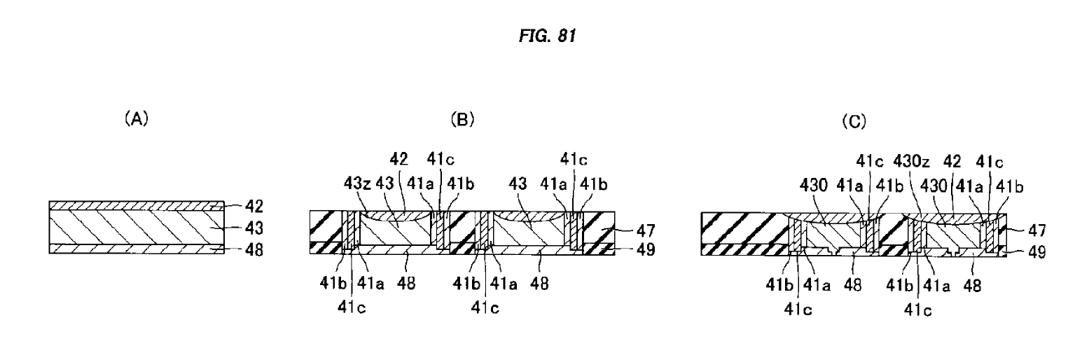

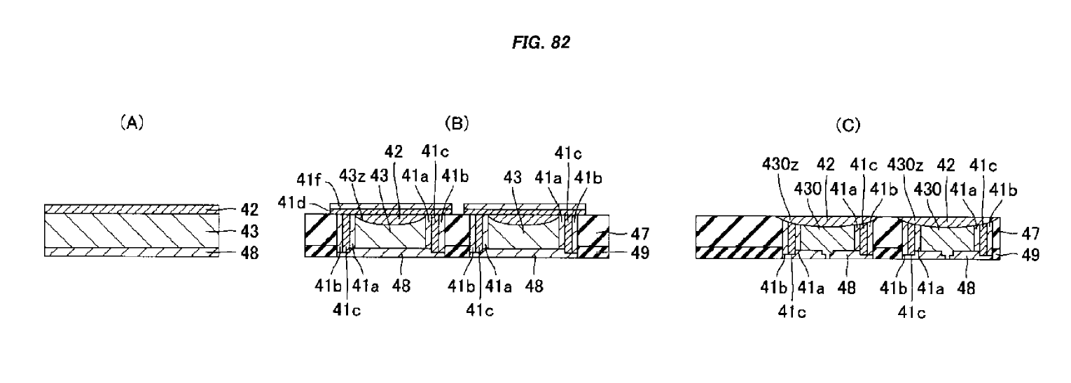

Subsequently, FIG. 81 to FIG. 82 show aspects of only the upper side than the wire main body 43 in FIG. 80 in subsequent processes following that in FIG. 80 and the lower side is omitted and not shown schematically. Each of Fig. (A) to (C) is a diagram when viewed in the same direction as that in Fig. (A) to (C) in FIG. 28 to FIG. 36.

A barrier metal film is formed over the uppermost surface that is exposed in FIGS. 80(A) to (C) and the CMP processing is performed so that the top surface is flattened. By doing so, the barrier metal 42 is formed so that the regions surrounded by the curved surface parts 43z, 430z and the barrier metals 41a, 41b are filled therewith as shown in FIGS. 81(A) to (C).

Then, a cladding layer and a barrier metal are formed over the uppermost surface that is exposed by sputtering etc. and photolithography, etching, etc., are performed so that these thin films remain particularly over the wire main body 43. By doing so, the cladding layer 41d and the barrier metal 41f are formed as shown in FIGS. 82(A) to (C). Subsequently, by forming the insulating layer 360 as in each of the embodiments described above, the configuration of the aspects shown in FIGS. 77 to 79 is completed.

The sixth embodiment of the present invention differs from the fourth and fifth embodiments of the present invention only in the respective points described above. That is, the configurations, conditions, procedures, effects, etc., not described in the sixth embodiment of the present invention are all quite the same as those in the fourth and fifth embodiments of the present invention. That is, the effects in the present sixth embodiment are also the effects in the fourth and fifth embodiments and the effects described in the present sixth embodiment are the effects that follow the effects in the fourth and fifth embodiments.

### Comparative Example

As a comparative example for reference, the configuration of the bit line 40 of the semiconductor device 200 of the present invention will be explained below.

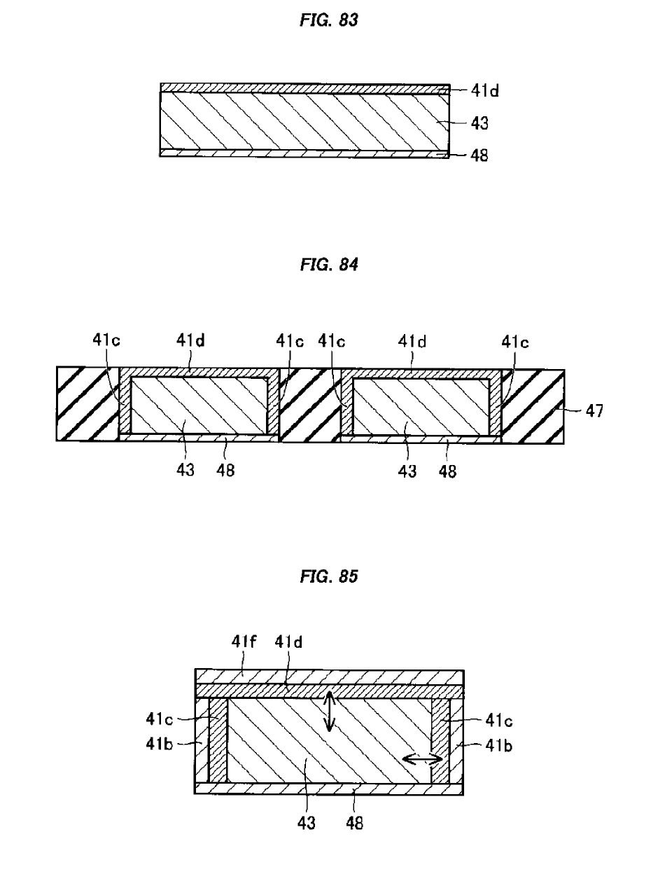

FIG. 83 is a diagram showing an aspect when a bit line based on the technology in the comparative example is viewed in the same direction as that in FIG. 3. FIG. 84 is a diagram showing an aspect when the bit line in FIG. 83 is viewed in the same direction as that in FIG. 4, that is, in the direction intersecting with FIG. 3. As shown in FIG. 84, in the comparative example, the cladding layer 41c that covers the side surface of the wire main body 43 of the bit line and the cladding layer 41d that covers the top surface of the wire main body 43 are arranged so as to come into direct contact with the side surface and the top surface of the wire main body 43. Because of this, there is a possibility of mutual diffusion of, for example, the copper atoms configuring the wire main body 43 and the atoms of the metal material configuring the cladding layers 41c, 41d. That is, there is a possibility that the wire main body 43 and the cladding layers 41c, 41d transform or deform and the electrical characteristics of the bit line and the performance of the semiconductor device 200 deteriorate.

This also applies when the barrier metals 41b, 41f are arranged outside the cladding layers 41c, 41d as shown in FIG. 85. FIG. 85 is a section view when viewed in the same direction as that in FIG. 84. In this case also, the state where the wire main body 43 and the cladding layers 41c, 41d are in direct contact remains unchanged. Because of this, there is a possibility that mutual diffusion shown by the arrows in FIG. 85 takes place.

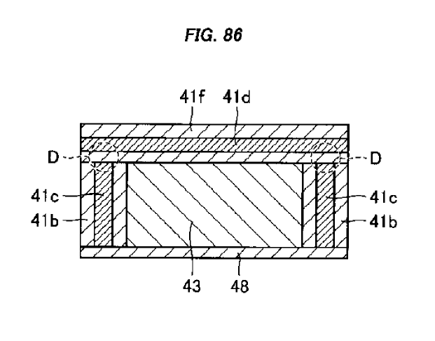

FIG. 86 shows a case where the cladding layer 41c and the cladding layer 41d are discontinuous in a region D surrounded by a circular dotted line. FIG. 86 is also a section view when viewed in the same direction as that in FIG. 84. In this case, in the region D, there is a possibility that the magnetic line of force that passes through the inside of the cladding layer 41c and the cladding layer 41d along the direction in which these cladding layers extend deviates to the outside of the cladding layers and leaks.

All of the embodiments disclosed here are only examples in all points and should not be considered as limited ones. The scope of the present invention is specified not by the embodiments described above but by claims and it is intended that all the meanings equivalent to the scope of claims and all modifications within the scope are included.

The semiconductor device of the present invention is particularly excellent as technology to prevent a magnetoresistive element from malfunctioning.

What is claimed is:

1. A semiconductor device comprising:
a semiconductor substrate having a main surface;
a magnetoresistive element located over the main surface of the semiconductor substrate;
a wire located over the magnetoresistive element;
a barrier layer arranged so as to continuously cover the side surface and the top surface of the wire; and
a cladding layer arranged so as to continuously cover the surface of the barrier layer facing the wire and the surface on the opposite side,
wherein a plurality of memory units including the magnetoresistive element, the wire, the barrier layer, and the cladding layer is formed, the memory units are arranged in parallel with the direction intersecting with the direction in which the wire extends, and the cladding layer is separated between the memory units.

2. The semiconductor device according to claim 1,
wherein the barrier layer contains an electrically conductive material and the barrier layer is separated between the memory units.

3. The semiconductor device according to claim 1,
wherein the barrier layer contains a dielectric material and the barrier layer is connected between the memory units.

4. The semiconductor device according to claim 1,
wherein the thickness of a lateral part of the cladding layer arranged so as to cover the barrier layer on the side surface of the wire is greater than that of an upper part of the cladding layer arranged so as to cover the barrier layer in the top surface of the wire.

5. The semiconductor device according to claim 1, further comprising a protective layer arranged so as to cover the surface of the cladding layer facing the barrier layer and the surface on the opposite side.

6. The semiconductor device according to claim 1,
wherein the wire and the cladding layer are electrically insulated.

7. The semiconductor device according to claim 1,
wherein at a corner part where the part of the cladding layer arranged so as to cover the surface on the opposite side of the barrier layer that covers the side surface of the wire is connected to the part of the cladding layer arranged so as to cover the surface on the opposite side of the barrier layer that covers the top surface of the wire, the angle formed by the directions in which the parts of the cladding layers to be connected to each other extend is more than 90° and less than 180°.

8. The semiconductor device according to claim 1,
wherein the barrier layer that covers the side surface of the wire and the barrier layer that covers the top surface of the wire contain the same material.

9. The semiconductor device according to claim 1,
wherein the top surface of the wire is bent into a concave shape.
